(19) United States
(12) Patent Application Publication
(10) Pub. No.: US 2024/0334697 A1
(43) Pub. Date: Oct. 3, 2024

(54) THREE-DIMENSIONAL MEMORY DEVICE INCLUDING A SOURCE STRUCTURE SURROUNDED BY INNER SIDEWALLS OF VERTICAL SEMICONDUCTOR CHANNELS AND METHODS OF FORMING THE SAME

(71) Applicant: SANDISK TECHNOLOGIES LLC, ADDISON, TX (US)

(72) Inventors: Takaaki IWAI, Yokkaichi (JP); Yuki FUKUSHIGE, Yokkaichi (JP); Teruo OKINA, Yokkaichi (JP)

(21) Appl. No.: 18/362,743

(22) Filed: Jul. 31, 2023

Related U.S. Application Data
(60) Provisional application No. 63/492,573, filed on Mar. 28, 2023.

(51) Int. Cl. H10B 43/27; G11C 16/04; H01L 23/522; H01L 23/528; H10B 43/10; H10B 43/35

(52) U.S. Cl. CPC H10B 43/27; G11C 16/0483; H01L 23/5226; H01L 23/5283; H10B 43/10; H10B 43/35

(57) ABSTRACT

A three-dimensional memory device includes a source structure having a portion surrounded by inner sidewalls of cylindrical vertical semiconductor channels.

### FIELD

The present disclosure relates generally to the field of semiconductor devices, and particularly to a three-dimensional memory device including a source structure surrounded by inner sidewalls of vertical semiconductor channels and methods for manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a semiconductor structure is provided, which comprises: an alternating stack of insulating layers and electrically conductive layers located over source-level material layers; a memory opening vertically extending through the alternating stack and into an upper portion of the source-level material layers; and a memory opening fill structure located in the memory opening and comprising a vertical stack of memory elements and a vertical semiconductor channel, wherein the source-level material layers comprise a source contact layer that includes an outer portion located outside a volume of the memory opening and an inner portion located within the volume of the memory opening and is more proximal to a vertical axis passing through a geometrical center of the volume of the memory opening than an inner sidewall of the vertical semiconductor channel is to the vertical axis.

According to another aspect of the present disclosure, a method of forming a semiconductor structure is provided. The method comprises: forming in-process source-level material layers that comprise a source-level sacrificial layer over a substrate; forming an alternating stack of insulating layers and spacer material layers over the in-process source-level material layers, wherein the spacer material layers are formed as, or are subsequently replaced with, electrically conductive layers; forming a memory opening through the alternating stack and through a segment of the source-level sacrificial layer; forming a memory opening fill structure comprising a vertical stack of memory elements, a vertical semiconductor channel, and a dielectric core that is laterally surrounded by the vertical semiconductor channel in the memory opening; forming a source cavity by removing the source-level sacrificial layer; expanding the source cavity into the memory opening fill structure to physically expose a segment of an inner sidewall of the vertical semiconductor channel; and forming a source contact layer in the source cavity over the segment of the inner sidewall of the vertical semiconductor channel.

According to an aspect of the present disclosure, a semiconductor structure is provided, which comprises: an alternating stack of insulating layers and electrically conductive layers located over a source semiconductor layer; a memory opening vertically extending through the alternating stack and the source semiconductor layer; a memory opening fill structure located in the memory opening and comprising, from outside to inside, a vertical stack of memory elements, a vertical semiconductor channel having a first tubular configuration, an etch stop dielectric layer having a second tubular configuration, and a dielectric core; and a metallic source structure contacting the source semiconductor layer, the etch stop dielectric layer, and the vertical semiconductor channel.

According to another aspect of the present disclosure, a method of forming a semiconductor structure is provided. The method comprises: forming a source semiconductor layer over a carrier substrate; forming an alternating stack of insulating layers and spacer material layers over the source semiconductor layer, wherein the spacer material layers are formed as, or are subsequently replaced with, electrically conductive layers; forming a memory opening through the alternating stack and the source semiconductor layer; forming a memory opening fill structure in the memory opening by sequentially forming at least a memory film, a vertical semiconductor channel, an etch stop dielectric layer, and a dielectric core; removing the carrier substrate; removing an end portion of the memory film; removing an end portion of the vertical semiconductor channel by performing a first isotropic etch process that etches a material of the vertical semiconductor channel selective to a material of the etch stop dielectric layer; and forming a metallic source structure on a segment of a backside surface of the source semiconductor layer and on the vertical semiconductor channel.

### BRIEF DESCRIPTION OF THE DRAWINGS

FIG. 1 is a schematic vertical cross-sectional view of a first exemplary structure after formation of a stopper insulating layer and a lower source-level semiconductor layer over a carrier substrate according to a first embodiment of the present disclosure.

FIG. 2A is a vertical cross-sectional view of the first exemplary structure after formation of a source-level sacrificial layer that comprises multiple source-level sacrificial material rails according to the first embodiment of the present disclosure.

FIG. 2B is a top-down view of the first exemplary structure of FIG. 2A. The hinged vertical plane A-A′ is the cut plane of the vertical cross-sectional view of FIG. 2A.

FIG. 3 is a schematic vertical cross-sectional view of the first exemplary structure after formation of an upper source-level semiconductor layer and an alternating stack of insulating layers and sacrificial material layers according to the first embodiment of the present disclosure.

FIG. 4 is a schematic vertical cross-sectional view of the first exemplary structure after formation of stepped surfaces and a stepped dielectric material portion according to the first embodiment of the present disclosure.

FIG. 5A is a schematic vertical cross-sectional view of the first exemplary structure after patterning memory openings and support openings according to the first embodiment of the present disclosure.

FIG. 5B is a top-down view of the first exemplary structure of FIG. 5A. The vertical plane A-A′ is the cut plane of the vertical cross-sectional view of FIG. 5A.

FIG. 6 is a schematic vertical cross-sectional view of the first exemplary structure after formation of support pillar structures in the support openings according to the first embodiment of the present disclosure.

FIGS. 7A-7D are sequential vertical cross-sectional views of a memory opening during formation of a memory opening fill structure according to an embodiments of the present disclosure.

FIG. 8 is a vertical cross-sectional view of the first exemplary structure after formation of memory opening fill structures according to the first embodiment of the present disclosure.

FIG. 9A is a vertical cross-sectional view of the first exemplary structure after formation of lateral isolation trenches according to the first embodiment of the present disclosure.

FIG. 9B is a top-down view of the first exemplary structure of FIG. 9A. The vertical plane A-A′ is the cut plane of the vertical cross-sectional view of FIG. 9A.

FIG. 10 is a vertical cross-sectional view of the first exemplary structure after formation of laterally-extending trenches according to the first embodiment of the present disclosure.

FIG. 11A is a vertical cross-sectional view of the first exemplary structure after formation of electrically conductive layers according to the first embodiment of the present disclosure.

FIG. 11B is a magnified view of a region of the first exemplary structure of FIG. 11A around a memory opening fill structure.

FIG. 12 is a vertical cross-sectional view of the first exemplary structure after formation of an insulating spacer around each lateral isolation trench according to the first embodiment of the present disclosure.

FIG. 13A is a vertical cross-sectional view of the first exemplary structure after formation of sacrificial trench spacers and vertical extension of laterally-extending cavities according to the first embodiment of the present disclosure.

FIG. 13B is a top-down view of the first exemplary structure of FIG. 13A. The vertical plane A-A′ is the cut plane of the vertical cross-sectional view of FIG. 13A.

FIG. 14A is a vertical cross-sectional view of the first exemplary structure after performing a first isotropic etch process that forms a source cavity according to the first embodiment of the present disclosure.

FIG. 14B is a horizontal cross-sectional view of the first exemplary structure along the horizontal plane B-B′ of FIG. 14A. The vertical plane A-A′ is the cut plane of the vertical cross-sectional view of FIG. 14A.

FIG. 15A is a vertical cross-sectional view of the first exemplary structure after performing a second isotropic etch process that removes portions of the memory films that are proximal to the source cavity according to the first embodiment of the present disclosure.

FIG. 15B is a horizontal cross-sectional view of the first exemplary structure along the horizontal plane B-B′ of FIG. 15A. The vertical plane A-A′ is the cut plane of the vertical cross-sectional view of FIG. 15A.

FIG. 15C is a magnified view of a region of the first exemplary structure of FIG. 15A around a memory opening fill structure.

FIG. 16 is a magnified view of a region of the first exemplary structure after performing a third isotropic etch process that removes portions of the vertical semiconductor channels that are proximal to the source cavity according to the first embodiment of the present disclosure.

FIG. 17A is a vertical cross-sectional view of the first exemplary structure after performing a fourth isotropic etch process that removes portions of dielectric cores that are proximal to the source cavity according to the first embodiment of the present disclosure.

FIG. 17B is a magnified view of a region of the first exemplary structure of FIG. 17A around a memory opening fill structure.

FIG. 18 is a vertical cross-sectional view of the first exemplary structure after conversion of the sacrificial trench spacers according to the first embodiment of the present disclosure.

FIG. 19A is a vertical cross-sectional view of the first exemplary structure after formation of a source contact layer and source contact via structures according to the first embodiment of the present disclosure.

FIG. 19B is a horizontal cross-sectional view of the first exemplary structure along the horizontal plane B-B′ of FIG. 19A. The vertical plane A-A′ is the cut plane of the vertical cross-sectional view of FIG. 19A.

FIG. 19C is a magnified view of a region of the first exemplary structure of FIG. 19A around a memory opening fill structure.

FIG. 20A is a vertical cross-sectional view of the first exemplary structure after formation of layer contact via structures and drain contact via structures according to the first embodiment of the present disclosure.

FIG. 20B is a top-down view of the first exemplary structure of FIG. 20A. The vertical plane A-A′ is the cut plane of the vertical cross-sectional view of FIG. 20A.

FIG. 21 is a vertical cross-sectional view of the first exemplary structure after formation of a memory die according to the first embodiment of the present disclosure.

FIG. 22 is a vertical cross-sectional view of a logic die according to the first embodiment of the present disclosure.

FIG. 23 is a vertical cross-sectional view of the first exemplary structure after attaching the logic die to the memory die according to the first embodiment of the present disclosure.

FIG. 24 is a vertical cross-sectional view of the first exemplary structure after removal of the carrier substrate according to the first embodiment of the present disclosure.

FIG. 25 is a vertical cross-sectional view of an alternative configuration of the first exemplary according to the first embodiment of the present disclosure.

FIG. 26A is a vertical cross-sectional view of a second exemplary structure after formation of laterally-extending cavities according to a second embodiment of the present disclosure.

FIG. 26B is a top-down view of the second exemplary structure of FIG. 26A. The vertical plane A-A′ is the cut plane of the vertical cross-sectional view of FIG. 26A.

FIG. 27 is a vertical cross-sectional view of the second exemplary structure after formation of sacrificial trench spacers according to the second embodiment of the present disclosure.

FIG. 28 is a vertical cross-sectional view of the second exemplary structure after vertical extension of the laterally-extending cavities according to the second embodiment of the present disclosure.

FIG. 29A is a vertical cross-sectional view of the second exemplary structure after performing a first isotropic etch process that forms a source cavity according to the second embodiment of the present disclosure.

FIG. 29B is a horizontal cross-sectional view of the second exemplary structure along the horizontal plane B-B′ of FIG. 29A. The vertical plane A-A′ is the cut plane of the vertical cross-sectional view of FIG. 29A.

FIG. 29C is a magnified view of a region of the second exemplary structure of FIG. 29A around a memory opening fill structure.

FIG. 30A is a vertical cross-sectional view of the second exemplary structure after performing a second isotropic etch process that removes portions of the memory films that are proximal to the source cavity according to the second embodiment of the present disclosure.

FIG. 30B is a horizontal cross-sectional view of the second exemplary structure along the horizontal plane B-B′ of FIG. 30A. The vertical plane A-A′ is the cut plane of the vertical cross-sectional view of FIG. 30A.

FIG. 30C is a magnified view of a region of the second exemplary structure of FIG. 30A around a memory opening fill structure.

FIG. 31 is a magnified view of a region of the second exemplary structure after performing a third isotropic etch process that removes portions of the vertical semiconductor channels that are proximal to the source cavity according to the second embodiment of the present disclosure.

FIG. 32A is a vertical cross-sectional view of the second exemplary structure after performing a fourth isotropic etch process that removes portions of dielectric cores that are proximal to the source cavity according to the second embodiment of the present disclosure.

FIG. 32B is a magnified view of a region of the second exemplary structure of FIG. 32A around a memory opening fill structure.

FIG. 33 is a vertical cross-sectional view of the second exemplary structure after removal of the sacrificial trench spacers according to the second embodiment of the present disclosure.

FIG. 34 is a vertical cross-sectional view of the second exemplary structure after formation of laterally-extending cavities according to the second embodiment of the present disclosure.

FIG. 35 is a vertical cross-sectional view of the second exemplary structure after formation of source regions according to the second embodiment of the present disclosure.

FIGS. 36A-36D are sequential vertical cross-sectional views of a region around a memory opening fill structure in the second exemplary structure during formation of an optional backside blocking dielectric layer, electrically conductive layers, a source contact layer, and a dielectric fill material layer according to the second embodiment of the present disclosure.

FIG. 36E is a vertical cross-sectional view of a region around a memory opening fill structure in an alternative configuration of the second exemplary structure after formation of electrically conductive layers, a source contact layer, and a dielectric fill material layer according to the second embodiment of the present disclosure.

FIG. 37 is a vertical cross-sectional view of the second exemplary structure after formation of the electrically conductive layers, the source contact layer, and the dielectric fill material layer according to the second embodiment of the present disclosure.

FIG. 38A is a vertical cross-sectional view of the second exemplary structure after removal of material portions in the lateral isolation trenches and above the contact-level dielectric layer according to the second embodiment of the present disclosure.

FIG. 38B is a vertical cross-sectional view of a region around a memory opening fill structure in the second exemplary structure of FIG. 38A.

FIG. 38C is a vertical cross-sectional view of a region around a memory opening fill structure in an alternative configuration of the second exemplary structure at a processing step that corresponds to the processing step of FIGS. 38A and 38B.

FIG. 39A is a vertical cross-sectional view of the second exemplary structure after formation of source contact via structures, layer contact via structures, and drain contact via structures according to the second embodiment of the present disclosure.

FIG. 39B is a top-down view of the second exemplary structure of FIG. 39A. The vertical plane A-A′ is the cut plane of the vertical cross-sectional view of FIG. 39A.

FIG. 40A is a vertical cross-sectional view of the second exemplary structure after formation of a memory die according to the second embodiment of the present disclosure.

FIG. 40B is a vertical cross-sectional view of the second exemplary structure after attaching the logic die to the memory die, and removal of the carrier substrate, according to the second embodiment of the present disclosure.

FIG. 41 is a schematic vertical cross-sectional view of a third exemplary structure after formation of a stopper insulating layer, a source semiconductor layer, and an alternating stack of insulating layers and sacrificial material layers over a carrier substrate according to a third embodiment of the present disclosure.

FIG. 42 is a schematic vertical cross-sectional view of the third exemplary structure after formation of stepped surfaces and a stepped dielectric material portion according to the third embodiment of the present disclosure.

FIG. 43 is a schematic vertical cross-sectional view of the third exemplary structure after formation of support openings according to the third embodiment of the present disclosure.

FIG. 44 is a schematic vertical cross-sectional view of the third exemplary structure after formation of support pillar structures according to the third embodiment of the present disclosure.

FIG. 45A is a schematic vertical cross-sectional view of the third exemplary structure after formation of memory openings according to the third embodiment of the present disclosure.

FIG. 45B is a top-down view of the third exemplary structure of FIG. 45A. The vertical plane A-A′ is the cut plane of the vertical cross-sectional view of FIG. 45A.

FIGS. 46A-46D are sequential vertical cross-sectional views of a memory opening during formation of a memory opening fill structure according to the third embodiments of the present disclosure.

FIG. 47A is a vertical cross-sectional view of the third exemplary structure after formation of memory opening fill structures according to the third embodiment of the present disclosure.

FIG. 47B is a top-down view of the third exemplary structure of FIG. 47A. The vertical plane A-A′ is the cut plane of the vertical cross-sectional view of FIG. 47A.

FIG. 48A is a vertical cross-sectional view of the third exemplary structure after formation of lateral isolation trenches according to the third embodiment of the present disclosure.

FIG. 48B is a top-down view of the third exemplary structure of FIG. 48A. The vertical plane A-A′ is the cut plane of the vertical cross-sectional view of FIG. 48A.

FIG. 49 is a vertical cross-sectional view of the third exemplary structure after formation of lateral recesses according to the third embodiment of the present disclosure.

FIG. 50 is a vertical cross-sectional view of the third exemplary structure after formation of electrically conductive layers according to the third embodiment of the present disclosure.

FIG. 51 is a vertical cross-sectional view of the third exemplary structure after formation of lateral isolation trench fill structures according to the third embodiment of the present disclosure.

FIG. 52A is a vertical cross-sectional view of the third exemplary structure after formation of drain contact via structures and layer contact via structures according to the third embodiment of the present disclosure.

FIG. 52B is a top-down view of the third exemplary structure of FIG. 52A. The vertical plane A-A′ is the cut plane of the vertical cross-sectional view of FIG. 52A.

FIG. 53 is a vertical cross-sectional view of the third exemplary structure after formation of a memory die according to the third embodiment of the present disclosure.

FIG. 54 is a vertical cross-sectional view of a logic die according to the third embodiment of the present disclosure.

FIG. 55 is a vertical cross-sectional view of the third exemplary structure after attaching the logic die to the memory die according to the third embodiment of the present disclosure.

FIG. 56A is a vertical cross-sectional view of the third exemplary structure after removal of the carrier substrate according to the third embodiment of the present disclosure.

FIG. 56B is a magnified view of region B of FIG. 56A.

FIG. 57A is a vertical cross-sectional view of the third exemplary structure after patterning the stopper insulating layer according to the third embodiment of the present disclosure.

FIG. 57B is a magnified view of region B of FIG. 57A.

FIGS. 58A-58D are sequential vertical cross-sectional views of a region of a first configuration of the third exemplary structure during formation of a backside source structure according to the third embodiment of the present disclosure.

FIGS. 59A-59C are sequential vertical cross-sectional views of a region of a second configuration of the third exemplary structure during formation of a backside source structure according to the third embodiment of the present disclosure.

FIG. 60 is a vertical cross-sectional view of the third exemplary structure after formation of the backside source structure according to the third embodiment of the present disclosure.

FIG. 61 is a vertical cross-sectional view of a third configuration of the third exemplary structure after removal of the stopper insulating layer according to the third embodiment of the present disclosure.

FIG. 62 is a vertical cross-sectional view of the third configuration of the third exemplary structure after formation of a backside source structure according to the third embodiment of the present disclosure.

FIG. 63 is a vertical cross-sectional view of the third configuration of the third exemplary structure after formation of a backside insulating layer and a backside contact pad according to the third embodiment of the present disclosure.

### DETAILED DESCRIPTION

As discussed above, the present disclosure is directed to a three-dimensional memory device including a source structure (e.g., a source contact layer of the first and second embodiments or a metallic source structure of the third embodiment) surrounded by inner sidewalls of vertical semiconductor channels and methods for manufacturing the same, the various aspects of which are described below. Embodiments of the disclosure can be employed to form various structures including a multilevel memory structure, non-limiting examples of which include three-dimensional memory array devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

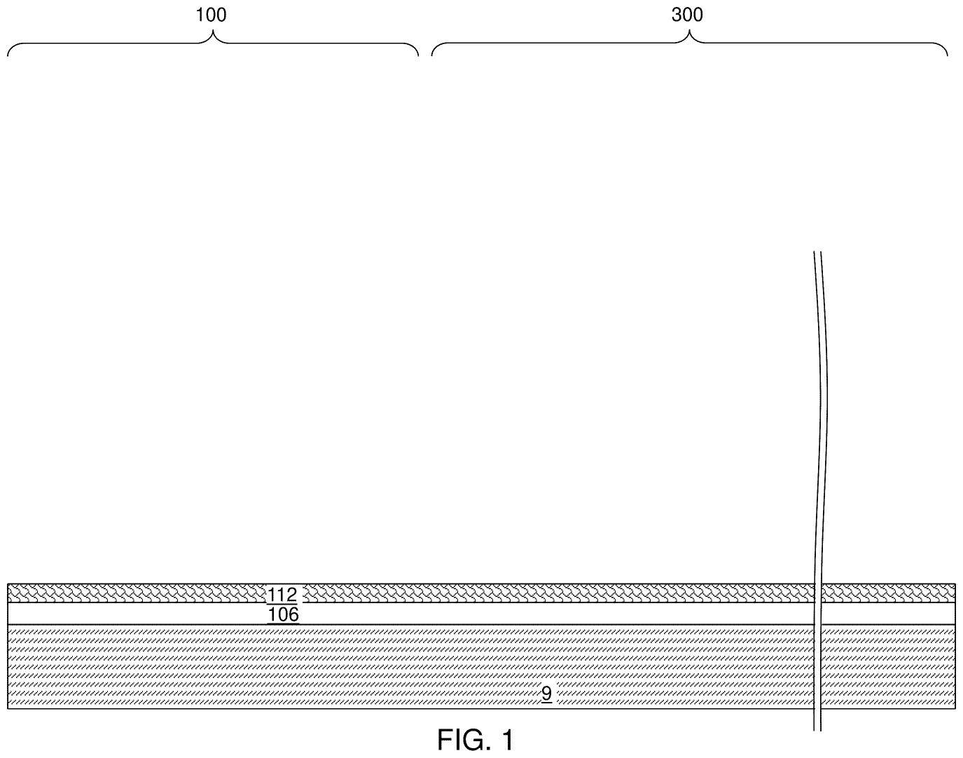

Referring to FIG. 1, a first exemplary structure according to a first embodiment of the present disclosure is illustrated. The first exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective the materials of insulating layers 32 and dielectric material portions to be subsequently formed. The first exemplary structure may comprise a memory array region 100 in which a three-dimensional memory array is to be subsequently formed, and a contact region 300 in which layer contact via structures contacting word lines of the three-dimensional memory array are to be subsequently formed.

An insulating material layer can be formed on a top surface of the carrier substrate 9. The insulating material layer can be subsequently employed as a stopping material layer for a process that removes the carrier substrate 9, and is herein referred to as a stopper insulating layer 106, or as a backside pad dielectric layer. If a polishing process such as a chemical mechanical polishing process is employed to subsequently remove the carrier substrate 9, the stopper material layer 106 may be subsequently employed as a polishing stopper material layer. If an etch process such as a wet etch process is employed to subsequently remove the carrier substrate 9, the stopper material layer 106 may be subsequently employed as an etch stop material layer. In one embodiment, the stopper insulating layer 106 comprises a dielectric material such as undoped silicate glass, a doped silicate glass, or silicon nitride. The thickness of the stopper insulating layer 106 may be in a range from 50 nm to 600 nm, such as from 100 nm to 300 nm, although lesser and greater thicknesses may also be employed.

A lower source-level semiconductor layer 112 can be formed over the stopper insulating layer 106. The lower source-level semiconductor layer 112 includes an undoped (i.e., intrinsic) semiconductor material, such as undoped polysilicon or undoped amorphous silicon. The thickness of each of the lower source-level semiconductor layer 112 may be in a range from 20 nm to 300 nm, such as from 60 nm to 150 nm, although lesser and greater thicknesses may also be used.

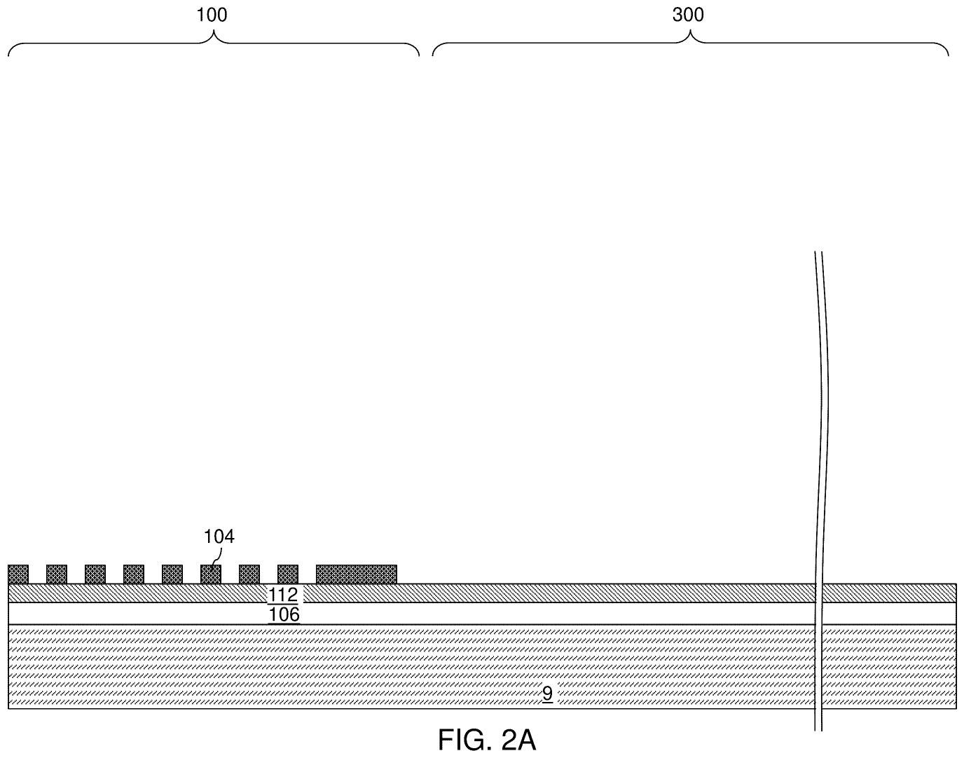

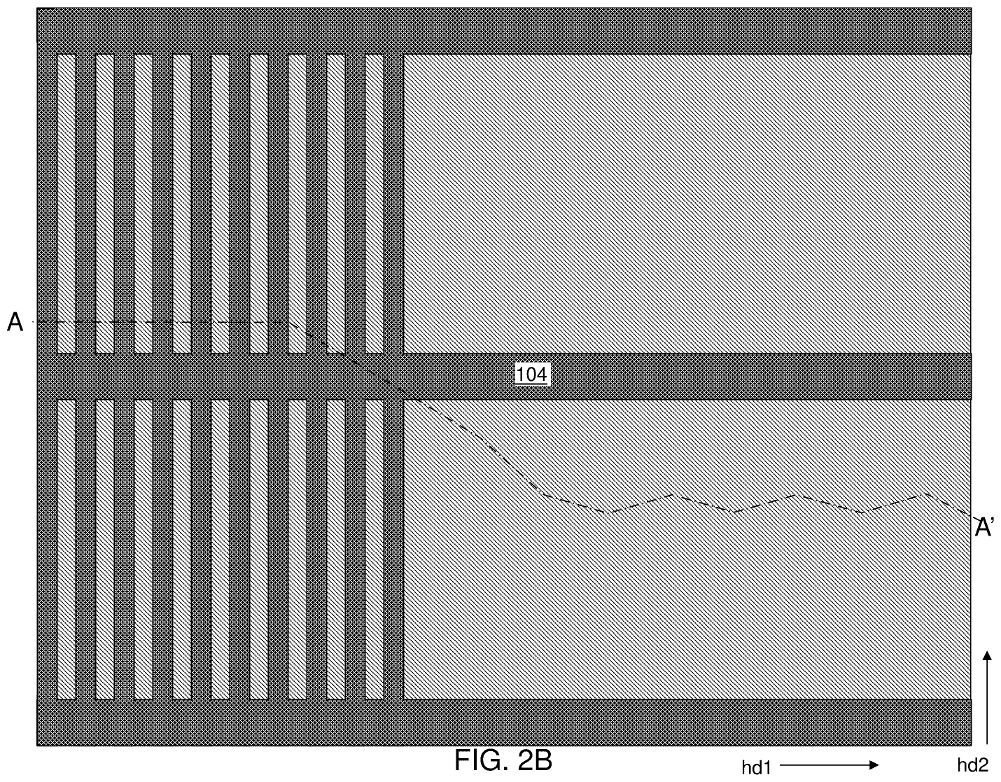

Referring to FIGS. 2A and 2B, a source-level sacrificial layer 104 can be formed over the lower source-level semiconductor layer 112. The source-level sacrificial layer 104 comprises a material that may be removed selective to the semiconductor material of the lower source-level semiconductor layer 112 and the semiconductor material of an upper source-level semiconductor layer to be subsequently formed. For example, the source-level sacrificial layer 104 may be formed by depositing and pattering a layer of a source-level sacrificial material such as silicon nitride or silicon oxynitride.

A blanket layer of the source-level sacrificial material can be deposited, and a photoresist layer (not shown) can be applied over the blanket layer. The photoresist layer can be lithographically patterned with a composite pattern including strip patterns and a line-and-space pattern. The strip patterns comprise patterns of lateral isolation trenches to be subsequently formed, and may comprise line patterns laterally extending along a first horizontal direction hd1. The line-and-space pattern comprise a periodic one-dimensional array of line patterns that laterally extend along a second horizontal direction hd2 and having a periodicity along the first horizontal direction hd1. In one embodiment, the first horizontal direction hd1 may be a direction that is perpendicular to boundary between the memory array region 100 and the contact region 300. In one embodiment, the line-and-space pattern of the photoresist layer can be formed in the memory array region 100, and the photoresist layer may be removed from the contact region 300. The strip patterns and the line-and-space patterns are interconnected among one another in the memory array region 100 such that multiple line patterns within the line-and-space pattern are attached to each strip pattern. As such, the strip patterns are also referred to as stem patterns, and the line-and-space patterns are also referred to as branch patterns. An anisotropic etch process can be performed to remove unmasked portions of the source-level sacrificial layer 104.

The remaining portions of the source-level sacrificial layer 104 may comprise multiple source-level sacrificial material beams that laterally extend along the first horizontal direction hd1 and replicate the pattern of the strip patterns, and multiple source-level sacrificial material rails that laterally extend along a second horizontal direction (e.g., bit line direction) hd2, which is different from the first horizontal direction (e.g., word line direction) hd1 and replicate the line-and-space pattern. In one embodiment, the second horizontal direction hd2 may be perpendicular to the first horizontal direction hd1. Thus, the source-level sacrificial layer 104 comprises multiple source-level sacrificial material rails that are laterally spaced from each other along the first horizontal direction hd1 and laterally extend along the second horizontal direction hd2 that is different from (e.g., perpendicular to) the first horizontal direction hd1. The periodicity of the multiple source-level sacrificial material rails of the source-level sacrificial layer 104 may be the same as the periodicity of memory openings to be subsequently formed along the first horizontal direction hd1. For example, the periodicity of the multiple source-level sacrificial material rails along the first horizontal direction hd1 may be in a range from 60 nm to 300 nm, such as from 100 nm to 200 nm, although lesser and greater periodicities may also be employed. The thickness (i.e., the height) of each source-level sacrificial material rail of the source-level sacrificial layer 104 may be in a range from 40 nm to 200 nm, such as from 60 nm to 150 nm, although lesser and grater thicknesses may also be employed.

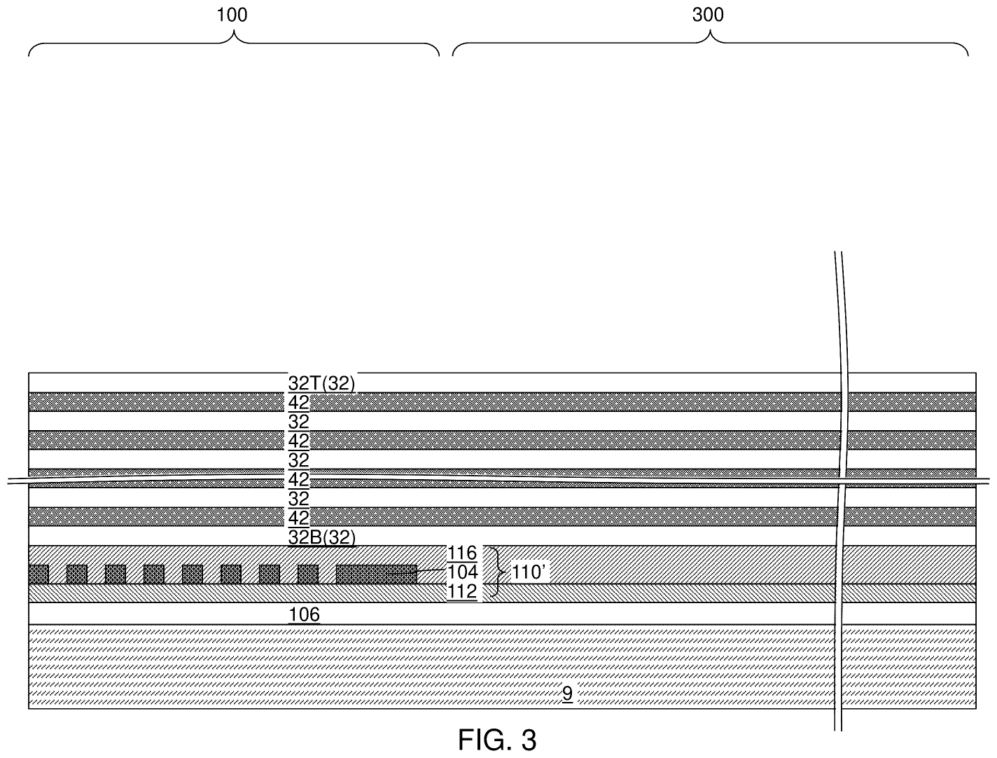

Referring to FIG. 3, an upper source-level semiconductor layer 116 can be formed over the source-level sacrificial layer 104. The upper source-level semiconductor layer 116 includes an undoped semiconductor material, such as undoped polysilicon or amorphous silicon. Optionally, the top surface of the source-level semiconductor layer 116 may be planarized, for example, employing a chemical mechanical polishing process. The thickness of the upper source-level semiconductor layer 116, as measured from the horizontal plane including the top surface of the lower source-level semiconductor layer 112, can be greater than the thickness of the source-level sacrificial layer 104. In one embodiment, the thickness of the upper source-level semiconductor layer 116 may be in a range from 60 nm to 400 nm, such as from 100 nm to 300 nm, although lesser and greater thicknesses may also be used. The combination of the lower source-level semiconductor layer 112, the source-level sacrificial layer 104, and the upper source-level semiconductor layer 116 constitutes in-process source-level material layers 110′. Thus, the in-process source-level material layers 110′ may comprise a lower source-level semiconductor layer 112 that underlies the source-level sacrificial layer 104, and an upper source-level semiconductor layer 116 that overlies the source-level sacrificial layer 104.

An alternating stack of first material layers and second material layers can be formed over the in-process source-level material layer 110′. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the in-process source-level material layer 110′. The insulating layers 32 comprise an insulating material such as undoped silicate glass or a doped silicate glass, and the sacrificial material layers 42 comprise a sacrificial material such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers. The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

Each of the insulating layers 32 other than the topmost insulating layer 32 may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32 may have a thickness of about one half of the thickness of other insulating layers 32.

While an embodiment is described in which the spacer material layers are formed as sacrificial material layers 42, the spacer material layers may be formed as electrically conductive layers in an alternative embodiment. Generally, spacer material layers may be formed as, or may be subsequently replaced at least partly with, electrically conductive layers.

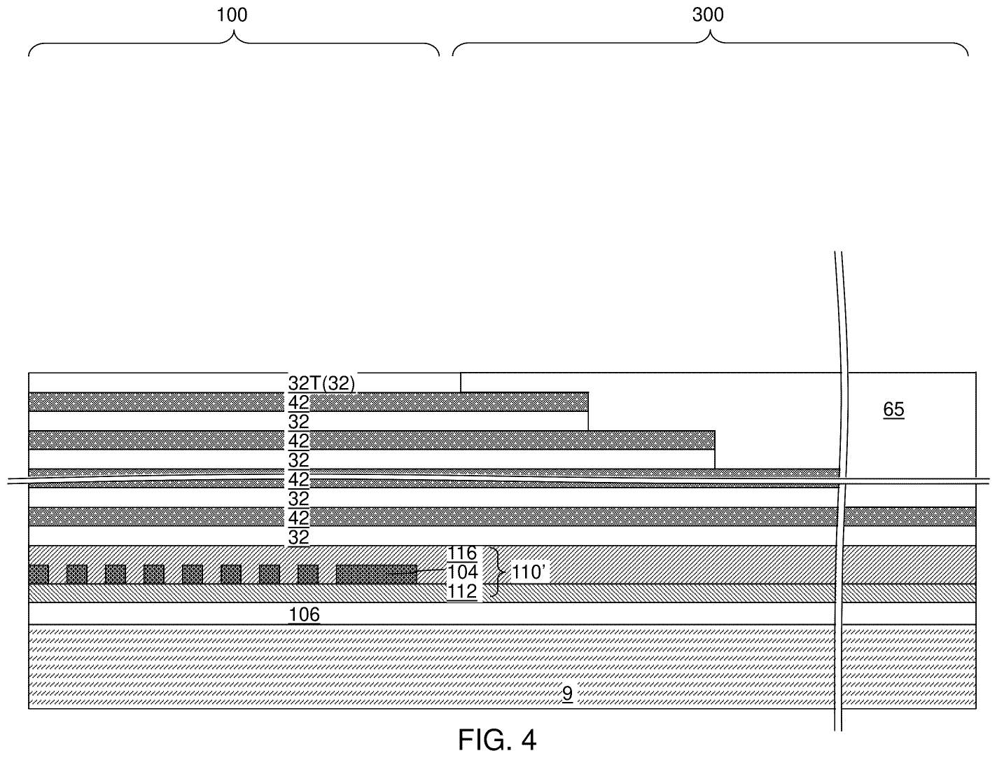

Referring to FIG. 4, optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the in-process source-level material layer 110′. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the stepped dielectric material portion 65. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the stepped dielectric material portion 65, the silicon oxide of the stepped dielectric material portion 65 may, or may not, be doped with dopants such as B, P, and/or F.

Optionally, drain-select-level isolation structures (not shown) can be formed through the topmost insulating layer 32T and a subset of the sacrificial material layers 42 located at drain-select-levels. The drain-select-level isolation structures can be formed, for example, by forming drain-select-level lateral isolation trenches and filling the drain-select-level lateral isolation trenches with a dielectric material such as silicon oxide. Excess portions of the dielectric material can be removed from above the top surface of the topmost insulating layer 32T.

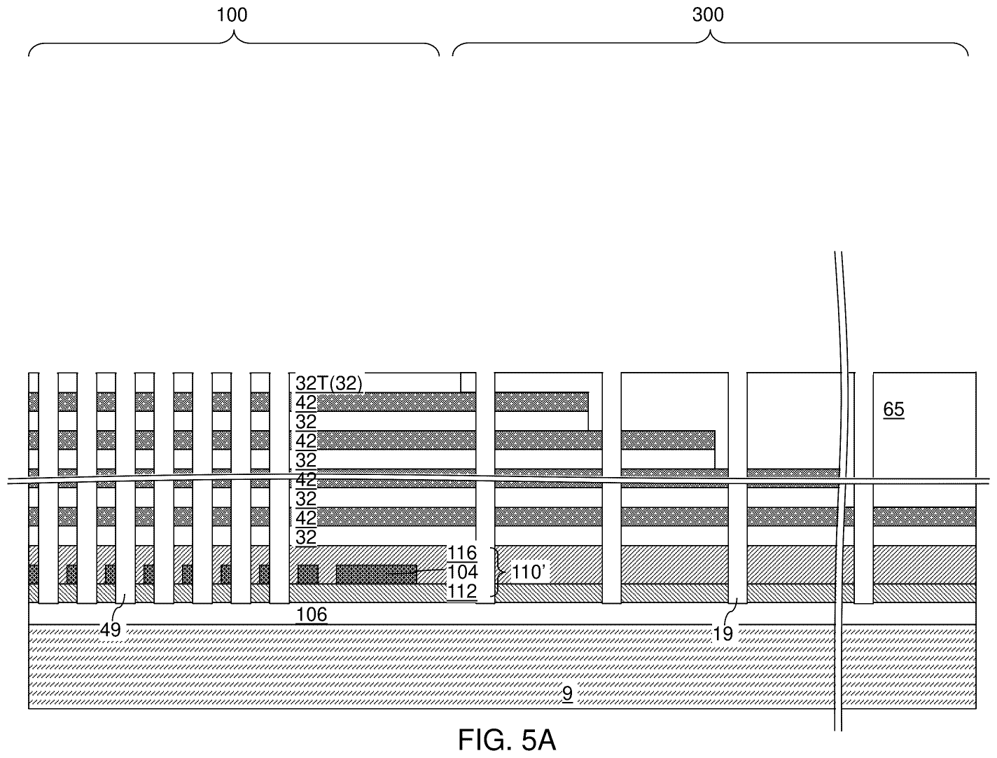

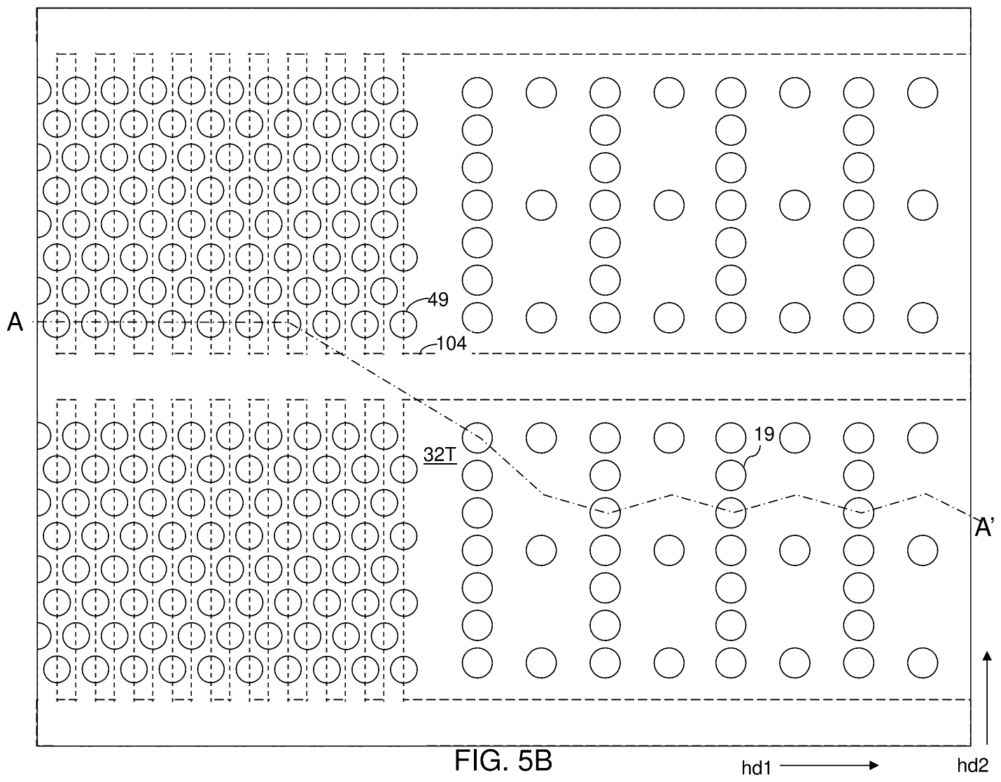

Referring to FIGS. 5A and 5B, an etch mask layer (not shown) can be formed over the alternating stack (32, 42), and can be lithographically patterned to form various openings therein. An anisotropic etch process can be performed to transfer the pattern of the openings in the etch mask layer through the alternating stack (32, 42). Various openings can be formed through the alternating stack (32, 42). The various openings may comprise memory openings 49 that are formed in the memory array region 100 and support openings 19 that are formed in the contact region 300. Each of the memory openings 49 and the support openings 19 can vertically extend through the alternating stack (32, 42) and into the in-process source-level material layers 110′. In one embodiment, bottom surfaces of the memory openings 49 and the support openings 19 may be formed within the lower source-level semiconductor layer 112 or at an interface between the lower source-level semiconductor layer 112 and the stopper insulating layer 106.

In one embodiment, each of the memory openings 49 may cut through an edge region of a respective one of the multiple source-level sacrificial material rails of the source-level sacrificial layer 104. In one embodiment, a horizontally-concave and vertically-straight surface segment of a respective one of the multiple source-level sacrificial material rails can be physically exposed to each memory opening 49. In one embodiment, each cluster of memory openings 49 may be formed as multiple rows of memory openings 49 that laterally extend along the first horizontal direction hd1. The periodicity of the memory openings 49 (such as a center-to-center distance between each neighboring pair of memory openings 49) may be the same as the periodicity of the source-level sacrificial material rails of the source-level sacrificial layer 104 along the first horizontal direction hd1. In one embodiment, each source-level sacrificial material rail of the source-level sacrificial layer 104 may comprise two sets of horizontally-concave and vertically-straight surface segments that are arranged along the second horizontal direction hd2. Each set of horizontally-concave and vertically-straight surface segments can be located on a respective lengthwise sidewall of a source-level sacrificial material rail of the source-level sacrificial layer 104. As used herein, a horizontally-concave and vertically-straight surface segment refers to a surface segment having a concave profile in a horizontal cross-sectional view and having a straight profile in a vertical cross-sectional view.

The support openings 19 may have a diameter in a range from 60 nm too 400 nm, such as from 120 nm to 300 nm, although lesser and greater thicknesses may be employed. The memory openings 49 may have a diameter in a range from 60 nm too 400 nm, such as from 120 nm to 300 nm, although lesser and greater thicknesses may be employed.

In one embodiment, the memory array region 100 may be laterally spaced apart from the contact region 300 along a first horizontal direction (e.g., word line direction) hd1. The memory openings 49 may comprise rows of memory openings 49 that are arranged along the first horizontal direction hd1 and laterally spaced apart along a second horizontal direction (e.g., bit line direction) hd2 that is perpendicular to the first horizontal direction hd2. Multiple clusters of memory openings 49, each containing a respective two-dimensional periodic array of memory openings 49, may be formed in the memory array region 100. The clusters of memory openings 49 may be laterally spaced apart along the second horizontal direction hd2.

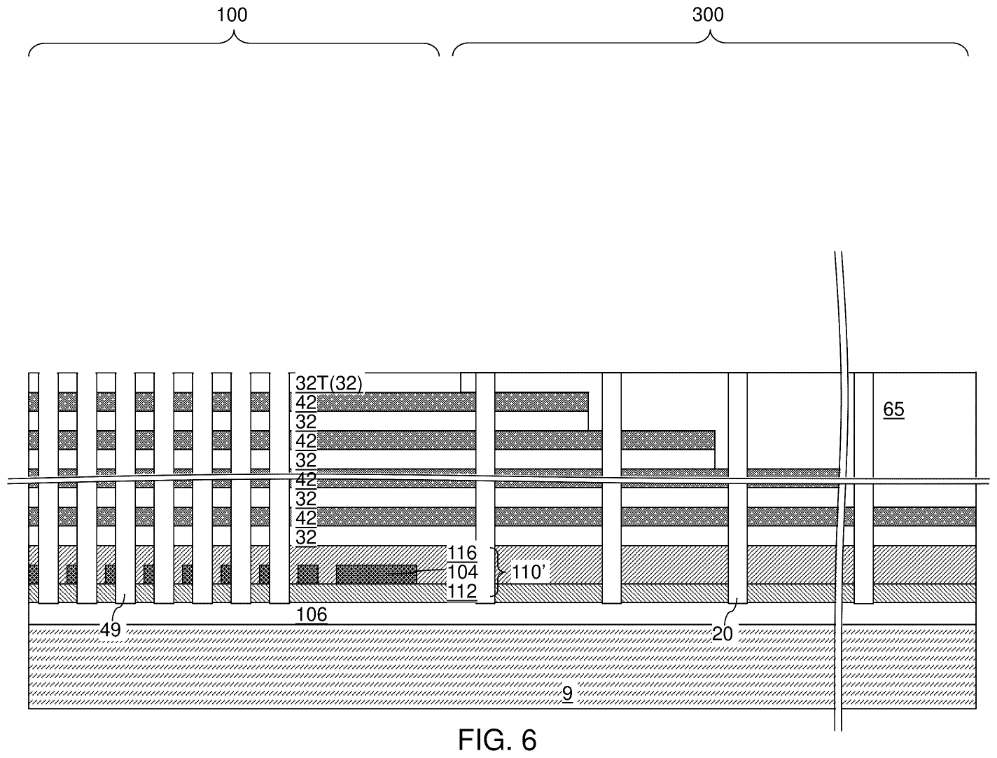

Referring to FIG. 6, an optional etch stop liner (not shown) and an optional sacrificial fill material (not shown) can be deposited in the memory openings 49 and the support openings. The optional etch stop liner (if present) comprises a thin dielectric material layer comprising silicon oxide, silicon nitride, or a dielectric metal oxide and having a thickness in a range from 1 nm to 6 nm. The sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or a polymer material. Excess portions of the sacrificial fill material can be removed from above the horizontal plane including the topmost layer of the alternating stack (32, 42) by a planarization process such as an etch back process. Remaining portions of the sacrificial fill material that fill the memory openings 49 and the support openings 19 constitute sacrificial memory opening fill structures (not shown) and sacrificial support opening fill structures (not shown).

A photoresist layer (not shown) can be applied over the alternating stack (32, 42) and the stepped dielectric material portion 65, and can be lithographically patterned to cover the memory array region 100 without covering the contact region 300. The sacrificial support opening fill structures and portions of the optional etch stop liner in the contact region 300 can be removed selective to the materials of the stepped dielectric material portion 65 and the alternating stack (32, 42). For example, an etch process or an ashing process may be employed to remove the sacrificial support opening fill structures and portions of the optional etch stop liner in the contact region 300. The photoresist layer can be subsequently removed.

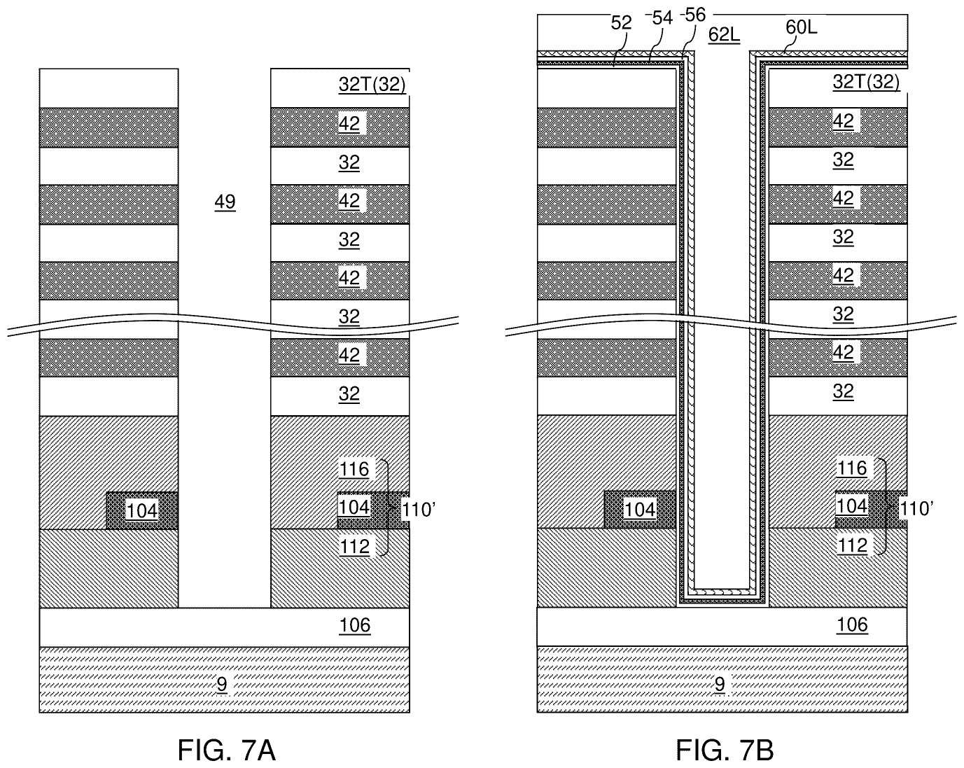

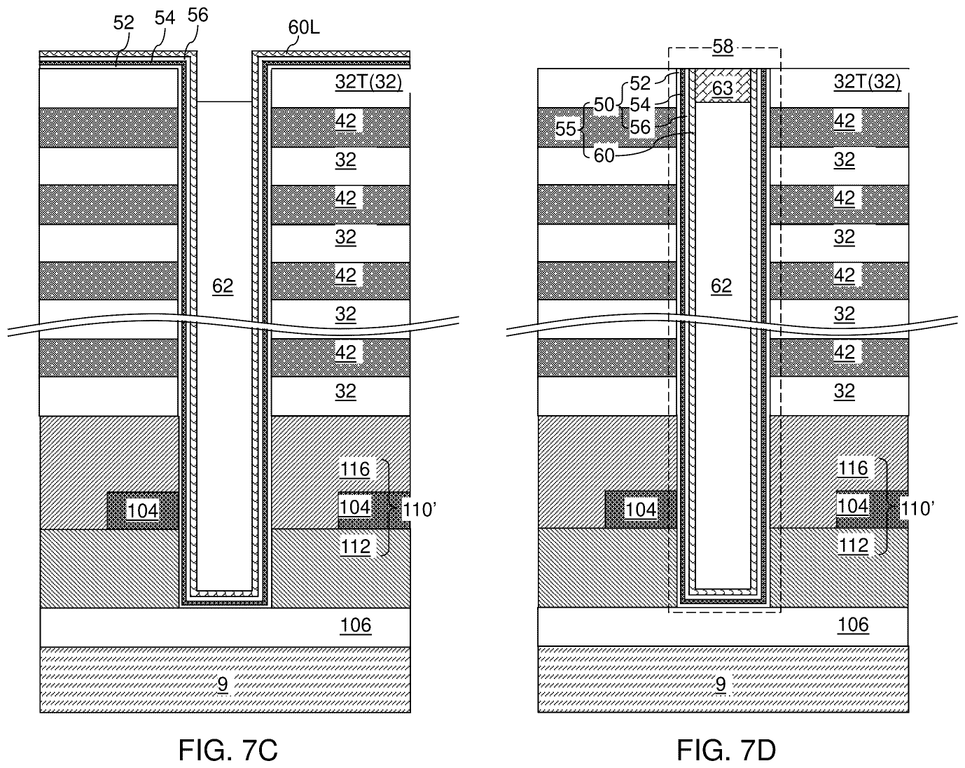

An optional dielectric fill material, such as silicon oxide, can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the stepped dielectric material portion 65 during replacement of the sacrificial material layers 42 with electrically conductive layers. Alternatively, rather than forming separate insulating support pillar structures 20 in the support openings 19, the support pillar structures 20 may be formed in the support openings 19 at the same time as the memory opening fill structures are formed in the memory openings 49, as will be described below with respect to FIGS. 7A-7D.

Subsequently, the sacrificial memory opening fill structures and portions of the optional etch stop liner in the memory array region 100 can be removed selective to the materials of the stepped dielectric material portion 65 and the alternating stack (32, 42). For example, an etch process or an ashing process may be employed to remove the sacrificial memory opening fill structures and portions of the optional etch stop liner in the memory array region 100. Voids are formed in the volumes of the memory openings 49.

FIGS. 7A-7D are sequential vertical cross-sectional views of a memory opening 49 during formation of a memory opening fill structure 58 according to an embodiments of the present disclosure.

Referring to FIG. 7A, a memory opening 49 is illustrated after the processing steps of FIG. 6.

Referring to FIG. 7B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material can be deposited in remaining volumes of the memory openings 49 and over the alternating stack (32, 42).

Referring to FIG. 7C, the dielectric core layer 62L can be vertically recessed such that each remaining portion of the dielectric core layer 62L has a top surface at, or about, the horizontal plane including the bottom surface of the topmost insulating layers 32T. Each remaining portion of the dielectric core layer 62L constitutes a dielectric core 62.

Referring to FIG. 7D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may be comprise portions of the memory material layer 54 located at levels of the sacrificial material layers 42, or generally speaking, at levels of spacer material layers that may be formed as, or may be subsequently replaced at least partly with, electrically conductive layers.

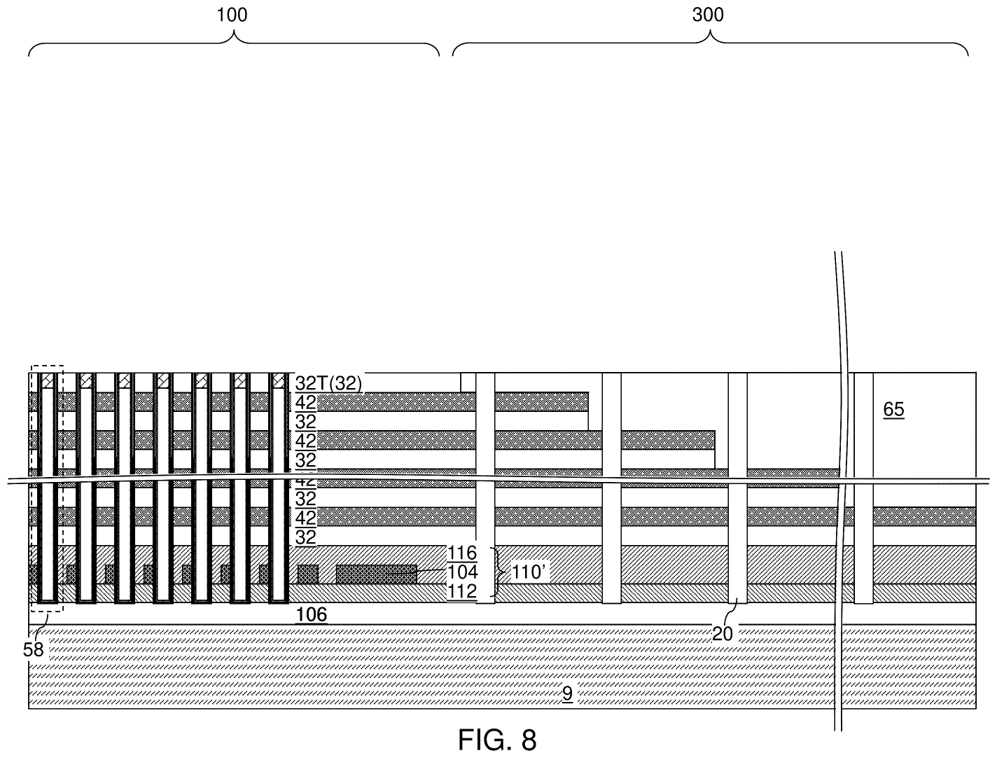

Referring to FIG. 8, the exemplary structure is illustrated after formation of memory opening fill structures 58 within the memory openings 49. Each of the memory opening fill structures 58 may comprise a vertical stack of memory elements (which may comprise portions of a memory material layer 54 located at levels of the sacrificial material layers 42), a vertical semiconductor channel 60, and a dielectric core 62 that is laterally surrounded by the vertical semiconductor channel 60. In the alternative embodiment, the support pillar structures 20 are formed at the same time as the memory opening fill structures 58 and have the same composition as the memory opening fill structures 58.

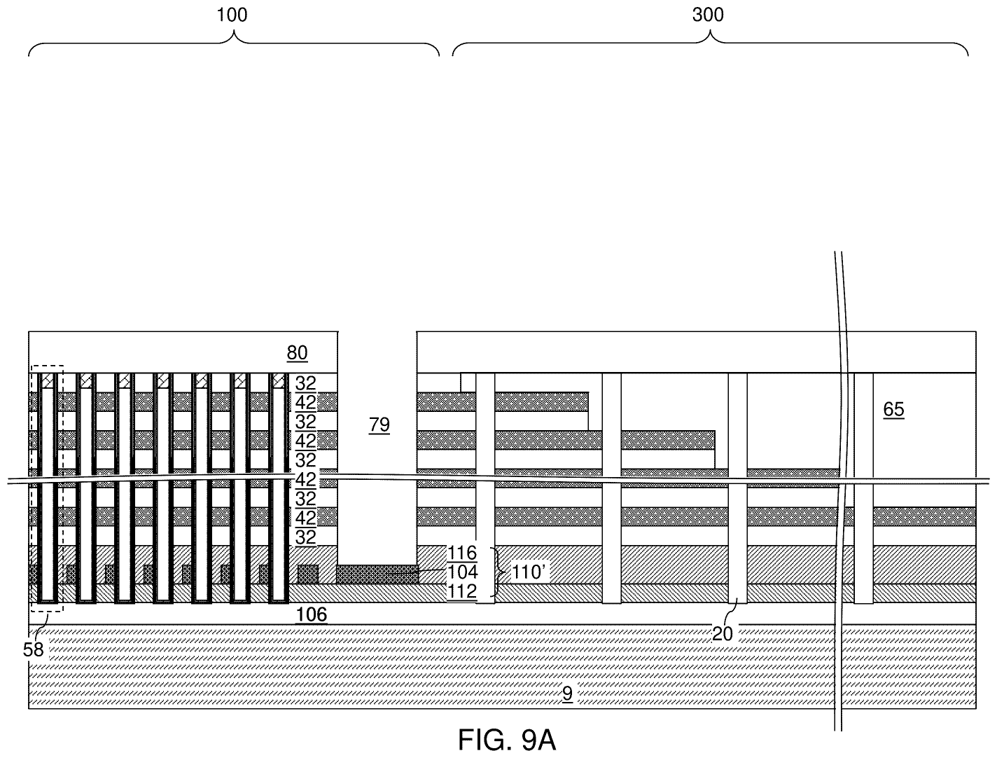

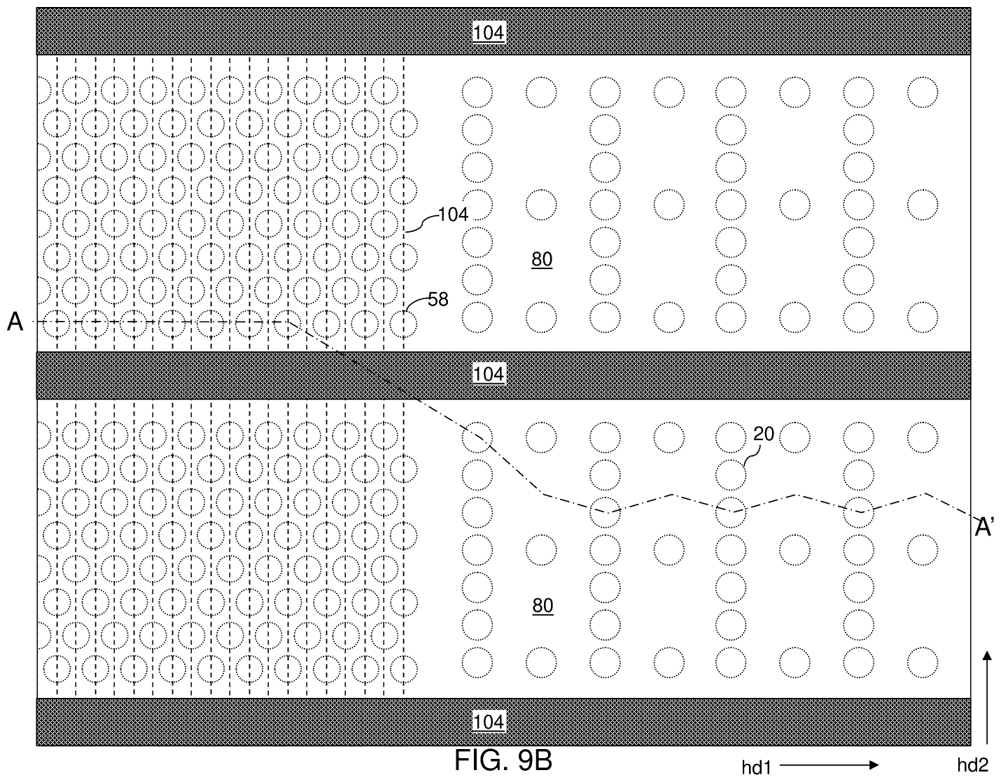

Referring to FIGS. 9A and 9B, a dielectric material, such as undoped silicate glass or a doped silicate glass, can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), the stepped dielectric material portion 65, and an upper portion of the upper source-level semiconductor layer 116. The source-level sacrificial material beams of the source-level sacrificial layer 104 can function as etch stop structures during the anisotropic etch process. Lateral isolation trenches 79 laterally extending along the first horizontal direction hd1 can be formed through the alternating stack (32, 42), the stepped dielectric material portion 65, the contact-level dielectric layer 80, and the in-process source-level material layers 110′. Each of the lateral isolation trenches 79 may comprise a respective pair of lengthwise sidewalls that are parallel to the first horizontal direction hd1 and vertically extend from the stopper insulating layer 106 to the top surface of the contact-level dielectric layer 80. The source-level sacrificial material beams of the source-level sacrificial layer 104 are exposed at the bottom of the lateral isolation trenches 79. The source-level sacrificial material rails of the source-level sacrificial layer 104 are covered by an overlying portion of the upper source-level semiconductor layer 116, and thus, are not exposed to the lateral isolation trenches 79.

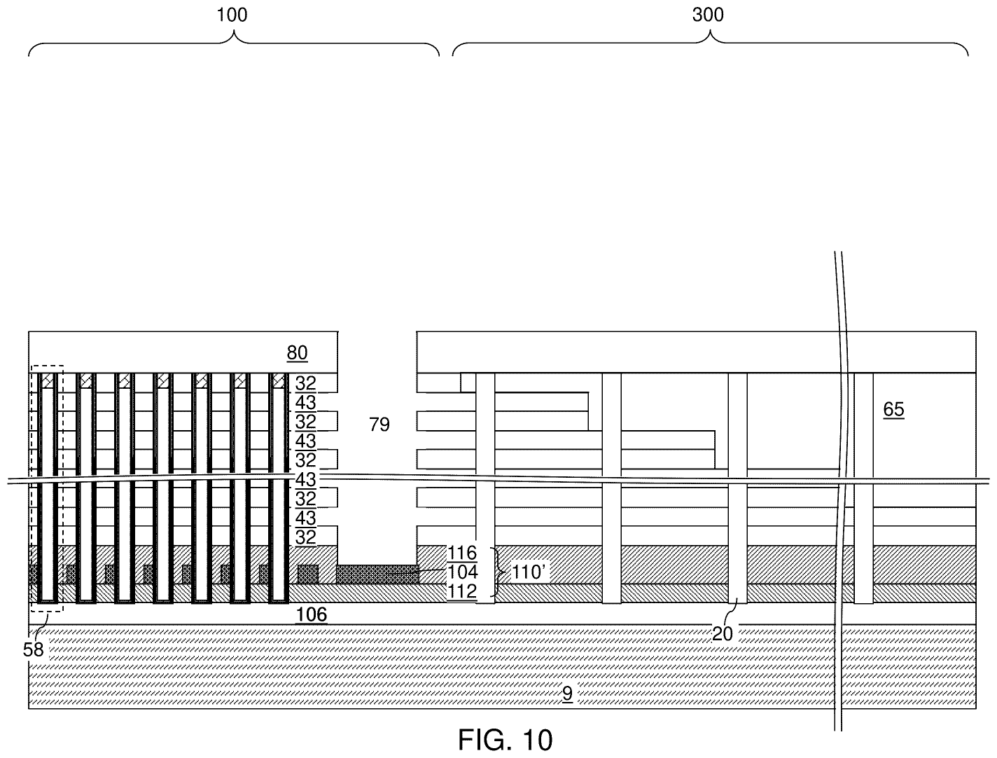

Referring to FIG. 10, an isotropic etch process can be performed to remove the sacrificial material layers 42 selective to the insulating layers 32, the memory opening fill structures 58, and the upper source-level semiconductor layer 116. Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon nitride, the isotropic etch process may comprise a wet etch process employing hot phosphoric acid. Since the upper source-level semiconductor layer 116 comprises undoped polysilicon or amorphous silicon, it is not significantly etched by hot phosphoric acid. This prevents damage to the in-process source-level material layers 110′ and undesirable removal of the source-level sacrificial layer 104 at this point in the process.

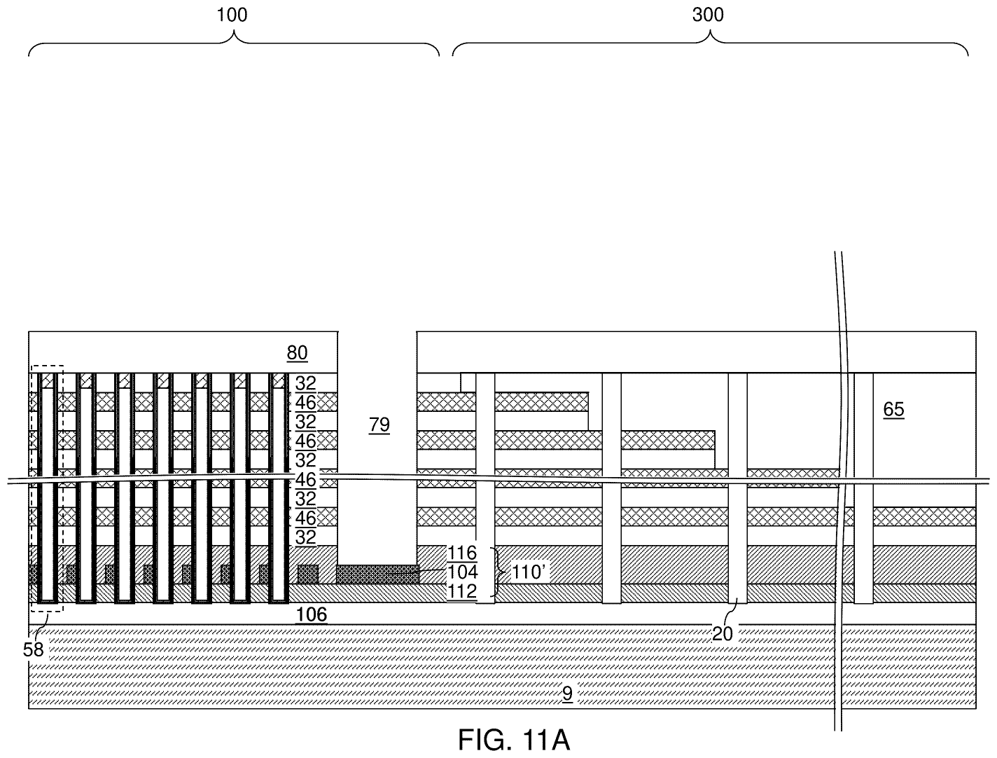

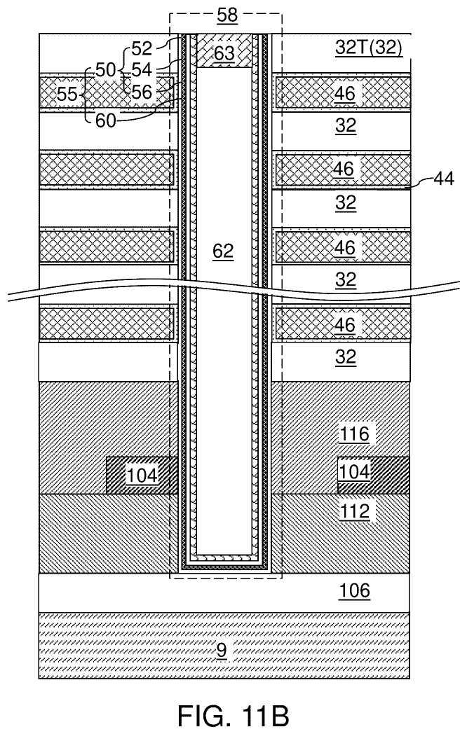

Referring to FIGS. 11A and 11B, a backside blocking dielectric layer 44 can be optionally formed in the laterally-extending cavities 43 by a conformal deposition process. At least one conductive material, such as at least one metallic material, can be conformally deposited in the laterally-extending cavities 43. The at least one conductive material may comprise, for example, a combination of a metallic barrier material and a metallic fill material. The metallic barrier material may comprise, for example, TiN, TaN, WN, MON, TiC, TaC, WC, or a combination thereof. The metallic fill material may comprise, for example, Ti. Ta, Mo, Co, Ru, W, Cu, other transition metals, and/or alloys or layer stacks thereof. Excess portions of the at least one conductive material that are deposited in the lateral isolation trenches 79 or above the contact-level dielectric layer 80 can be removed by performing an etch-back process, which may comprise an isotropic etch process and/or an anisotropic etch process.

Each remaining portion of the at least one conductive material filling a respective one of the laterally-extending cavities 43 constitutes an electrically conductive layer 46. In case the at least one conductive material comprises a combination of a metallic barrier material and a metallic fill material, each electrically conductive layer 46 may comprise a combination of a metallic barrier liner (not separately shown) and a metallic fill material portion (not separately shown). An alternating stack of insulating layers 32 and electrically conductive layers 46 can be formed between each neighboring pair of lateral isolation trenches 79 over the carrier substate 9. A plurality of alternating stacks of insulating layers 32 and electrically conductive layers 46 can be laterally spaced apart among one another by the lateral isolation trenches 79.

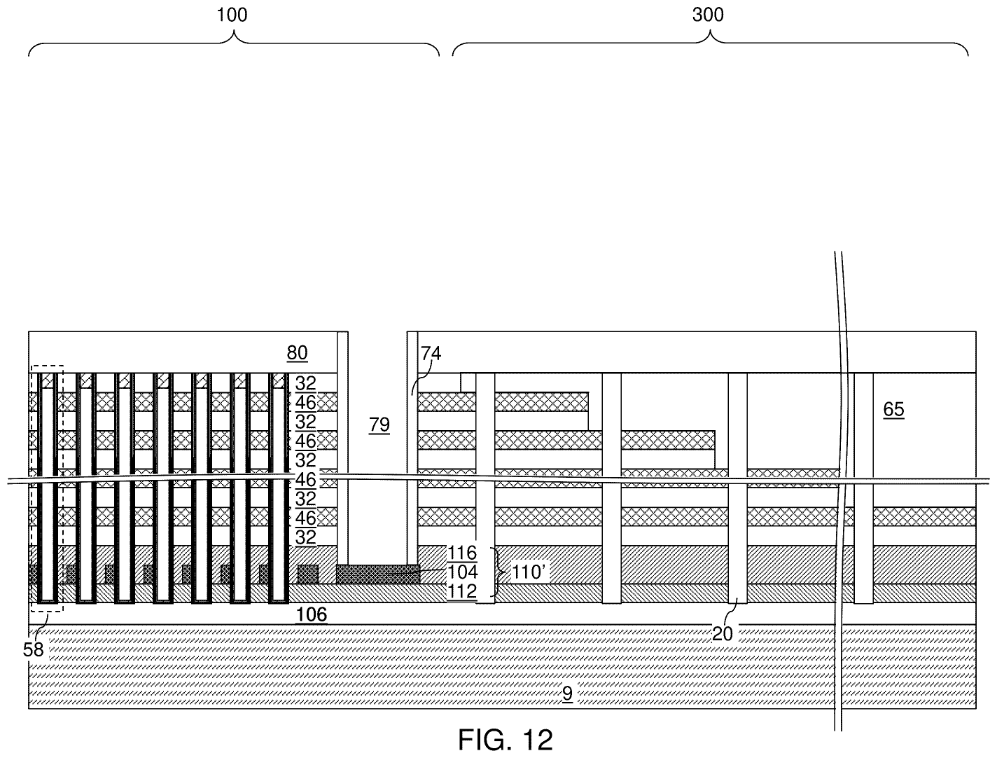

Referring to FIG. 12, an insulating material, such as silicon oxide, can be conformally deposited in peripheral regions of the lateral isolation trenches 79 and above the contact-level dielectric layer 80. An anisotropic etch process can be performed to remove horizontally-extending portions of the insulating material. Each remaining vertically-extending tubular portion of the insulating material located within a respective one of the lateral isolation trenches 79 constitutes an insulating spacer 74.

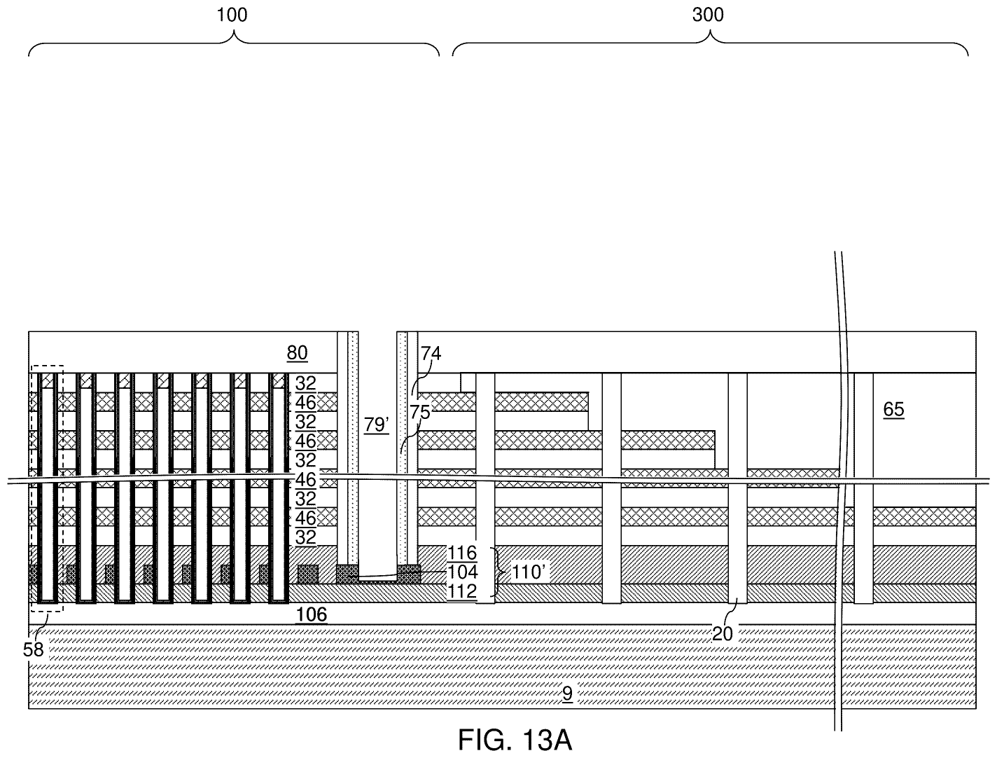

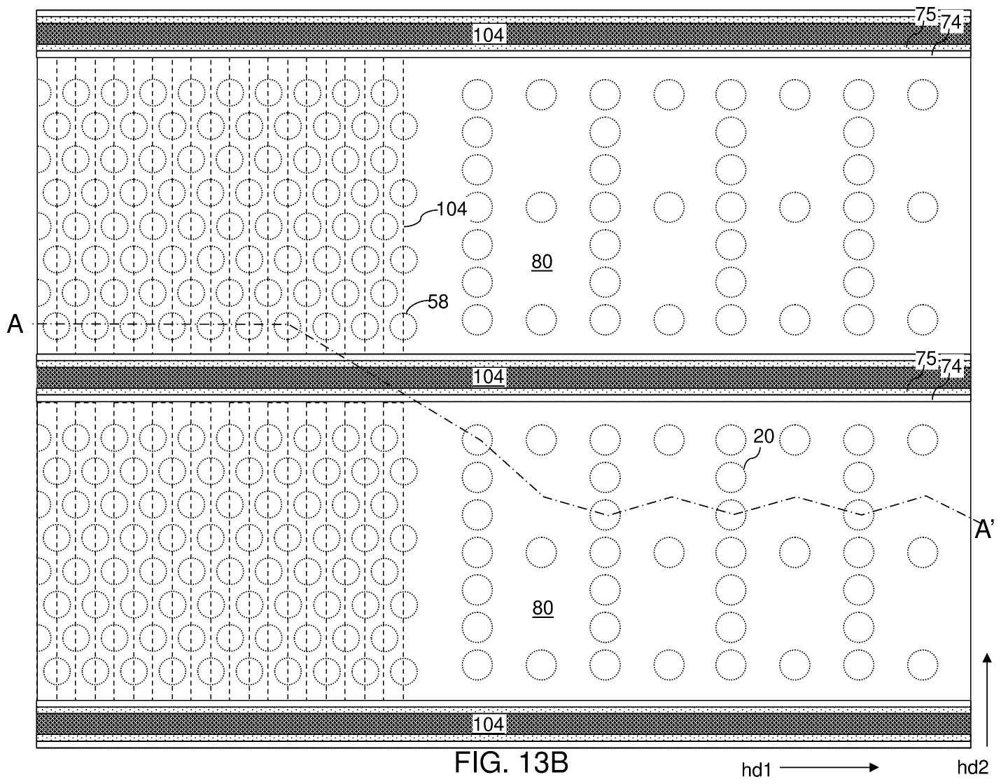

Referring to FIGS. 13A and 13B, a sacrificial spacer material that can function as an etch mask during subsequent isotropic etch processes can be conformally deposited in unfilled volumes of the lateral isolation trenches 79. The sacrificial spacer material can be a material that is different from the materials of the source-level sacrificial layer 104 and the dielectric cores 62. For example, if the source-level sacrificial layer 104 comprises silicon nitride and if the dielectric cores 62 comprise silicon oxide, then the sacrificial spacer material may comprise silicon carbonitride. An anisotropic etch process can be performed to remove horizontally-extending portions of the sacrificial spacer material. Each remaining tubular portion of the sacrificial spacer material constitutes a sacrificial trench spacer 75.

In one embodiment, the anisotropic etch process may be extended, with a change in the etch chemistry, to etch an upper portion the source-level sacrificial layer 104, and selective to the material of the lower source-level material layer 112. In case the anisotropic etch process etches the material of the source-level sacrificial layer 104, unmasked portions of the source-level sacrificial material rails of the source-level sacrificial layer 104 may be etched underneath lateral isolation cavities 79′, which are unfilled volumes of the lateral isolation trenches 79. Generally, sidewalls of the remaining portions of the source-level sacrificial material rails of the source-level sacrificial layer 104 can be physically exposed underneath the lateral isolation cavities 79′.

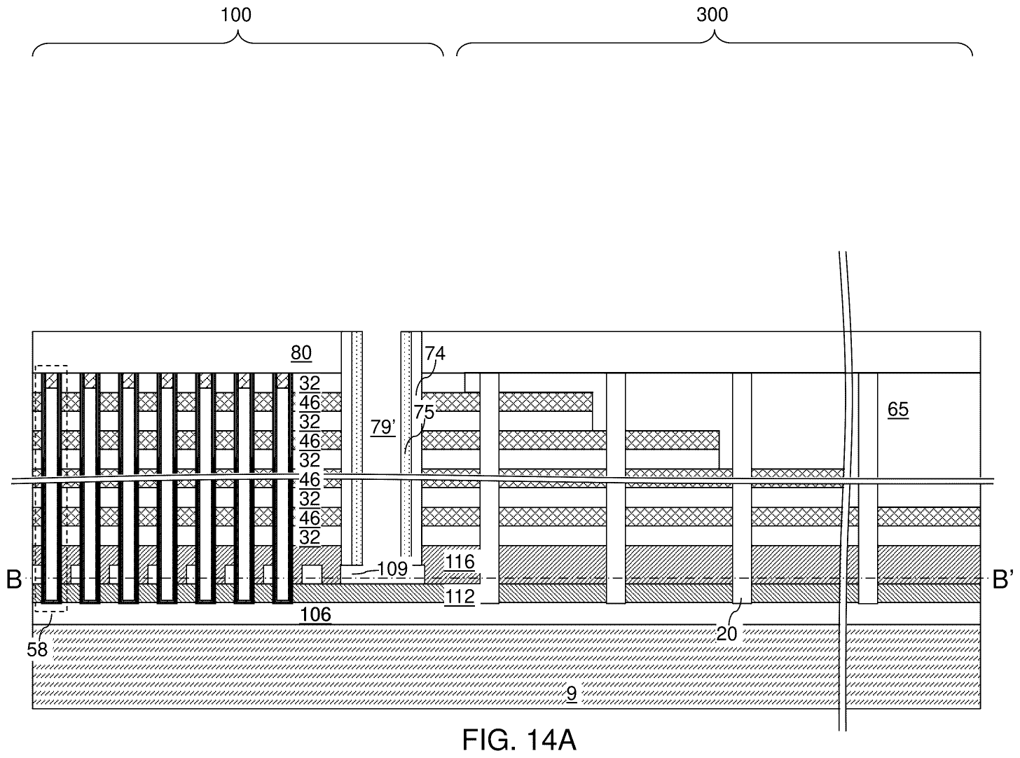

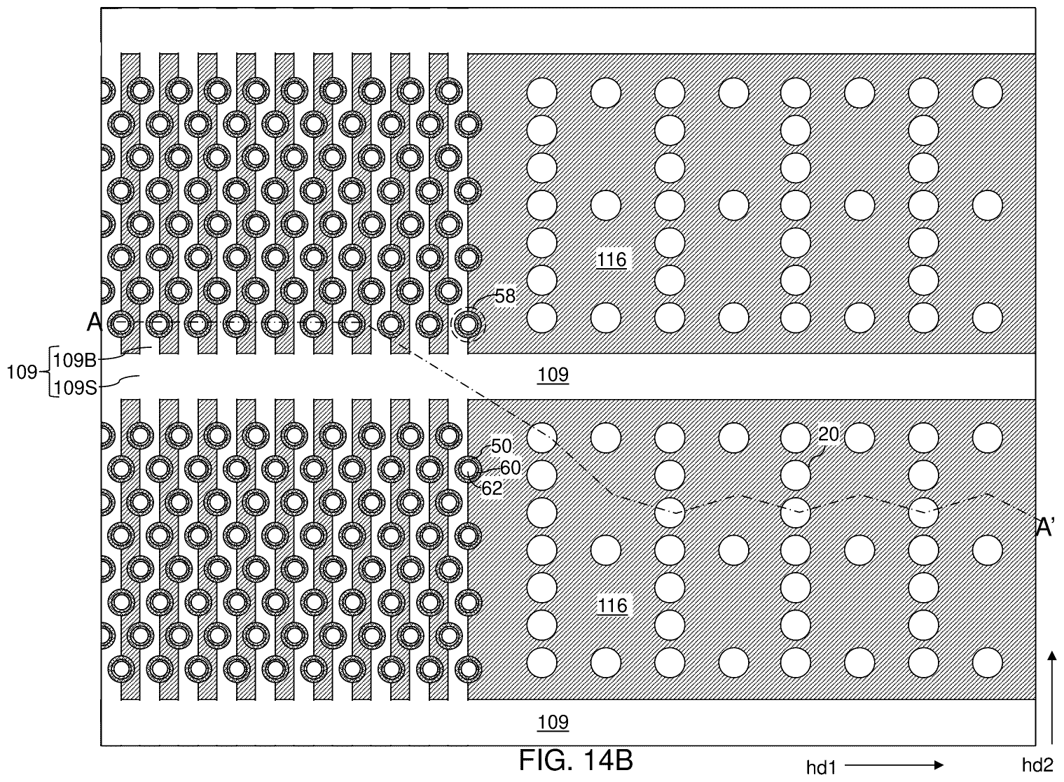

Referring to FIGS. 14A and 14B, a first isotropic etch process can be performed to etch the material of the source-level sacrificial layer 104 selective to materials of the lower source-level semiconductor layer 112, the upper source-level semiconductor layer 116, the contact-level dielectric layer 80, and the sacrificial trench spacers 75. In an illustrative example, if the multiple source-level sacrificial material rails of the source-level sacrificial layer 104 comprise silicon nitride, a wet etch process employing hot phosphoric acid can be performed to remove the source-level sacrificial material rails of the source-level sacrificial layer 104.

A source cavity 109 is formed underneath a horizontal plane including bottom surfaces of the sacrificial trench spacers 75. The source cavity 109 comprises an interconnected network of cavities, or cavity segments, located at the source level, i.e., at the levels between the lower source-level semiconductor layer 112 and the upper source-level semiconductor layer 116. In one embodiment shown in FIG. 14B, the source cavity 109 comprises stem portions 109S that underlie a respective one of the laterally-extending cavities 79′ and laterally extending along the first horizontal direction hd1, and branch portions 109B that laterally extend along the second horizontal direction hd2 and intersect the stem portions. The second horizontal direction hd2 is different from the first horizontal direction hd1, and may be perpendicular to the first horizontal direction hd1. Two columns of memory opening fill structures 58 may be exposed to a branch portion 109B of the source cavity 109 which is not an outermost branch portion.

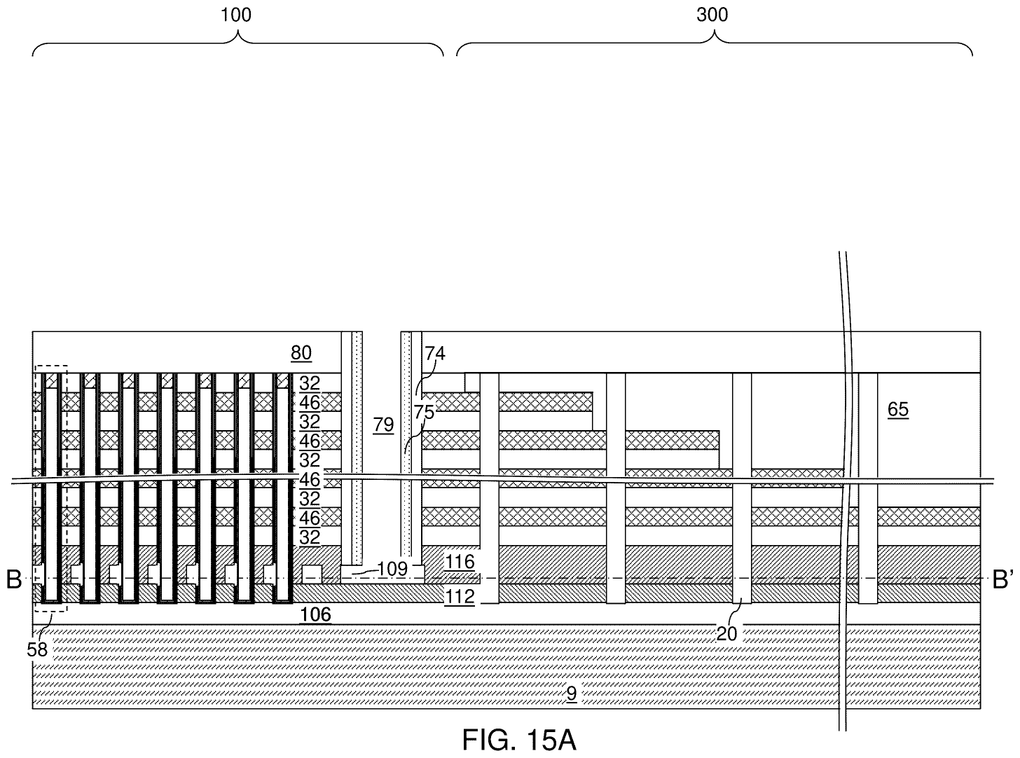

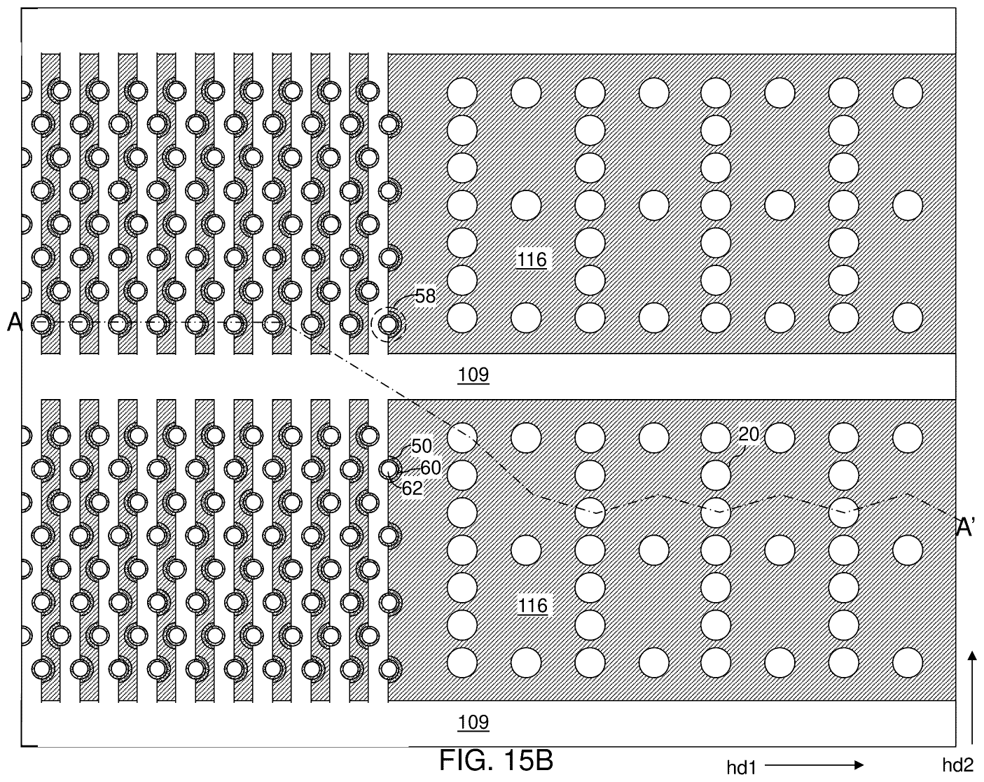

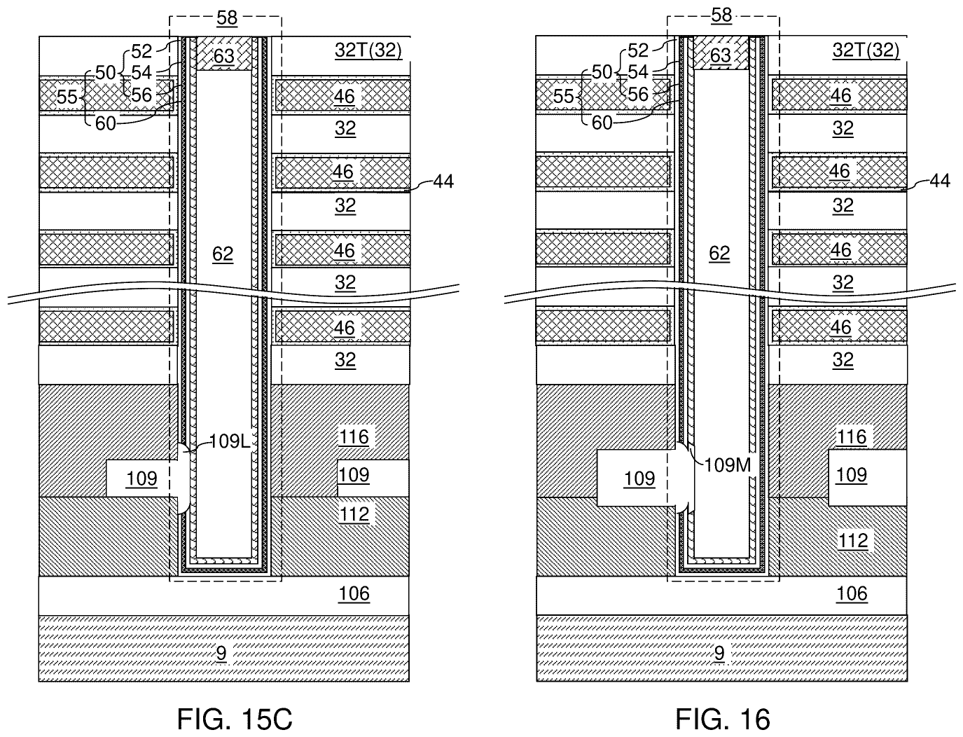

Referring to FIGS. 15A-15C, a second isotropic etch process can be performed to remove portions of the memory films 50 that are proximal to the source cavity 109. The second isotropic etch process can comprise a sequence of isotropic etch steps that etches various layers of each memory film 50 from outside to inside. For example, the second isotropic etch process may comprise a first isotropic etch step that etches the material of the blocking dielectric layers 52, a second isotropic etch step that etches the material of the memory material layers 54, and a third isotropic etch step that etches the material of the dielectric liner 56. A first lateral opening 109L is formed through a bottom portion of each memory film 50 such that each vertical semiconductor channel 60 comprises an outer surface segment that is exposed to the source cavity 109 (e.g., to the branch portion 109B of the source cavity 109). Within each memory opening fill structure 58, each of the blocking dielectric layer 52, the memory material layer 54, and the dielectric liner 56 may have a respective opening that is exposed to the source cavity 109.

Referring to FIG. 16, a third isotropic etch process can be performed to isotropically etch the material of the vertical semiconductor channels 60. For example, if the vertical semiconductor channels 60 comprise polysilicon, the third isotropic etch process may comprise a wet etch process using hot trimethyl-2 hydroxyethyl ammonium hydroxide (“hot TMY”) or tetramethyl ammonium hydroxide (TMAH). A second lateral opening 109M can be formed through a bottom region of a vertically-extending portion of each vertical semiconductor channel 60. Each of the dielectric cores 62 may have a sidewall segment that is physically exposed to the source cavity 109. The height of the source cavity 109 may be increased during the third isotropic etch process.

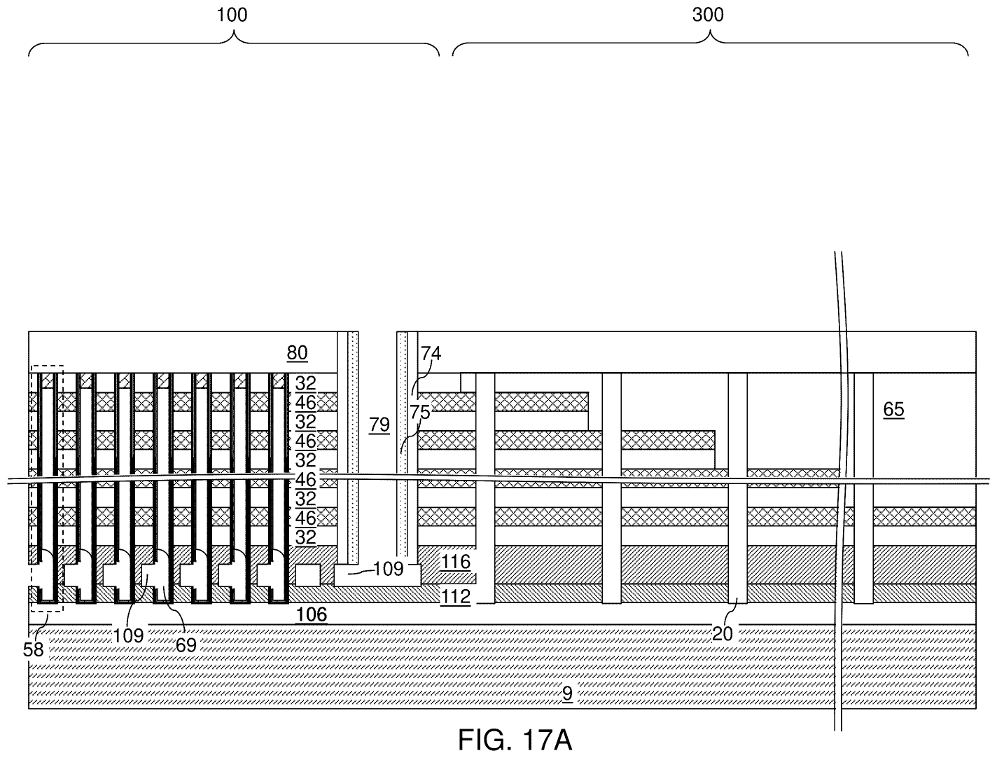

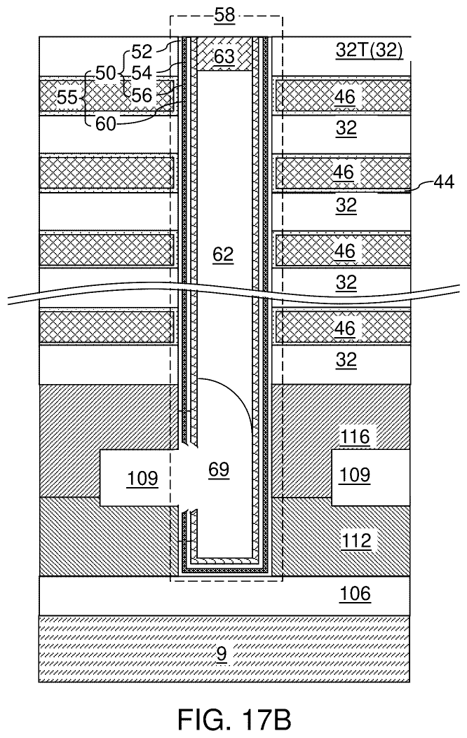

Referring to FIGS. 17A and 17B, a fourth isotropic etch process can be performed to isotropically etch the material of the dielectric cores 62 selective to materials of the lower source-level semiconductor layer 112, the upper source-level semiconductor layer 116, and the sacrificial trench spacers 75. An isotropic etchant can be provided to each of the dielectric cores 62 through the source cavity 109 and the lateral openings in the vertical semiconductor channels 60. In an illustrative example, the fourth isotropic etch process may comprise a wet etch process employing dilute hydrofluoric acid. The top surface of the contact-level dielectric layer 80 and top surfaces of the insulating spacers 74 may be collaterally recessed during the fourth isotropic etch process.

The duration of the fourth isotropic etch process can be selected such that the etch distance of the fourth isotropic etch process for the material of the dielectric cores 62 (which may comprise silicon oxide) is greater than the maximum lateral dimension (such as a diameter) of a bottom portion of each dielectric core 62. In one embodiment, the duration of the fourth isotropic etch process can be selected such that the entirety of the portion of each dielectric core 62 that underlies the horizontal plane including physically exposed horizontal surfaces of the upper source-level dielectric layer 116 is removed by the fourth isotropic etch process.

Further, in one embodiment, each remaining portion of the dielectric core 62 may have a lopsided shape having a respective concave tapered bottom surface. The respective concave tapered bottom surface vertically protrudes downward further on a side that is distal from a lateral opening of the vertical semiconductor channel 60 within the same memory opening fill structure 58 than on a side that is proximal to the lateral opening of the vertical semiconductor channel 60. In other words, each dielectric core 62 may have a lopsided bottom portion so that each dielectric core 62 has a lesser vertical extent on a side that is proximal to the lateral opening in the vertical semiconductor channel 60 than on a side that is distal from the lateral opening in the vertical semiconductor channel 60. A core cavity 69 is formed within each volume from which the material of a respective dielectric core 62 is removed. Each core cavity 69 is connected to the source cavity 109 through a lateral opening in a memory stack structure 55. Generally, the source cavity 109 can be expanded into each memory opening fill structure 58 to form core cavities 69, and to physically expose a segment of an inner sidewall of each vertical semiconductor channel 60. In one embodiment, the top of the core cavity 69 may be located below the bottommost electrically conductive layer 46 (e.g., a source side select gate electrode) as shown in FIG. 17B. In an alternative embodiment, the top of the core cavity 69 may be located at the level of the bottommost electrically conductive layer 46.

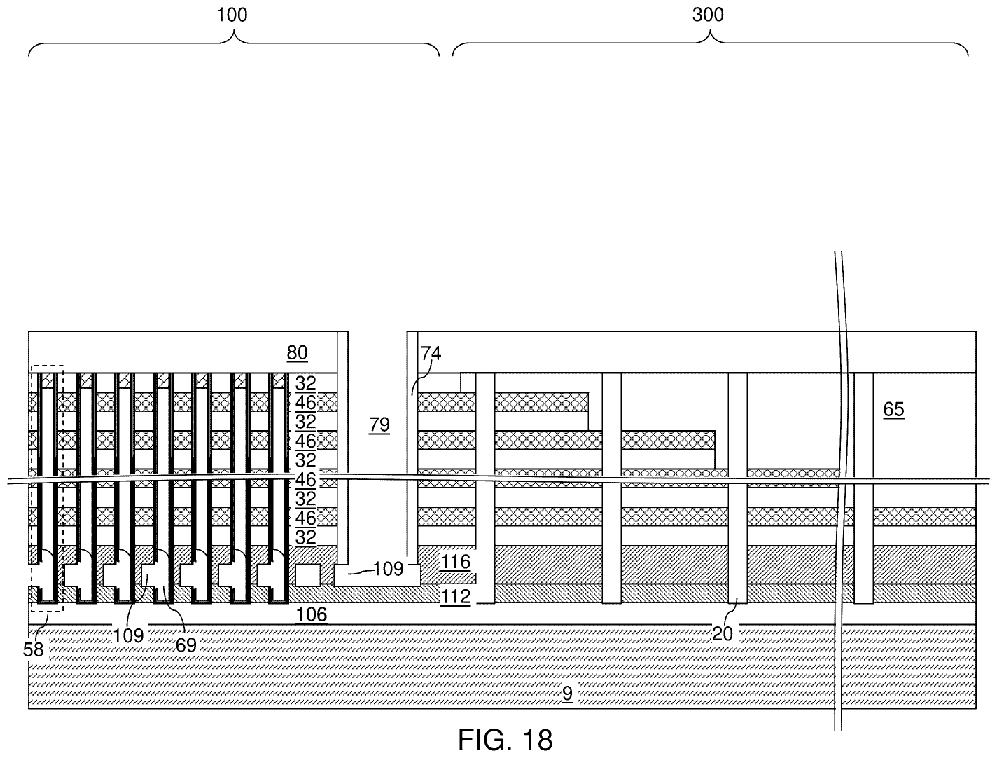

Referring to FIG. 18, the sacrificial trench spacers 75 may be converted to silicon oxide or removed by selective etching. For example, if the sacrificial trench spacers 75 comprise silicon carbonitride, then an ashing process in an oxygen plasma may be performed to convert silicon carbonitride into silicon oxide, and thus merge the sacrificial trench spacers 75 into the silicon oxide insulating spacers 74.

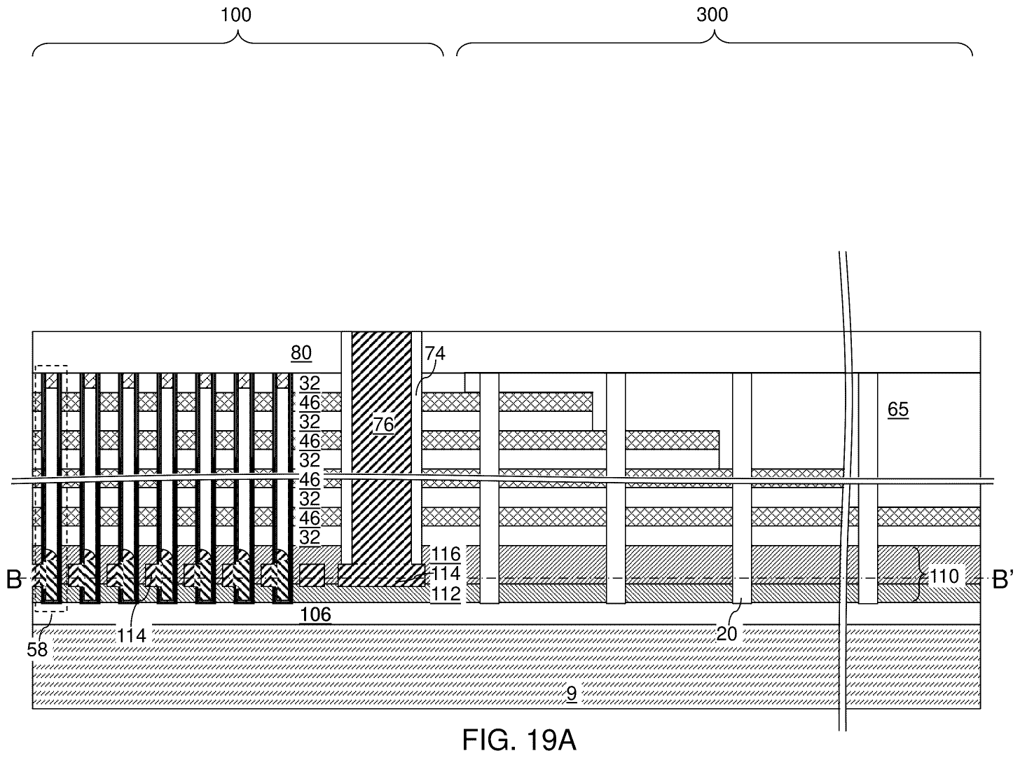

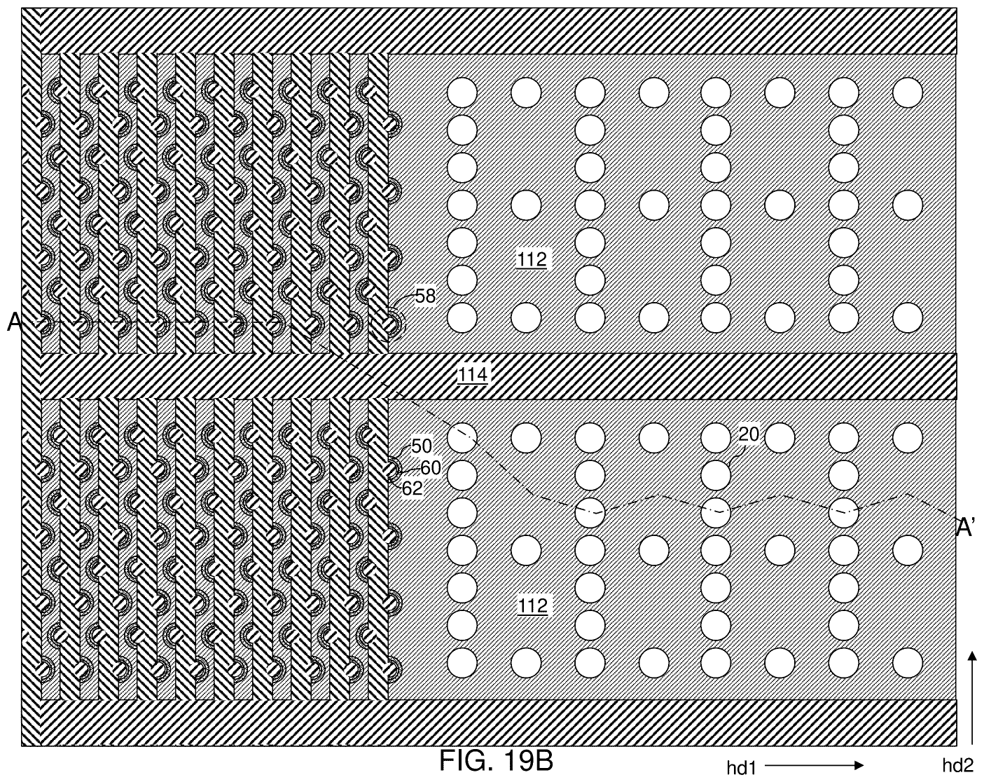

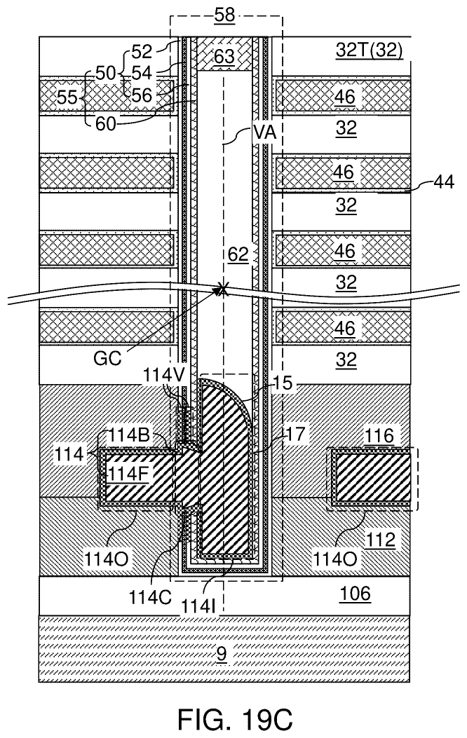

Referring to FIGS. 19A-19C, at least one conductive material can be conformally deposited in the core cavities 69, in the source cavity 109, in the lateral isolation trenches 79, and above the contact-level dielectric layer 80. The conformal deposition may comprise at least one chemical vapor deposition process and/or at least one atomic layer deposition process. The at least one conductive material may comprise a heavily doped semiconductor material having a doping of the second conductivity type, and/or at least one metallic material. In one embodiment, the at least one conductive material comprises a combination of a metallic barrier material (such as a conductive metallic nitride or a conductive metallic carbide), and a metallic fill material such as a metal or an intermetallic alloy. For example, the at least one conductive material comprises a TiN barrier layer and a tungsten fill layer surrounded by the TiN barrier layer.

Excess portions of the at least one conductive material can be removed from above the horizontal plane including the top surface of the contact-level dielectric layer 80 by a planarization process. The planarization process may comprise a chemical mechanical polishing process and/or a recess etch process. A remaining portion of the at least one conductive material that fills the core cavities 69 and the source cavity 109 constitutes a source contact layer 114. Each remaining portion of the at least one conductive material that fills a respective lateral isolation trench 79 constitutes a source contact via structure (e.g., source electrode or local interconnect) 76. Each source contact via structure 76 can be laterally surrounded by a respective insulating spacer 74, and is adjoined to the source contact layer 114 at a horizontal plane including the bottom surface of the respective insulating spacer 74. A continuous conductive material layer (which may comprise a heavily doped semiconductor portion and/or a metallic material portion) continuously extends through the source contact layer 114 and each of the source contact via structures 76. For example, the source contact layer 114 and each of the source contact via structures 76 may comprise a TiN barrier layer and a tungsten fill layer surrounded by the TiN barrier layer. The use of a metallic material, such as a TiN/W bilayer, can generate a higher erase current than a doped semiconductor material. Thus, erasing of the vertical NAND strings (i.e., the memory opening fill structures 58) by gate induced leakage hole injection from the source contact layer 114 into the vertical semiconductor channels 60 is improved by the higher erase current. Thus, a lower number of source side select gate electrodes may be used in the memory device without significantly negatively affecting the erase operation.

The combination of the lower source-level semiconductor layer 112, the upper source-level semiconductor layer 116, and the source contact layer 114 constitutes source-level material layers 110. The source contact layer 114 can be formed in the source cavity 109 over and directly on a segment of the inner sidewall of each vertical semiconductor channel 60. In one embodiment, each inner portion 1141 of the source contact layer 114 can be in contact with a segment of an inner sidewall of a respective vertical semiconductor channel 60, as shown in FIG. 19C.

In one embodiment shown in FIG. 19C, the source contact layer 114 includes an outer portion 1140 located outside the volumes of the memory openings 49, and inner portions 1141 that are located within the volumes of the memory openings 49. The outer portion 1140 of the source contact layer 114 may comprise stem portions that laterally extend along the first horizontal direction hd1 and multiple branch portions that laterally extend along the second horizontal direction hd2 that is different from (e.g., perpendicular to) the first horizontal direction hd1. The stem portions of the source contact layer 114 are not in direct contact with the memory opening fill structures 58, and the branch portions of the source contact layer 114 are in direct contact with the memory opening fill structures 58. Generally, each of the memory opening fill structures 58 comprises a respective vertical semiconductor channel 60 that contacts a respective branch portion of the source contact layer 114.

In one embodiment, each inner portion 1141 of the source contact layer 114 may be located inside the vertical semiconductor channel 60 of a respective memory opening fill structure 58. Therefore, each inner portion 1141 of the source contact layer 114 may be more proximal to a vertical axis VA passing through the geometrical center GC of the volume of the memory opening 49 in which the inner portion 1141 is located than an inner sidewall of the vertical semiconductor channel 60 within the memory opening 49 is to the vertical axis VA. In one embodiment, the outer portion 1140 of the source contact layer 114 and each inner portion 1141 of the source contact layer 114 can be interconnected to each other by a respective interconnection portion 114C of the source contact layer 114 that is located within a lateral opening through a respective one of the vertical semiconductor channels 60.

In one embodiment, each memory opening fill structure 58 comprises a dielectric liner 56 that is interposed between a vertical semiconductor channel 60 and a vertical stack of memory elements (e.g., portions of the memory film 54). An interconnection portion 114C of the source contact layer 114 extends through a lateral opening in the dielectric liner 56. In one embodiment, each memory opening fill structure 58 comprises a blocking dielectric layer 52 that is interposed between the vertical stack of memory elements and the alternating stack (32, 46) of insulating layers 32 and electrically conductive layers 46. An interconnection portion 114C of the source contact layer 114 extends through a lateral opening in the blocking dielectric layer 52.

In one embodiment, each inner portion 1141 of the source contact layer 114 comprises a lower cylindrical segment 17 and an upper tapered segment 15 having a tapered convex surface. The lower cylindrical segment 17 of the inner portion 1141 of the source contact layer 114 can contact an inner sidewall of a vertical semiconductor channel 60. The upper tapered segment 15 of the inner portion 1141 of the source contact layer 114 contacts a tapered concave sidewall of a dielectric core 62.

In one embodiment, the memory opening fill structure 58 comprises a dielectric core 62 that extends vertically through each electrically conductive layer 46 within the alternating stack (32, 46) and has a lopsided bottom portion so that the dielectric core 62 has a lesser vertical extent on a side that is proximal to the outer portion 1140 of the source contact layer 114 than on a side that is distal from the outer portion 1140 of the source contact layer 114. In one embodiment, the lopsided bottom portion of the dielectric core 62 has a concave tapered bottom surface that overlies a convex tapered top surface of the upper tapered segment 15 of the inner portion 1141 of the source contact layer 114. In one embodiment, the concave tapered bottom surface of the lopsided bottom portion of the dielectric core 62 is in contact with the convex tapered top surface of the inner portion 1141 of the source contact layer 114.

In one embodiment, the source contact layer 114 may be formed by deposition of a combination of a metallic barrier material and a metallic fill material. In this case, the source contact layer 114 may include a source contact metallic barrier layer 114B comprising a conducive metallic nitride (such as TiN, TaN, WN, or MoN) or a conductive metallic carbide (such as TiC. TaC, or WC), and a source contact fill material layer 114F comprising a metal (such as Ti, Ta, W, Co, Ru, Mo, Cu, alloys thereof, or a combination thereof) and embedded within the source contact metallic barrier layer 114B.

In one embodiment, each memory opening fill structure 58 comprises a dielectric liner 56 that is interposed between a vertical stack of memory elements and a vertical semiconductor channel 60, and the source contact layer 114 comprises a vertically-extending fin 114V that contacts a surface segment of an outer sidewall of the vertical semiconductor channel 60 and contacts a surface segment of the dielectric liner 56, and is located within a volume of a respective memory opening 49.

In one embodiment, the source-level material layers 110 comprise a lower source-level semiconductor layer 112 that underlies the source contact layer 114, and an upper source-level semiconductor layer 116 layer that is interposed between the lower source-level semiconductor layer 112 and alternating stack (32, 46) and embedding the source contact layer 114.

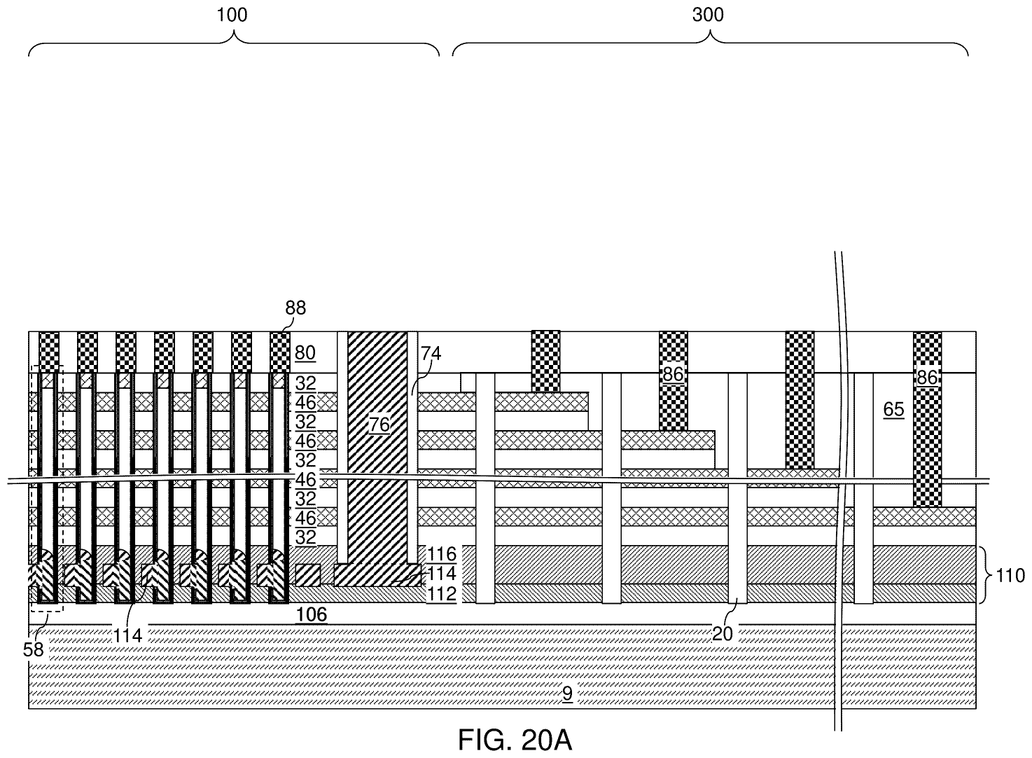

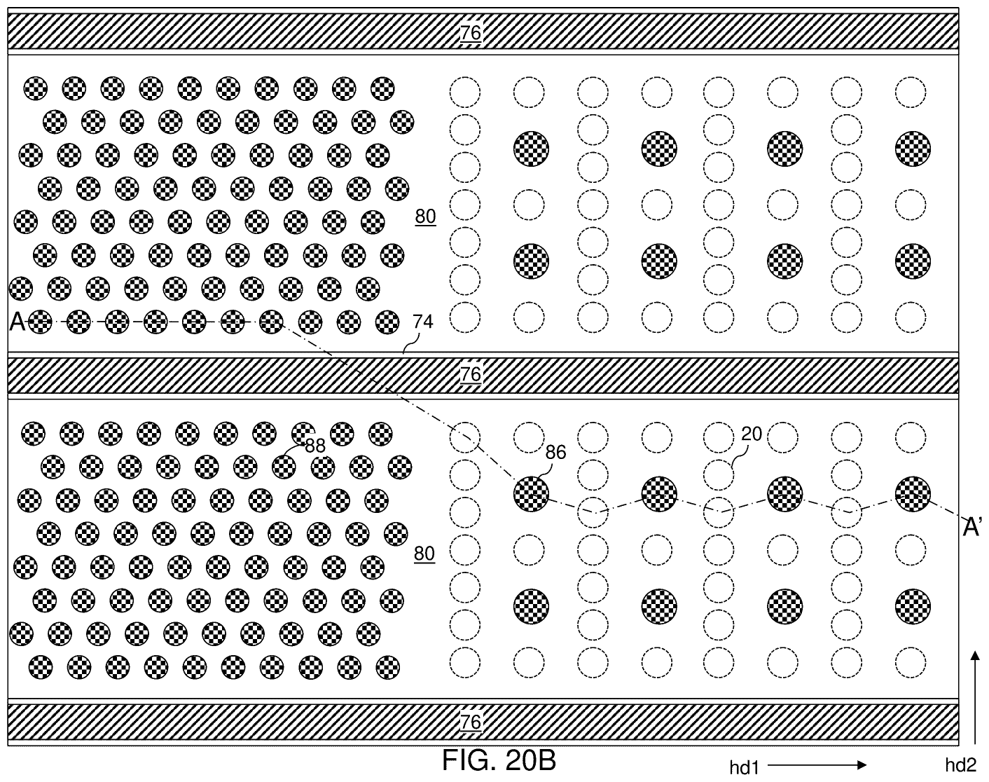

Referring to FIGS. 20A and 20B, a photoresist layer (not shown) can be applied over the contact-level dielectric layer 80, and can be lithographically patterned to form openings over each of the memory opening fill structures 58 over the horizontally-extending surfaces of the stepped surfaces in the contact region. An anisotropic etch process can be performed to transfer the pattern of the openings in the photoresist layer through the contact-level dielectric layer 80 and the stepped dielectric material portion 65. Drain contact via cavities can be formed through the contact-level dielectric layer 80 over the memory opening fill structures 58. Layer contact via structures can be formed through the contact-level dielectric layer 80 and the stepped dielectric material portion 65 on a top surface of a respective one of the electrically conductive layers 46. The photoresist layer can be subsequently removed, for example, by ashing.

At least one conductive material, such as a combination of a metallic barrier material and a metallic fill material, can be deposited in the drain contact via cavities and the layer contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63. Remaining portions of the at least one conductive material that fill the layer contact via cavities constitute layer contact via structures 86 contacting a top surface of a respective one of the electrically conductive layers 46.

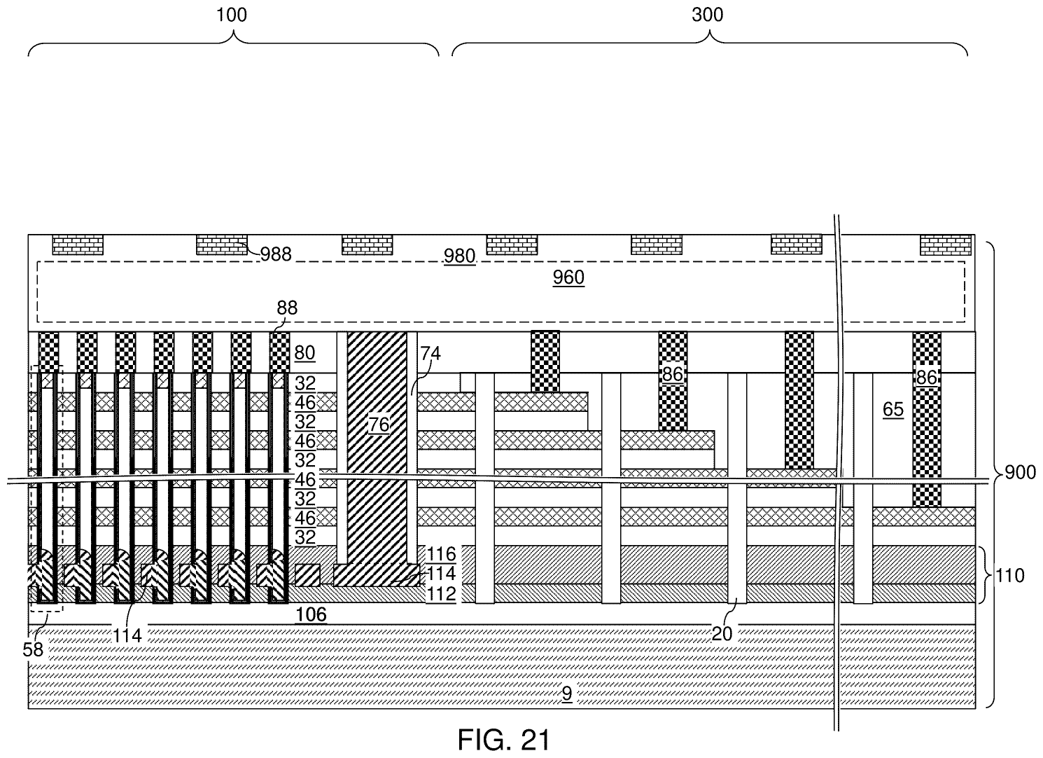

Referring to FIG. 21, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to as upper bonding pads 988, may be formed at the topmost level of the memory-side dielectric material layers 960. The upper bonding pads 988 may be electrically connected to the memory-side metal interconnect structures 980 and various nodes of the three-dimensional memory array including the electrically conductive layers 46 and the drain regions 63 of the memory opening fill structures 58.

A memory die 900 is thus formed which comprises the memory-side dielectric material layers 960 formed over the alternating stacks (32, 46), the memory-side metal interconnect structures 980 are embedded in the memory-side dielectric material layers 960, and the memory-side bonding pads 988 embedded within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array underlying the first dielectric material layer 110 and comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; a two-dimensional array of drain contact via structures 88 electrically connected to a respective one of the vertical semiconductor channels 60 via the respective drain regions 63; and a two-dimensional array of layer contact via structures 86 electrically connected to a respective one of the electrically conductive layers 46, a subset of which functions as word lines for the three-dimensional memory array.

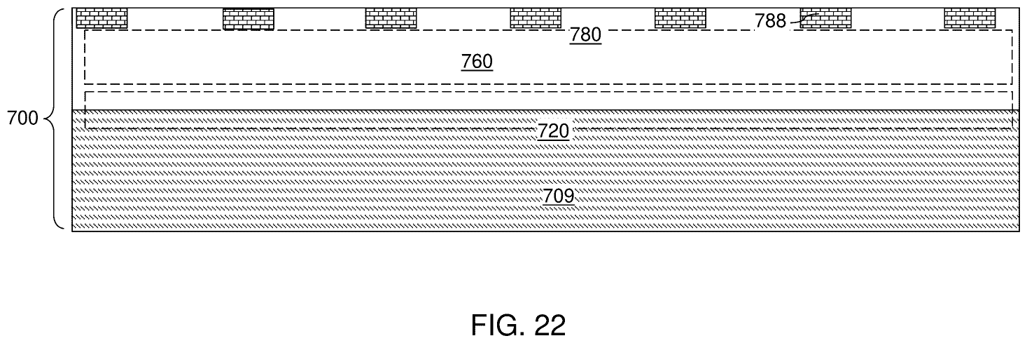

Referring to FIG. 22, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 778. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source structure to be subsequently formed. The peripheral circuit 720 can be configured to control operation of the vertical stack of memory elements in the memory array in the memory die 900.

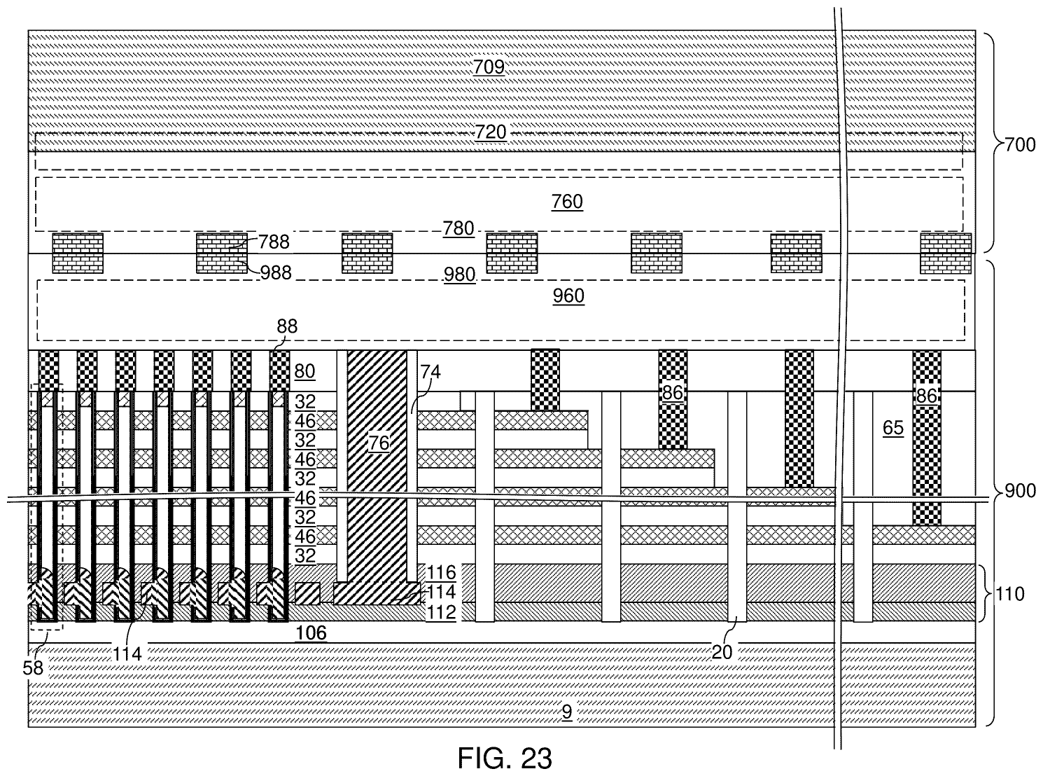

Referring to FIG. 23, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

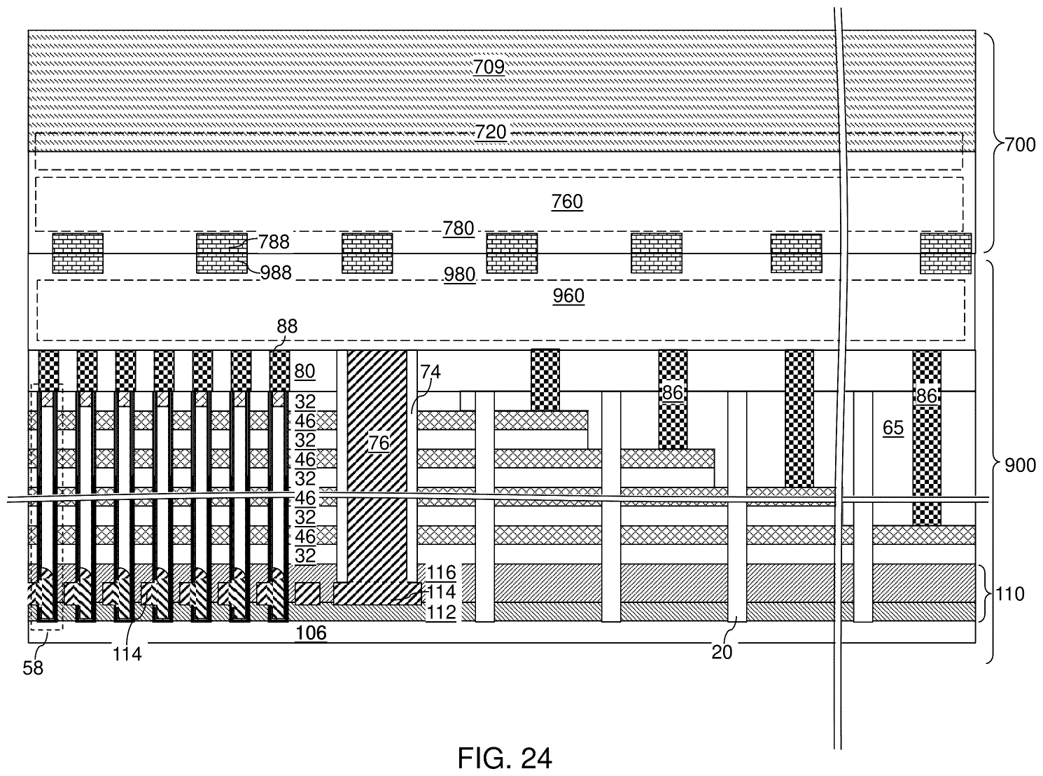

Referring to FIG. 24, the carrier substrate 9 can be removed, for example, by grinding, polishing, cleaving, an isotropic etch process, and/or an anisotropic etch process. If a polishing process such as a chemical mechanical polishing process is employed to remove the carrier substrate 9, the stopper insulating layer 106 may be subsequently employed as a polishing stopper material layer. If an etch process such as a wet etch process is employed to remove the carrier substrate 9, the stopper insulating layer 106 may be subsequently employed as an etch stop material layer. The source contact layer 114 may be electrically connected to the peripheral circuit in the logic die 700 using one or more contact via structures (not shown) extending through a peripheral region of the memory die 900.

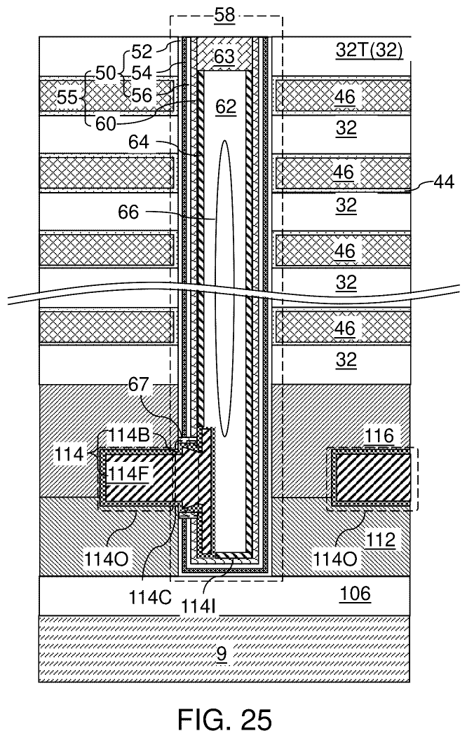

Referring to FIG. 25, an alternative configuration of the first exemplary structure can be derived from the first exemplary structure shown in FIG. 19C. In the alternative configuration, the dielectric core 62 includes a vertical scam or airgap 66. Such scam or airgap 64 makes it difficult to control the height of the core cavity 69 during the etching step described above with respect to FIGS. 17A and 17B. Therefore, in the alternative configuration, an etch stop dielectric layer 64 is formed between the vertical semiconductor channel 60 and the dielectric core 62. The etch stop dielectric layer 64 comprises one or more dielectric layers which are deposited over the semiconductor channel material layer 60L, followed by depositing the dielectric core layer 62L over the etch stop dielectric layer 64 during the formation of the memory stack structure 55 illustrated in FIG. 7B. The etch stop dielectric layer may comprise a dielectric metal oxide layer (e.g., aluminum oxide), a silicon nitride layer, or a stack of silicon oxide and silicon nitride layers. During the etching step described above with respect to FIGS. 17A and 17B, the etch stop dielectric layer 64 limits the amount of the dielectric core 62 material that is etched. Thus, the core cavity 69 does not extend upwards into the scam or airgap 66, thus providing improved control of the height of the core cavity 69.

Furthermore, an optional semiconductor barrier 67 may be conformally deposited into the cavity 109 and into the first lateral opening 109L after the etching step shown in FIG. 15C. The semiconductor barrier 67 may comprise undoped amorphous silicon or polysilicon. The semiconductor barrier 67 prevents vertical over-etching of the portions of the memory film 50 (e.g., the memory material layer 54) exposed in the first lateral opening 109L during the etching of the second lateral opening 109M shown in FIG. 16. Thus, the vertically-extending fin 114V may be omitted in the alternative structure because the semiconductor barrier 67 limits the vertical extent of the first lateral opening 109L into the memory film 50.

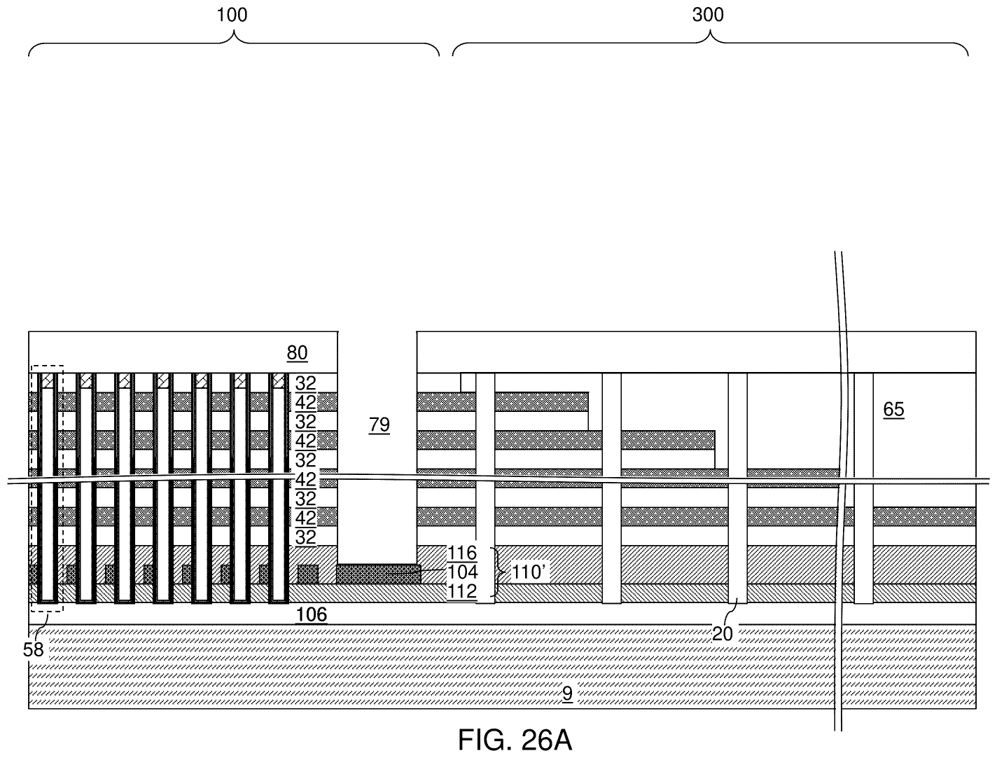

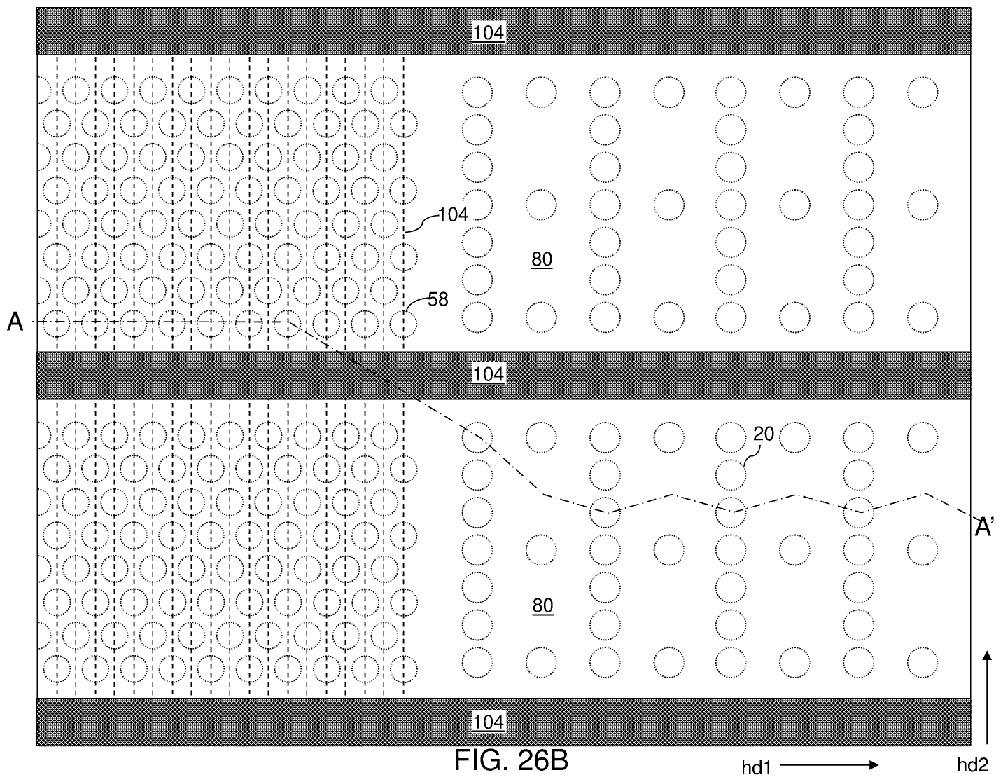

Referring to FIGS. 26A and 26B, a second exemplary structure according to a second embodiment of the present disclosure is illustrated, which may be the same as the first exemplary structure illustrated in FIGS. 9A and 9B, except that the source-level sacrificial layer 104 is exposed at the bottom of the lateral isolation trenches 79. Thus, the trench 79 etch is deeper in the second embodiment than in the first embodiment.

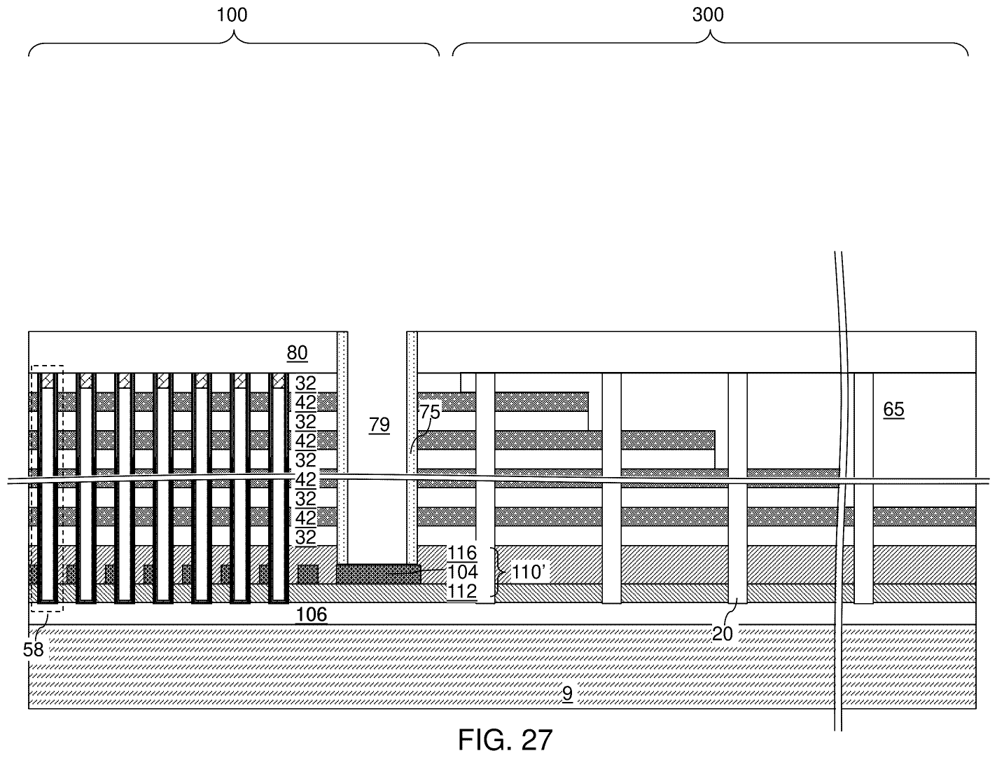

Referring to FIG. 27, a sacrificial spacer material that can function as an etch mask during subsequent isotropic etch processes can be conformally deposited in the lateral isolation trenches 79. The sacrificial spacer material can be a material that is different from the materials of the source-level sacrificial layer 104 and the dielectric cores 62. For example, if the source-level sacrificial layer 104 comprises silicon nitride and if the dielectric cores 62 comprises silicon oxide, the sacrificial spacer material may comprise silicon carbonitride. An anisotropic etch process can be performed to remove horizontally-extending portions of the sacrificial spacer material. Each remaining tubular portion of the sacrificial spacer material constitutes a sacrificial trench spacer 75.

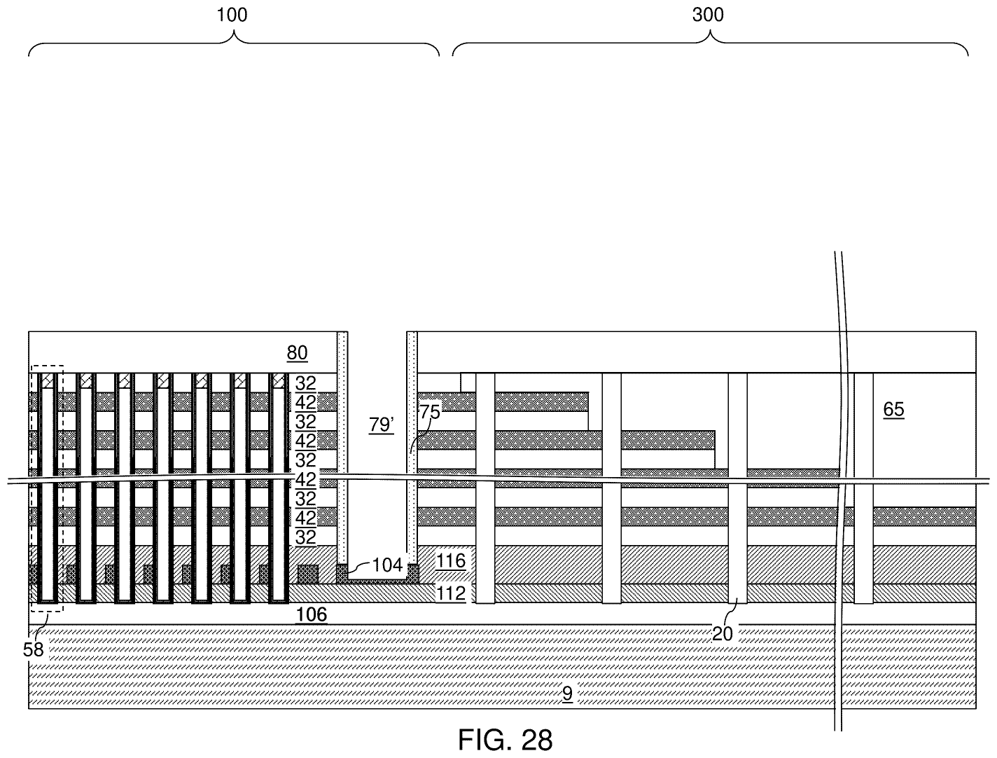

Referring to FIG. 28, the anisotropic etch process may be extended, with a change in the etch chemistry, to etch the materials of the source-level sacrificial layer 104 and optionally the lower source-level semiconductor layer 112. The unmasked portions of the source-level sacrificial material rails of the source-level sacrificial layer 104 may be etched underneath lateral isolation cavities 79′, which are unfilled volumes of the lateral isolation trenches 79. Generally, sidewalls of the remaining portions of the source-level sacrificial material rails of the source-level sacrificial layer 104 can be physically exposed underneath the lateral isolation cavities 79′.

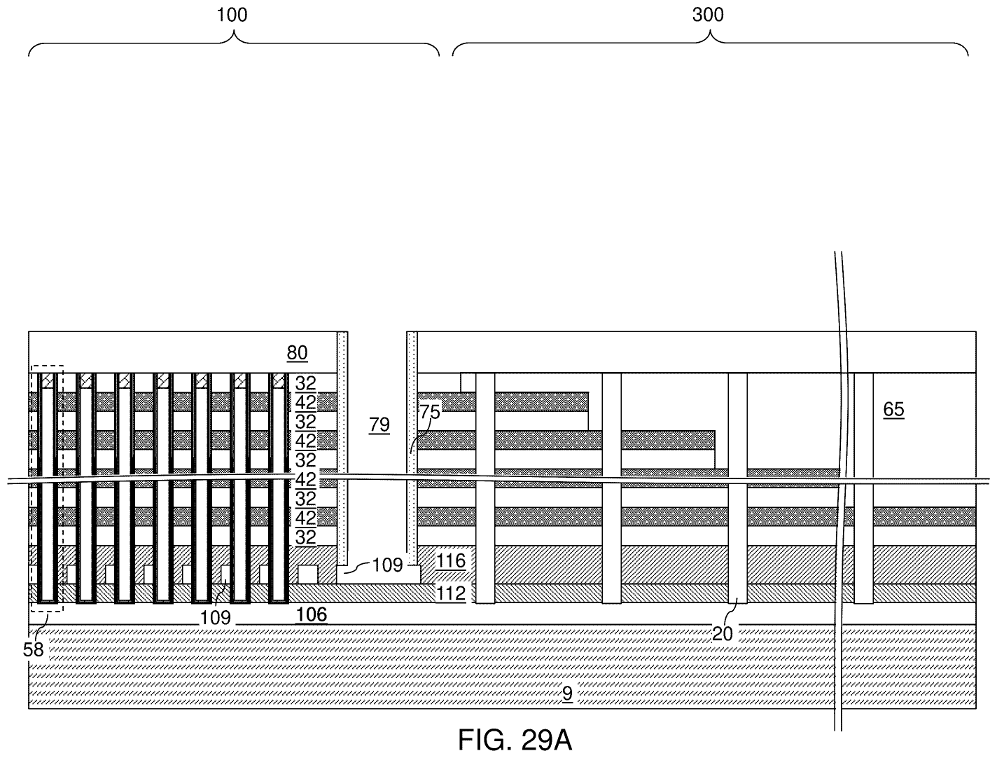

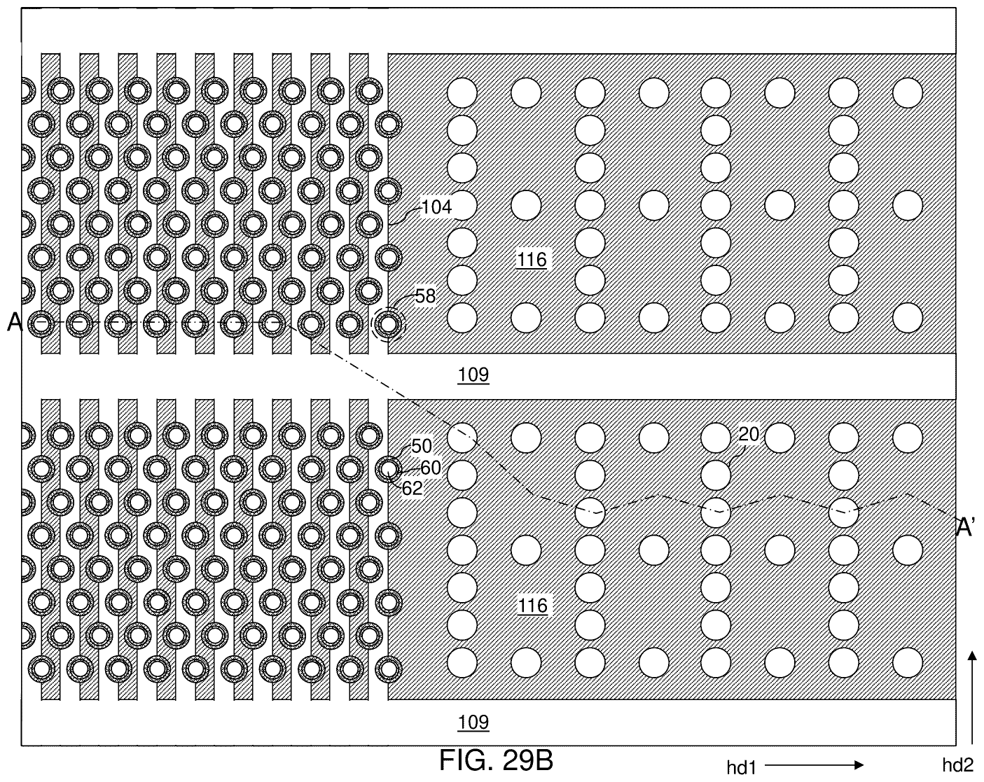

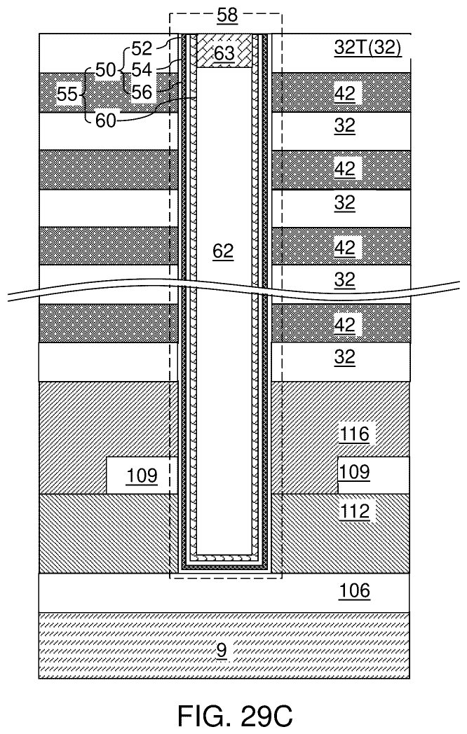

Referring to FIGS. 29A-29C, a first isotropic etch process can be performed to etch the material of the source-level sacrificial layer 104 selective to materials of the lower source-level semiconductor layer 112, the upper source-level semiconductor layer 116, the contact-level dielectric layer 80, and the sacrificial trench spacers 75. In an illustrative example, if the multiple source-level sacrificial material rails of the source-level sacrificial layer 104 comprise silicon nitride, a wet etch process employing hot phosphoric acid can be performed to remove the source-level sacrificial material rails of the source-level sacrificial layer 104.

A source cavity 109 is formed underneath a horizontal plane including bottom surfaces of the sacrificial trench spacers 75. The source cavity 109 comprises an interconnected network of cavities, or cavity segments, located at the source level, i.e., at the levels of the lower source-level semiconductor layer 112 and the upper source-level semiconductor layer 116. In one embodiment, the source cavity 109 comprises stem portions that underlie a respective one of the laterally-extending cavities 79′ and laterally extending along the first horizontal direction hd1, and branch portions that laterally extend along the second horizontal direction hd2 and intersects the stem portions. The second horizontal direction hd2 is different from the first horizontal direction hd1, and may be perpendicular to the first horizontal direction hd1. Two columns of memory opening fill structures 58 may be exposed to a branch portion of the source cavity 109 which is not an outermost branch portion.

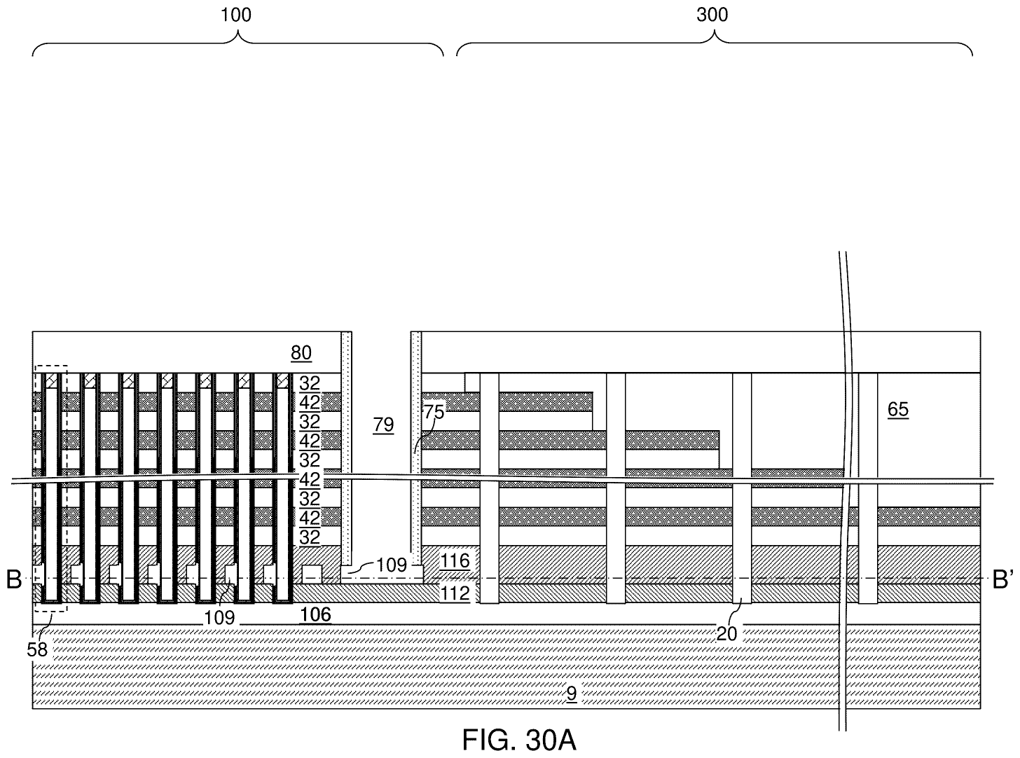

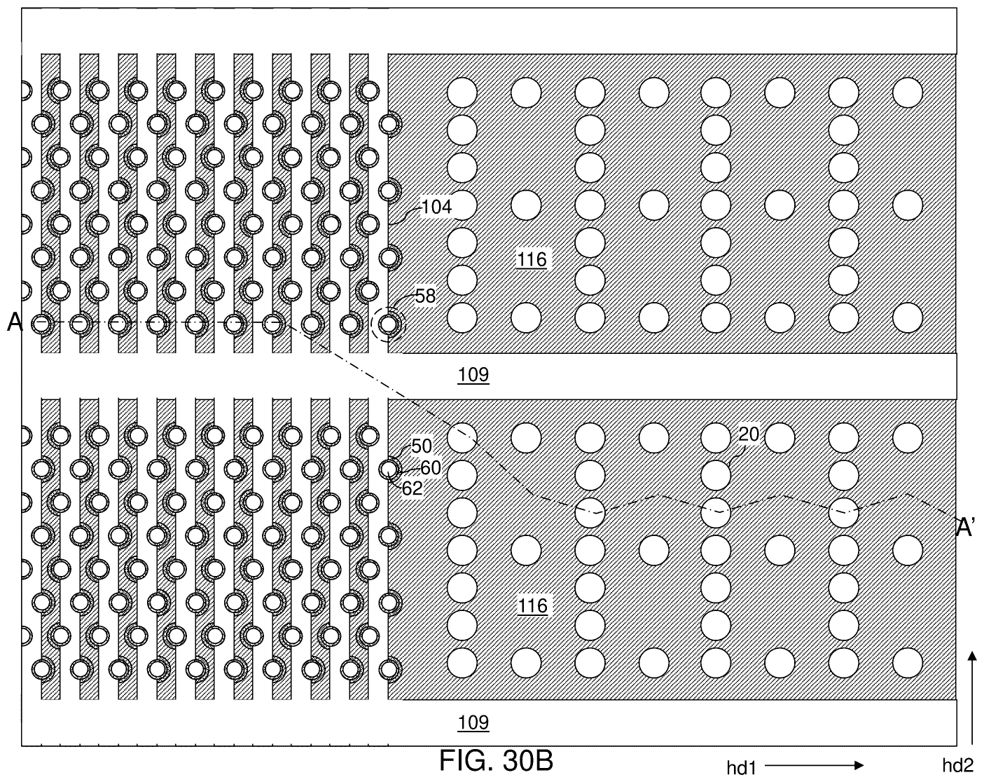

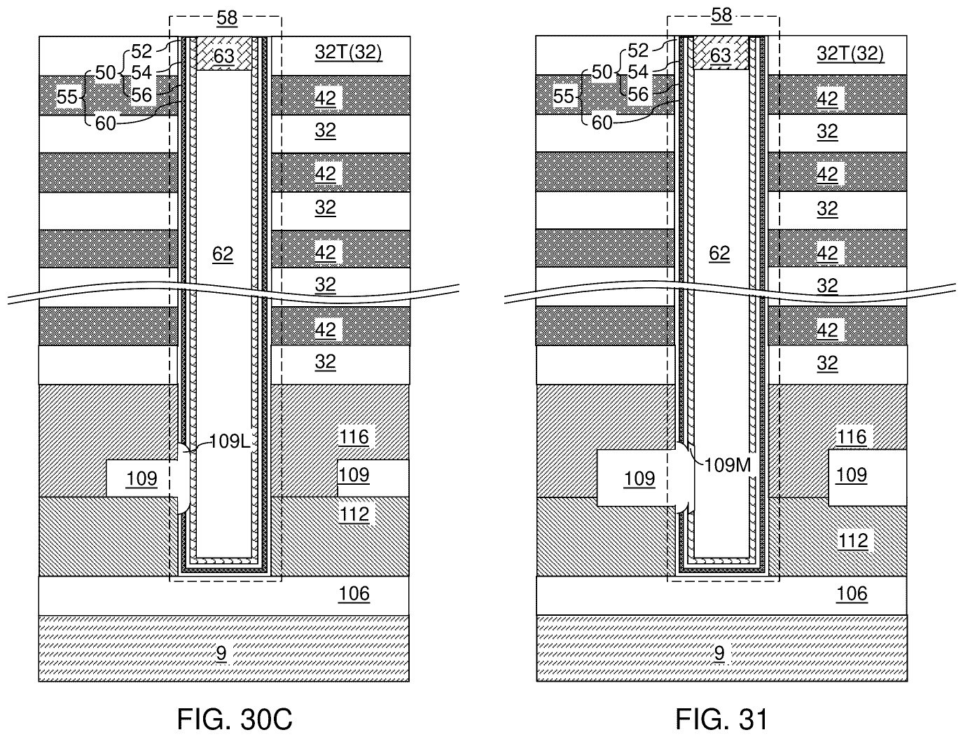

Referring to FIGS. 30A-30C, a second isotropic etch process can be performed to remove portions of the memory films 50 that are proximal to the source cavity 109. The second isotropic etch process can comprise a sequence of isotropic etch steps that etches various layers of each memory film 50 from outside to inside. For example, the second isotropic etch process may comprise a first isotropic etch step that etches the material of the blocking dielectric layers 52, a second isotropic etch step that etches the material of the memory material layers 54, and a third isotropic etch step that etches the material of the dielectric liner 56. A first lateral opening 109L is formed through a bottom portion of each memory film 50 such that each vertical semiconductor channel 60 comprises an outer surface segment that is exposed to the source cavity 109. Within each memory opening fill structure 58, each of the blocking dielectric layer 52, the memory material layer 54, and the dielectric liner 56 may have a respective opening that is exposed to the source cavity 109.

Referring to FIG. 31, a third isotropic etch process can be performed to isotropically etch the material of the vertical semiconductor channels 60. For example, if the vertical semiconductor channels 60 comprise polysilicon, the third isotropic etch process may comprise a wet etch process using hot trimethyl-2 hydroxyethyl ammonium hydroxide (“hot TMY”) or tetramethyl ammonium hydroxide (TMAH). A second lateral opening 109M can be formed through a bottom region of a vertically-extending portion of each vertical semiconductor channel 60. Each of the dielectric cores 62 may have a sidewall segment that is physically exposed to the source cavity 109.

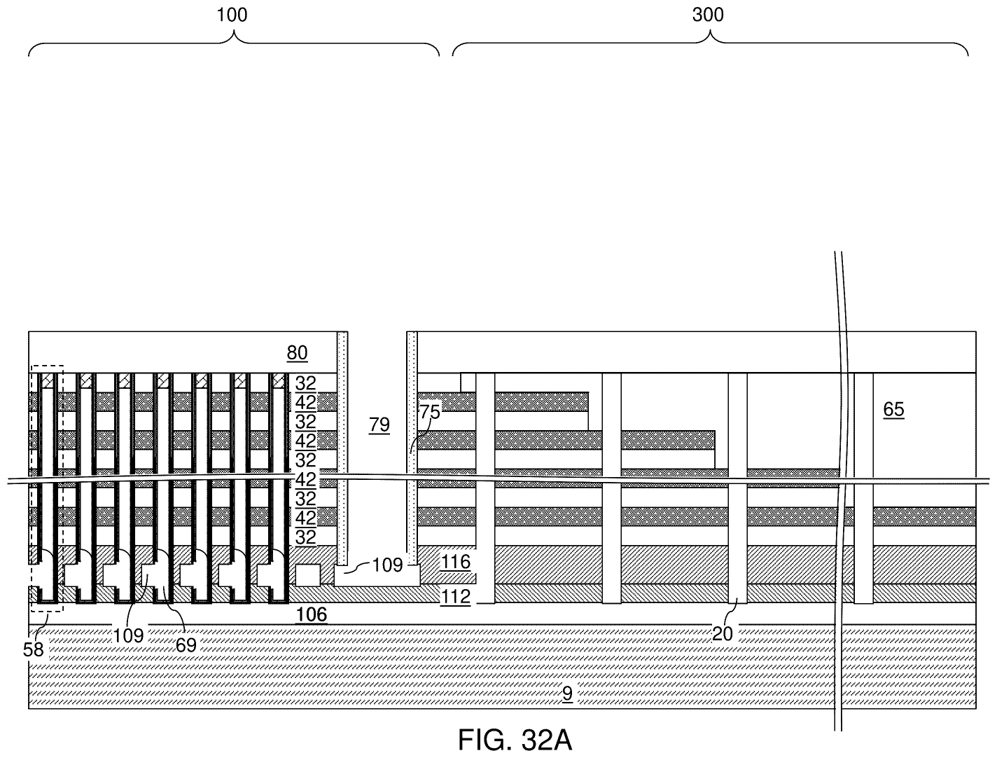

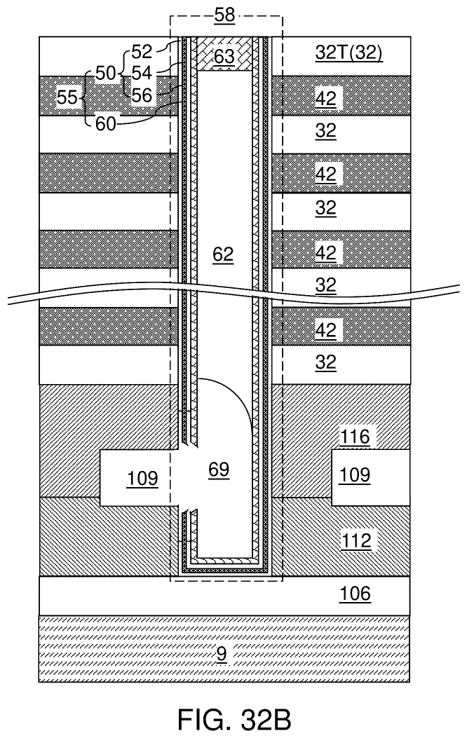

Referring to FIGS. 32A and 32B, a fourth isotropic etch process can be performed to isotropically etch the material of the dielectric cores 62 selective to materials of the lower source-level semiconductor layer 112, the upper source-level semiconductor layer 116, and the sacrificial trench spacers 75. An isotropic etchant can be provided to each of the dielectric cores 62 through lateral openings in the vertical semiconductor channels 60. In an illustrative example, the fourth isotropic etch process may comprise a wet etch process employing dilute hydrofluoric acid. The top surface of the contact-level dielectric layer 80 may be collaterally recessed during the fourth isotropic etch process.

The duration of the fourth isotropic etch process can be selected such that the etch distance of the fourth isotropic etch process for the material of the dielectric cores 62 (which may comprise silicon oxide) is greater than the maximum lateral dimension (such as a diameter) of a bottom portion of each dielectric core 62. In one embodiment, the duration of the fourth isotropic etch process can be selected such that the entirety of the portion of each dielectric core 62 that underlies the horizontal plane including physically exposed horizontal surfaces of the upper source-level dielectric layer 116 is removed by the fourth isotropic etch process.

Further, each remaining portion of the dielectric core 62 may have a lopsided shape having a respective concave tapered bottom surface, as described above with respect to the first embodiment. A core cavity 69 is formed within each volume from which the material of a respective dielectric core 62 is removed. Each core cavity 69 is connected to the source cavity 109 through a lateral opening in a memory stack structure 55. Generally, the source cavity 109 can be expanded into each memory opening fill structure 58 to form core cavities 69, and to physically expose a segment of an inner sidewall of each vertical semiconductor channel 60.

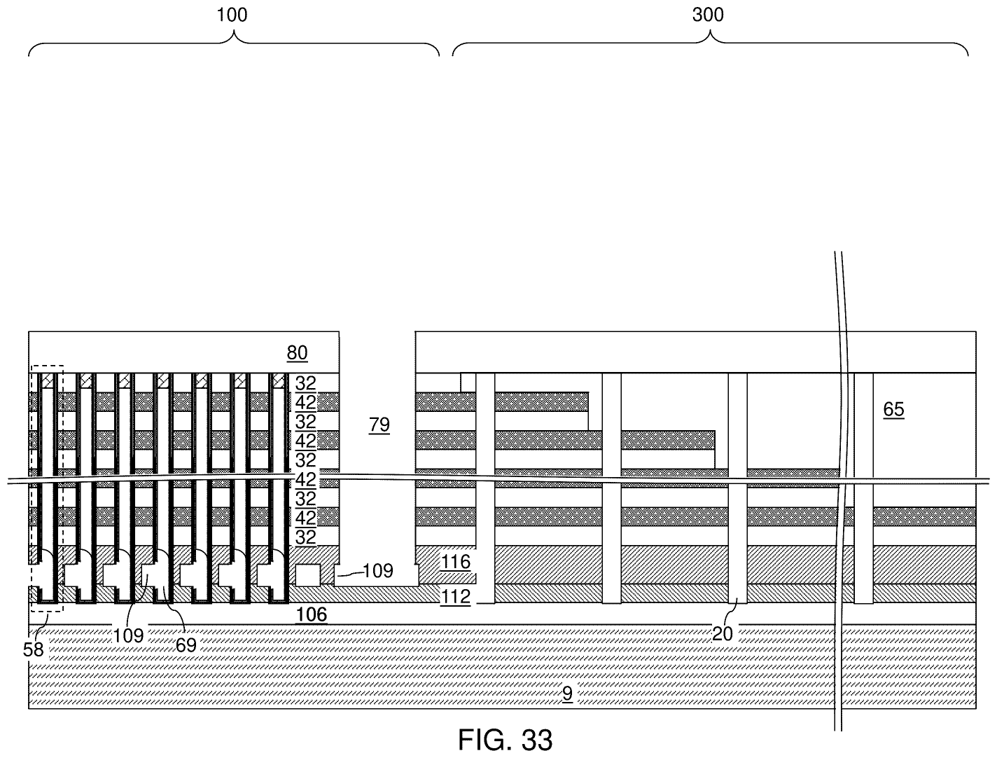

Referring to FIG. 33, the sacrificial trench spacers 75 may be removed selective to materials of the dielectric cores 62, the insulating spacers 74, the contact-level dielectric layer 80, the lower source-level semiconductor layer 112, and the upper source-level semiconductor layer 116. For example, if the sacrificial trench spacers 75 comprise silicon carbonitride, then they may be converted to silicon oxide by ashing in oxygen plasma followed by etching the silicon oxide using hydrofluoric acid.

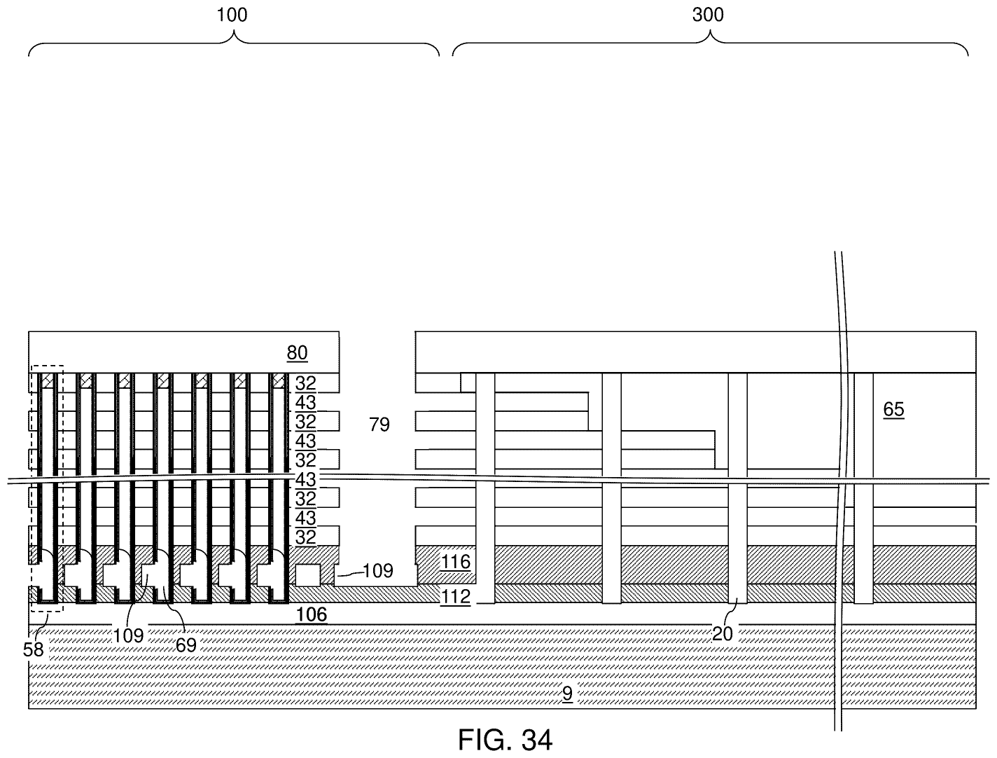

Referring to FIG. 34, an isotropic etch process can be performed to remove the sacrificial material layers 42 selective to the insulating layers 32, the contact-level dielectric layer 80, the memory opening fill structures 58, the dielectric cores 62, the upper source-level semiconductor layer 116, and the lower source-level semiconductor layer 112. Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon nitride, the isotropic etch process may comprise a wet etch process employing hot phosphoric acid.

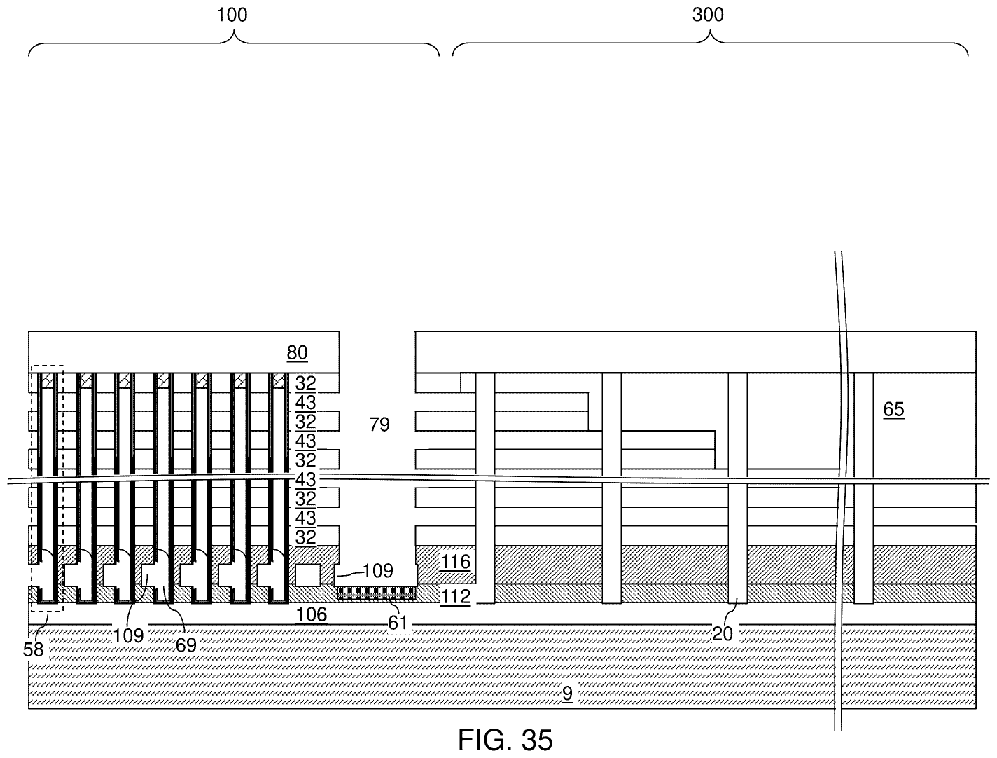

Referring to FIG. 35, an implantation process may be optionally performed to implant dopants of the second conductivity type into portions of the lower source-level semiconductor layer 112 that underlie the lateral isolation trenches 79. Source regions 61 including dopants of the second conductivity type at a higher atomic concentration than the lower source-level semiconductor layer 112 can be formed.

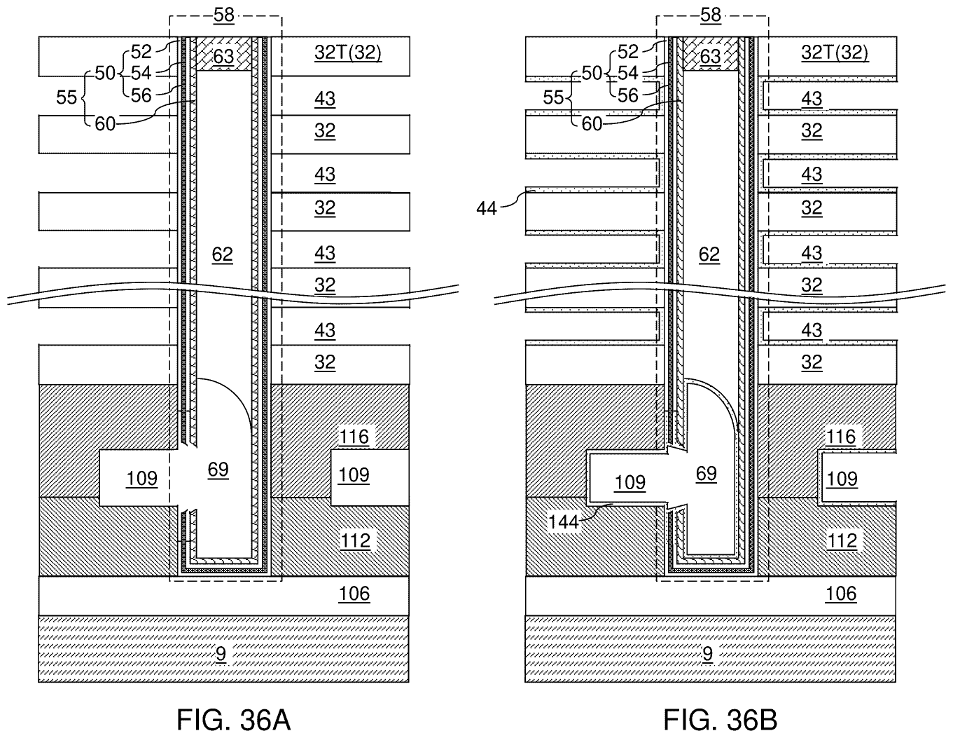

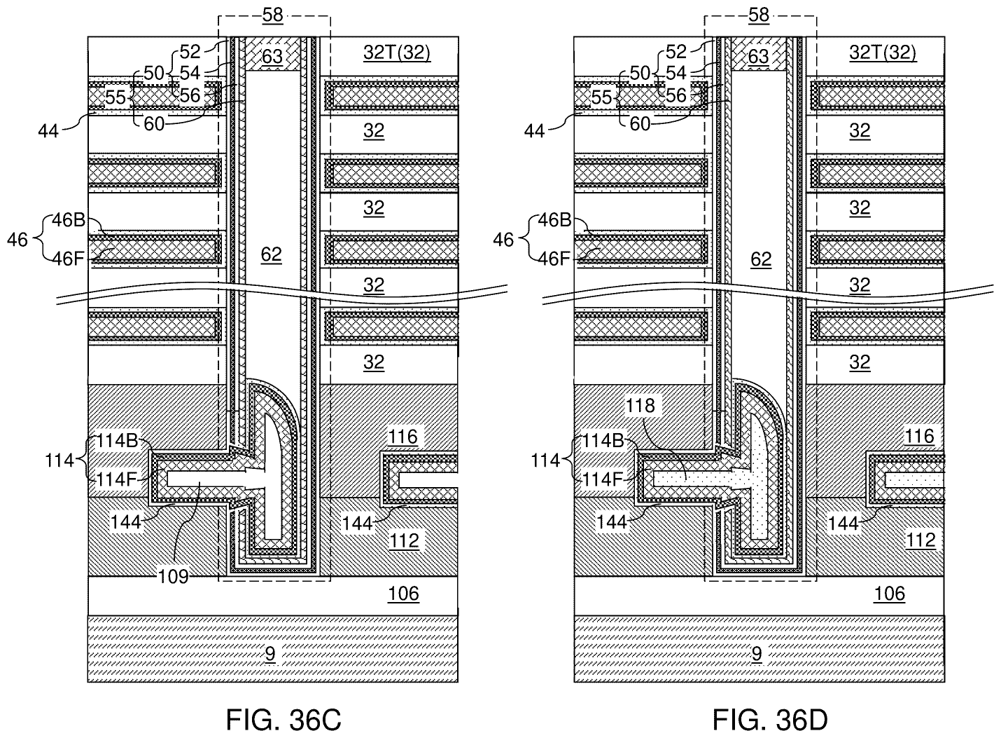

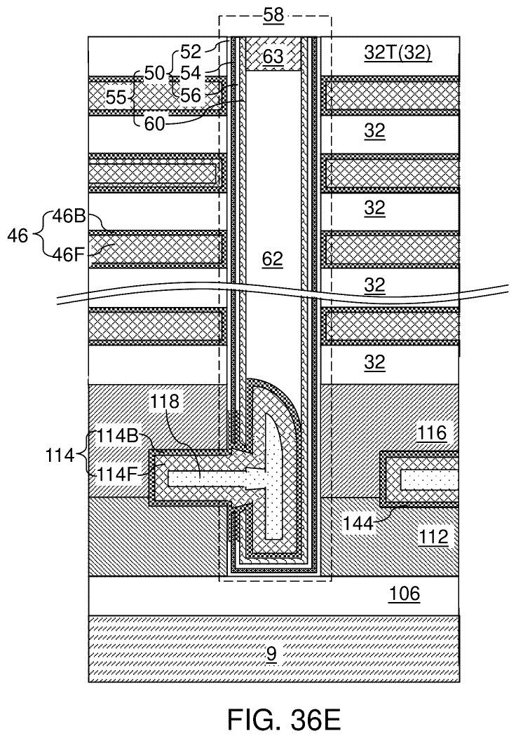

FIGS. 36A-36D are sequential vertical cross-sectional views of a region around a memory opening fill structure 58 in the second exemplary structure during formation of an optional backside blocking dielectric layer 52, electrically conductive layers 46, a source contact layer 114, and a dielectric fill material layer according to the second embodiment of the present disclosure.

Referring to FIG. 36A, a region around a memory opening fill structure 58 is illustrated after the processing steps of FIG. 35.

Referring to FIG. 36B, a dielectric material can be conformally deposited in the core cavities 69, in the source cavity 109, in the lateral isolation trenches 79, and over the contact-level dielectric layer 80. The deposited dielectric material can be a blocking dielectric material, i.e., a dielectric material that reduces passage of electrical current therethrough. In one embodiment, the blocking dielectric material may comprise a dielectric metal oxide (such as aluminum oxide, tantalum oxide, hafnium oxide, etc.), silicon oxide, silicon nitride, or a combination thereof. In one embodiment, the blocking dielectric material may comprise aluminum oxide. The blocking dielectric material may be deposited by atomic layer deposition or chemical vapor deposition. The thickness of the deposited blocking dielectric material may be in a range from 0.3 nm to 4 nm, such as from 0.6 nm to 3 nm, although lesser and greater thicknesses may also be employed.

Generally, the thickness of the deposited blocking dielectric material may be selected such that quantum tunneling of electrical charges can occur through the blocking dielectric material. The portion of the blocking dielectric material layer that is deposited in the core cavities 69 and the source cavity 109 constitutes a source-level blocking dielectric layer 144. Each portion of the blocking dielectric material that is deposited in the laterally-extending cavities 43 constitutes a backside blocking dielectric layer 44. The source-level blocking dielectric layer 144 and the backside blocking dielectric layers 44 are optional structures, and as such, may be omitted. In the second exemplary structure, the thickness of the blocking dielectric layers 52 may be selected such that the blocking dielectric layers 52 alone, or each combination of a blocking dielectric layer 52 and a backside blocking dielectric layer 44, is sufficient to prevent tunneling of electrical charges between the memory elements in the memory films 50 and the electrically conductive layers to be subsequently formed.

Referring to FIG. 36C, at least one conductive material can be conformally deposited in the core cavities 69, in the source cavity 109, in the laterally-extending cavities 43, in the lateral isolation trenches 79, and above the contact-level dielectric layer 80. The conformal deposition may comprise at least one chemical vapor deposition process and/or at least one atomic layer deposition process. The at least one conductive material may comprise a heavily doped semiconductor material having a doping of the second conductivity type, and/or at least one metallic material. In one embodiment, the at least one conductive material comprises a combination of a metallic barrier material (such as a conductive metallic nitride or a conductive metallic carbide) and a metallic fill material (such as a metal or an intermetallic alloy).

Generally, the source cavity 109 may have a greater height than each of the laterally-extending cavities 43. In one embodiment, the duration of the deposition process(es) employed to deposit the at least one conductive material can be selected such that the laterally-extending cavities 43 are completely filled with the at least one conductive material, while voids are present in unfilled volumes of the source cavity 109 after deposition of the at least one conductive material. Further, in case the lateral dimensions of a core cavity 69 is greater than twice the total thickness of the deposited conductive material(s), voids may be present in unfilled volumes of the core cavities 69 after deposition of the at least one conductive material.

Each portion of the at least one conductive material that fills a respective laterally-extending cavity 43 constitutes an electrically conductive layer 46. The portion of the at least one conductive material that is deposited in the source cavity 109 constitutes a source contact layer 114. In case the at least one conductive material comprises a combination of a metallic barrier material and a metallic fill material, each electrically conductive layer 46 may comprise a combination of a metallic barrier liner 46B and a metallic fill material portion 46F, and the source contact layer 114 may comprise a combination of a source contact metallic barrier layer 114B and a source contact fill material layer 114F. The metallic barrier layer 114B comprises a conducive metallic nitride (such as TiN, TaN, WN, or MoN) or a conductive metallic carbide (such as TiC, TaC, or WC). The source contact fill material layer 114F comprises a metal (such as Ti, Ta, W, Co, Ru, Mo, Cu, alloys thereof, or a combination thereof), and is embedded within the source contact metallic barrier layer 114B.

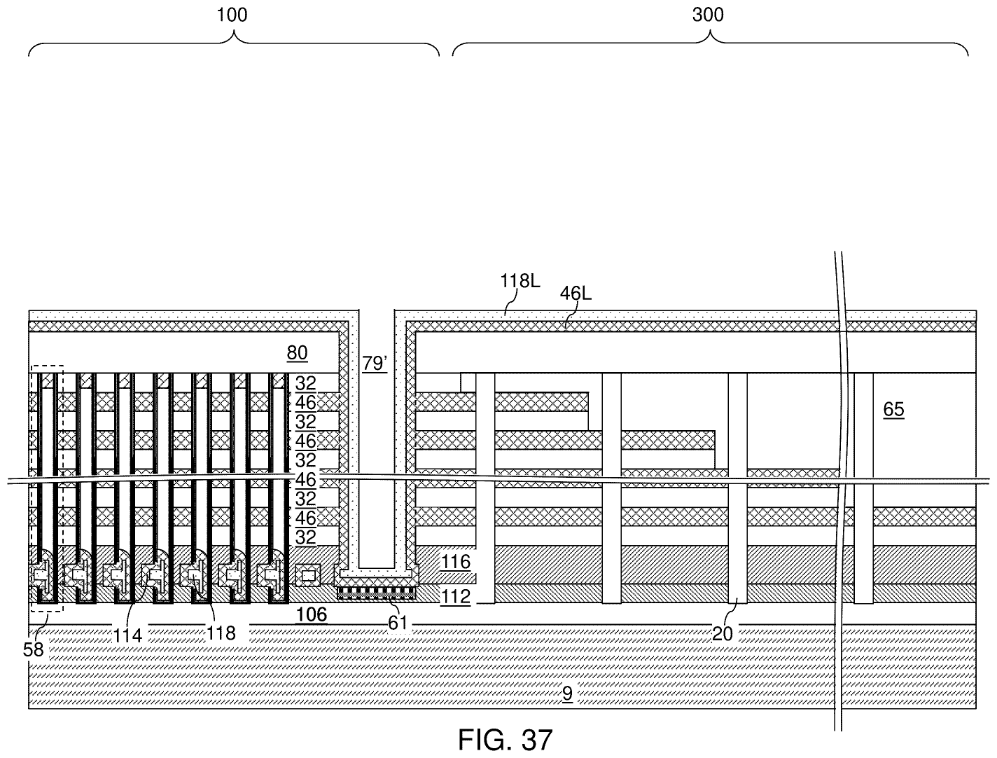

Referring to FIGS. 36D and 37, a continuous metallic material layer 46L having a same material composition as the electrically conductive layers 46 and the source contact layer 114 can be present at peripheral regions of the lateral isolation trenches 79 and over the top surface of the contact-level dielectric layer 80. A dielectric fill material, such as silicon oxide, may be conformally deposited in remaining volumes of the source cavity 109 and over the continuous metallic material layer 46L by a conformal deposition process. The portion of the dielectric fill material that is deposited in remaining volumes (i.e., in the void) of the source cavity 109 constitutes a dielectric fill material layer 118. The portion of the dielectric fill material that is deposited over the continuous metallic material layer 46L constitutes a continuous dielectric material layer 118L. The thickness of the continuous dielectric material layer 118L can be selected such that a lateral isolation cavity 79′ is present within each of the lateral isolation trenches 79. Each lateral isolation cavity 79′ is an unfilled volume of a respective lateral isolation trench 79.

Referring to FIG. 36E, an alternative configuration of the second exemplary structure is illustrated, which can be derived from the second exemplary structure illustrated in FIGS. 36D and 37 by omitting formation of the backside blocking dielectric layers 44 and the source-side blocking dielectric layer 144.

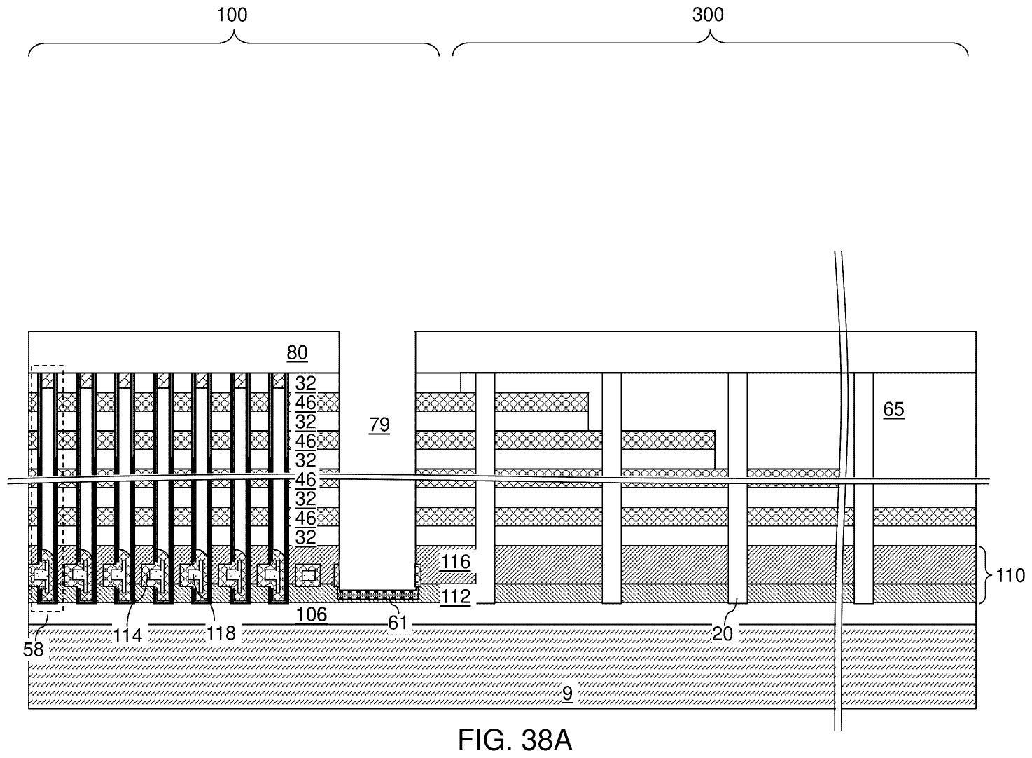

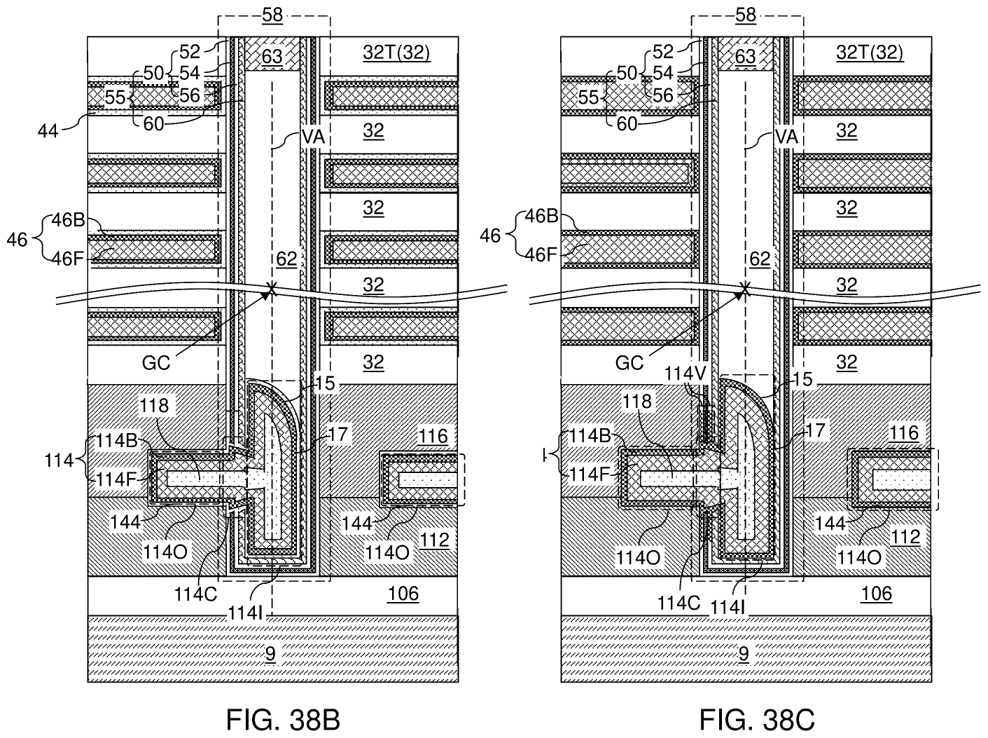

Referring to FIGS. 38A and 38B, the continuous dielectric material layer 118L can be removed by performing a first etch back process, which may comprise an isotropic etch process and/or an anisotropic etch process. In case an isotropic etch process is employed to remove the continuous dielectric material layer 118L, the duration of the isotropic etch process can be selected such that the dielectric fill material layer 118 is present in areas that do not underlie the lateral isolation cavities 79′. Subsequently, the continuous metallic material layer 46L can be removed by performing a second etch back process, which may comprise an isotropic etch process and/or an anisotropic etch process. In case an isotropic etch process is employed to remove the continuous metallic material layer 46L, the duration of the isotropic etch process can be selected such that the source contact layer 114 is present in areas that do not underlie the lateral isolation cavities 79′.

Referring to FIG. 38C, an alternative configuration of the second exemplary structure can be derived from the second exemplary structure illustrated in FIGS. 38A and 38B by omitting formation of the backside blocking dielectric layers 44 and the source-level blocking dielectric layer 144.

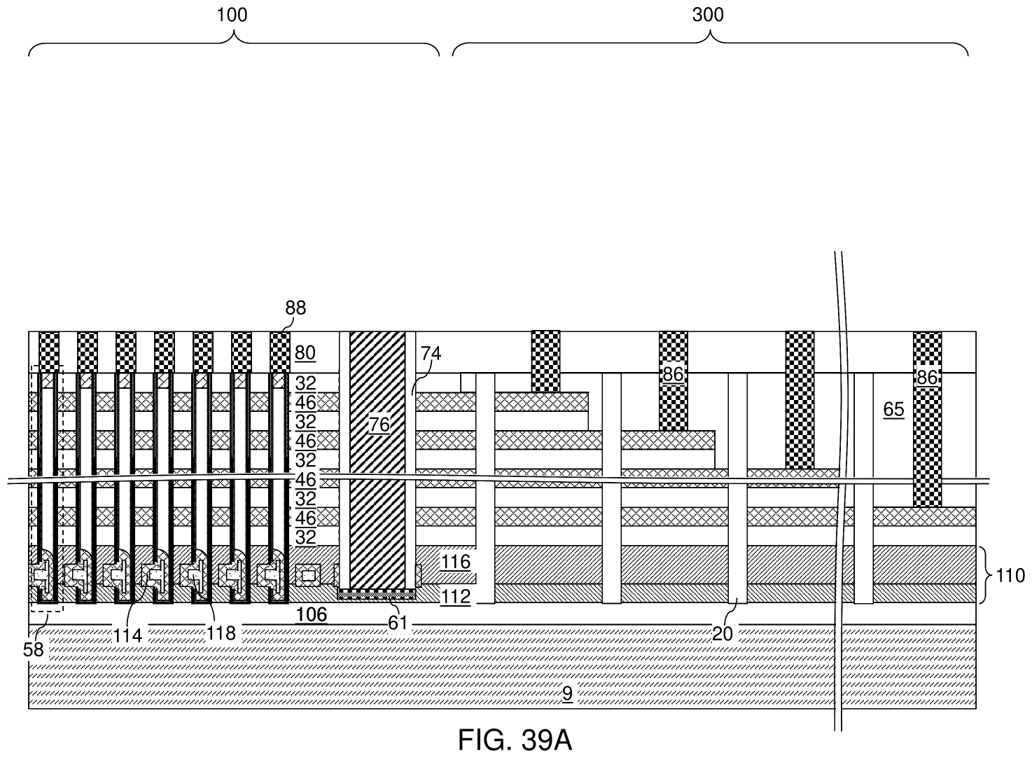

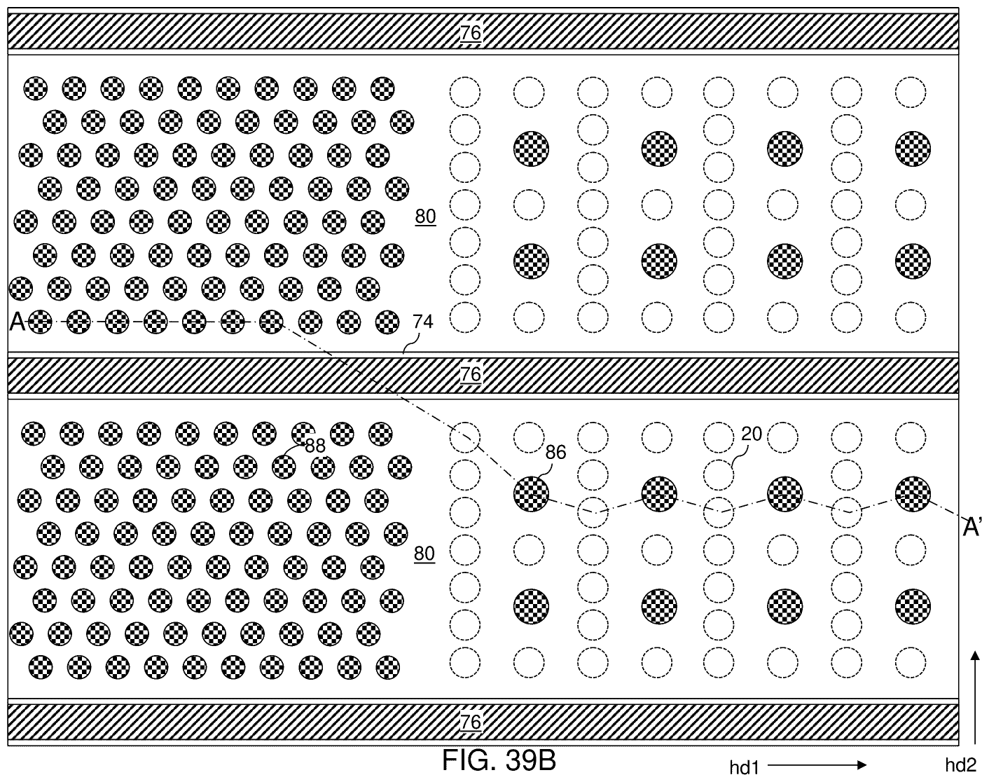

Referring collectively to FIGS. 39A-39B, the combination of the lower source-level semiconductor layer 112, the upper source-level semiconductor layer 116, and the source contact layer 114 constitutes source-level material layers 110. The source contact layer 114 can be formed in the source cavity 109 over, and directly on a segment of the inner sidewall of each vertical semiconductor channel 60. In the embodiment illustrated in FIG. 38B, the source contact layer 114 can be spaced from each vertical semiconductor channel 60 by a source-level blocking dielectric layer 144, through which electrical charges tunnel while electrical current flows through any of the vertical semiconductor channels 60. In the embodiment illustrated in FIG. 38C, each inner portion 1141 of the source contact layer 114 can be in contact with a segment of an inner sidewall of a respective vertical semiconductor channel 60.

Referring again collectively to FIGS. 38A-38C, the source contact layer 114 includes an outer portion 1140 located outside the volumes of the memory openings 49, and inner portions 1141 that are located within the volumes of the memory openings 49. The outer portion 1140 of the source contact layer 114 may comprise stem portions that laterally extends along the first horizontal direction hd1 and multiple branch portions that laterally extend along the second horizontal direction hd2 that is different from the first horizontal direction hd1. The stem portions of the source contact layer 114 are not in direct contact with the memory opening fill structures 58, and the branch portions of the source contact layer 114 are in direct contact with the memory opening fill structures 58. Generally, each of the memory opening fill structures 58 comprises a respective vertical semiconductor channel 60 that contacts a respective branch portion of the source contact layer 114.

In one embodiment, each inner portion 1141 of the source contact layer 114 may be located inside the vertical semiconductor channel 60 of a respective memory opening fill structure 58. Therefore, each inner portion 1141 of the source contact layer 114 may be more proximal to a vertical axis VA passing through the geometrical center GC of the volume of the memory opening 49 in which the inner portion 1141 is located than an inner sidewall of the vertical semiconductor channel 60 within the memory opening 49 is to the vertical axis VA. In one embodiment, the outer portion 1140 of the source contact layer 114 and each inner portion 1141 of the source contact layer 114 can be interconnected to each other by a respective interconnection portion 114C of the source contact layer 114 that is located within a lateral opening through a respective one of the vertical semiconductor channels 60.

In one embodiment, each memory opening fill structure 58 comprises a dielectric liner 56 that is interposed between a vertical semiconductor channel 60 and a vertical stack of memory elements. An interconnection portion 114C of the source contact layer 114 extends through a lateral opening in the dielectric liner 56. In one embodiment, each memory opening fill structure 58 comprises a blocking dielectric layer 52 that is interposed between the vertical stack of memory elements and the alternating stack (32, 46) of insulating layers 32 and electrically conductive layers 46. An interconnection portion 114C of the source contact layer 114 extends through a lateral opening in the blocking dielectric layer 52.

In one embodiment, the memory opening fill structure 58 comprises a dielectric core 62 that extends vertically through each electrically conductive layer 46 within the alternating stack (32, 46) and has a lopsided bottom portion so that the dielectric core 62 has a lesser vertical extent on a side that is proximal to the outer portion 1140 of the source contact layer 114 than on a side that is distal from the outer portion 1140 of the source contact layer 114. In one embodiment, the lopsided bottom portion of the dielectric core 62 has a concave tapered bottom surface that overlies a convex tapered top surface of the inner portion 1141 of the source contact layer 114. In one embodiment, the concave tapered bottom surface of the lopsided bottom portion of the dielectric core 62 is in contact with the convex tapered top surface of the inner portion 1141 of the source contact layer 114.

In one embodiment, the source contact layer 114 may be formed by deposition of a combination of a metallic barrier material and a metallic fill material. In this case, the source contact layer 114 may include a source contact metallic barrier layer 114B comprising a conducive metallic nitride (such as TiN, TaN, WN, or MoN) or a conductive metallic carbide (such as TiC, TaC, or WC), and a source contact fill material layer 114F comprising a metal (such as Ti, Ta, W. Co, Ru, Mo, Cu, alloys thereof, or a combination thereof) and embedded within the source contact metallic barrier layer 114B.

In one embodiment, each memory opening fill structure 58 comprises a dielectric liner 56 that is interposed between a vertical stack of memory elements and a vertical semiconductor channel 60, and the source contact layer 114 comprises a vertically-extending fin 114V that contacts a surface segment of an outer sidewall of the vertical semiconductor channel 60 and contacts a surface segment of the dielectric liner 56, and is located within a volume of a respective memory opening 49.

In one embodiment, the source-level material layers 110 comprise a lower source-level semiconductor layer 112 that underlies the source contact layer 114, and an upper source-level semiconductor layer 116 layer that is interposed between the lower source-level semiconductor layer 112 and alternating stack (32, 46) and embedding the source contact layer 114.

In one embodiment, each inner portion 1141 of the source contact layer 114 comprises a lower cylindrical segment 17 and an upper tapered segment 15 having a tapered convex surface. The lower cylindrical segment 17 of the inner portion 1141 of the source contact layer 114 may contact an inner sidewall of a vertical semiconductor channel 60 as illustrated in FIG. 38C. The upper tapered segment 15 of the inner portion 1141 of the source contact layer 114 may contact a tapered concave sidewall of a dielectric core 62 as illustrated in FIG. 38C. Alternatively, the lower cylindrical segment 17 of the inner portion 1141 of the source contact layer 114 may be laterally spaced from an inner sidewall of a vertical semiconductor channel 60 by a portion of the source-level blocking dielectric layer 144 as illustrated in FIG. 38B. The upper tapered segment 15 of the inner portion 1141 of the source contact layer 114 may contact a tapered concave surface of the source-level blocking dielectric layer as illustrated in FIG. 38B.

Referring to FIGS. 39A and 39B, an insulating material such as silicon oxide can be conformally deposited in peripheral regions of the lateral isolation trenches 79 and above the contact-level dielectric layer 80. An anisotropic etch process can be performed to remove horizontally-extending portions of the insulating material. Each remaining vertically-extending tubular portion of the insulating material located within a respective one of the lateral isolation trenches 79 constitutes an insulating spacer 74.

At least one conductive material can be conformally deposited in unfilled volumes of the lateral isolation trenches 79 and above the contact-level dielectric layer 80. The conformal deposition may comprise at least one chemical vapor deposition process and/or at least one atomic layer deposition process. The at least one conductive material may comprise a heavily doped semiconductor material having a doping of the second conductivity type, and/or at least one metallic material. In one embodiment, the at least one conductive material may comprise a combination of a conductive metallic nitride or a conductive metallic carbide, and a metallic fill material such as a metal or an intermetallic alloy.

Excess portions of the at least one conductive material can be removed from above the horizontal plane including the top surface of the contact-level dielectric layer 80 by a planarization process. The planarization process may comprise a chemical mechanical polishing process and/or a recess etch process. A remaining portion of the at least one conductive material that fills a respective lateral isolation trench 79 constitutes a source contact via structure 76. Each source contact via structure 76 can be laterally surrounded by a respective insulating spacer 74, and contacts a respective source region 61, or a respective portion of the lower source-level semiconductor layer 112 (in case source regions 61 are not formed).

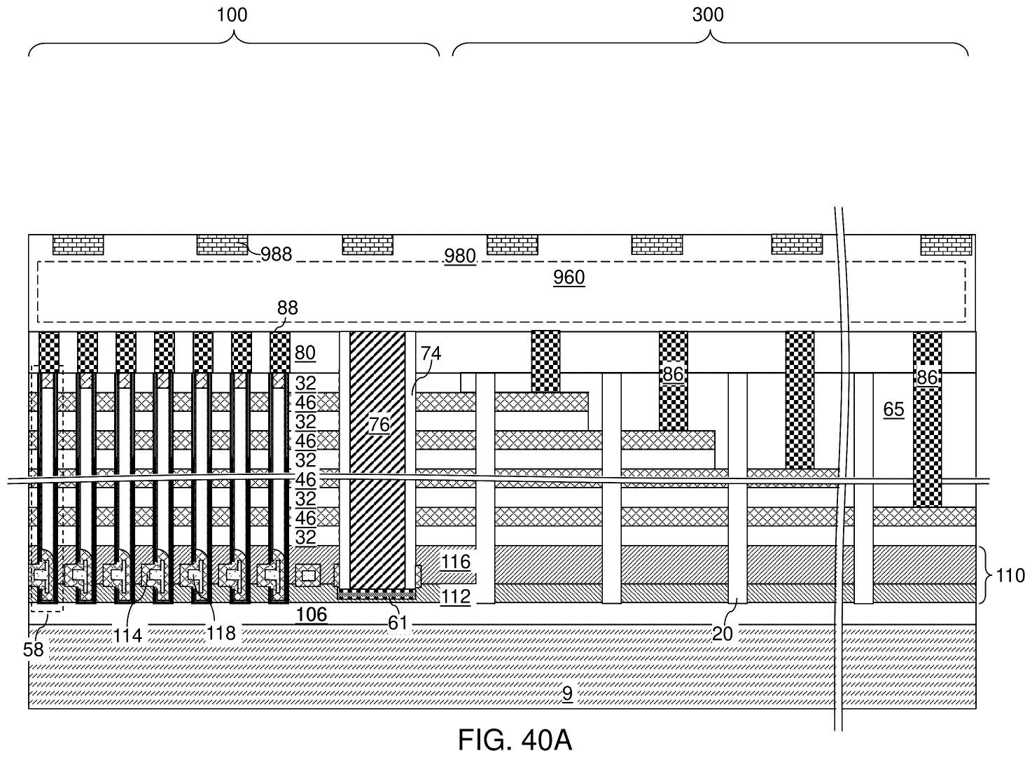

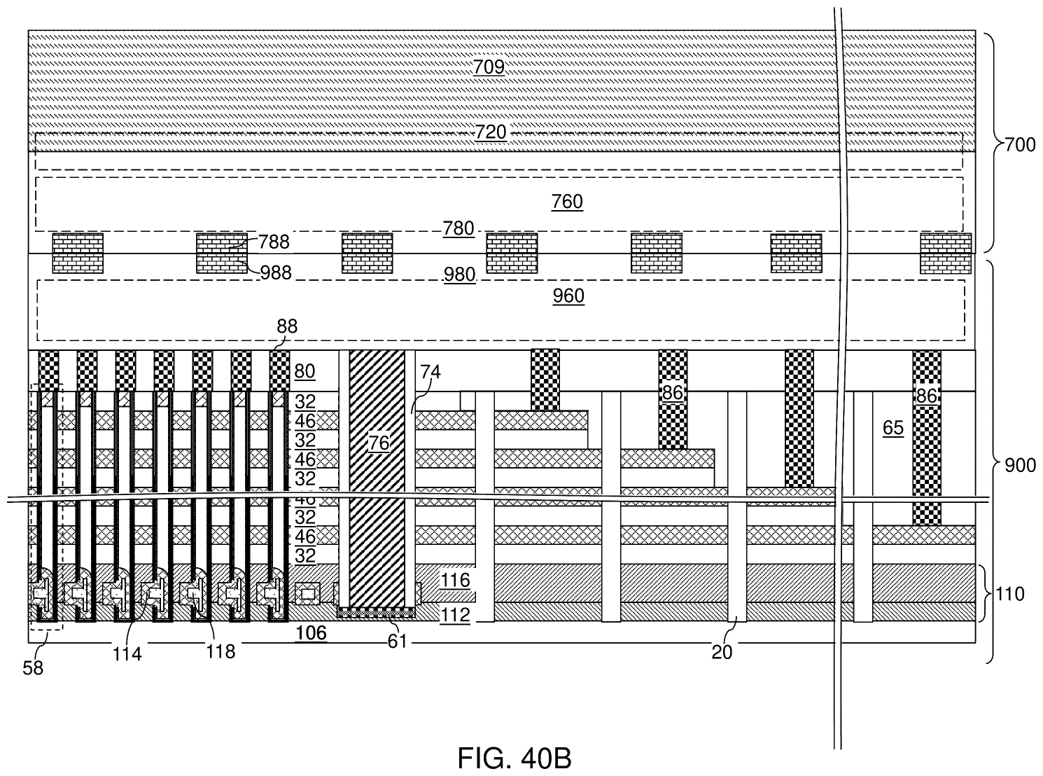

Referring to FIG. 40A, the processing steps described with reference to FIG. 21 can be performed to form a memory die 900.

Referring to FIG. 40B, the processing steps described with reference to FIGS. 22-25 can be performed to attach a logic die 700 to the memory die 900, and to remove the carrier substrate 9.

Referring to first and second embodiments of the present disclosure. a semiconductor structure is provided, which comprises: an alternating stack (32, 46) of insulating layers 32 and electrically conductive layers 46 located over source-level material layers 110; a memory opening 49 vertically extending through the alternating stack (32, 46) and into an upper portion of the source-level material layers 110; and a memory opening fill structure 58 located in the memory opening 49 and comprising a vertical stack of memory elements and a vertical semiconductor channel 60, wherein the source-level material layers 110 comprise a source contact layer 114 that includes an outer portion 1140 located outside a volume of the memory opening 49 and an inner portion 1141 located within the volume of the memory opening 49 and is more proximal to a vertical axis VA passing through a geometrical center GC of the volume of the memory opening 49 than an inner sidewall of the vertical semiconductor channel 60 is to the vertical axis VA.

In one embodiment, the outer portion 1140 of the source contact layer 114 and the inner portion 1141 of the source contact layer 114 are interconnected to each other by an interconnection portion 114C of the source contact layer 114 that is located within a lateral opening through the vertical semiconductor channel 60. In one embodiment, the memory opening fill structure 58 comprises a dielectric liner 56 that is interposed between the vertical semiconductor channel 60 and the vertical stack of memory elements; and the interconnection portion 114C of the source contact layer 114 extends through a lateral opening in the dielectric liner 56. In one embodiment, the memory opening fill structure 58 comprises a blocking dielectric layer 52 that is interposed between the vertical stack of memory elements and the alternating stack (32, 46); and the interconnection portion 114C of the source contact layer 114 extends through a lateral opening in the blocking dielectric layer 52.

In one embodiment, the inner portion 1141 of the source contact layer 114 comprises a lower cylindrical segment 17 and an upper tapered segment 15 having a tapered convex surface. In one embodiment, the memory opening fill structure 58 comprises a dielectric core 62 that extends vertically through each electrically conductive layer 46 within the alternating stack (32, 46) and has a lopsided (i.e., asymmetric) bottom portion so that the dielectric core 62 has a lesser vertical extent on a side that is proximal to the outer portion 1140 of the source contact layer 114 than on a side that is distal from the outer portion 1140 of the source contact layer 114. In one embodiment, the lopsided bottom portion of the dielectric core 62 has a concave tapered bottom surface that overlies a convex tapered top surface of the inner portion 1141 of the source contact layer 114.

In one embodiment, the concave tapered bottom surface of the lopsided bottom portion of the dielectric core 62 is in contact with the convex tapered top surface of the inner portion 1141 of the source contact layer 114. In one embodiment, the concave tapered bottom surface of the lopsided bottom portion of the dielectric core 62 is spaced from the convex tapered top surface of the inner portion 1141 of the source contact layer 114 by a source-level blocking dielectric layer 144. In one embodiment, each neighboring pair of an electrically conductive layer 46 and an insulating within the alternating stack (32, 46) is vertically spaced from each other by a respective backside blocking dielectric layer 52 having a same material composition as the source-level blocking dielectric layer 144.

In one embodiment, the source contact layer 114 comprises: a source contact metallic barrier layer 114B comprising a conducive metallic nitride or a conductive metallic carbide; and a source contact fill material layer 114F comprising a metal and embedded within the source contact metallic barrier layer 114B. In one embodiment, the memory opening fill structure 58 comprises a dielectric liner 56 that is interposed between the vertical stack of memory elements and the vertical semiconductor channel 60; and the source contact layer 114 comprises a vertically-extending fin 114V that contacts a surface segment of an outer sidewall of the vertical semiconductor channel 60 and contacts a surface segment of the dielectric liner 56. In one embodiment, the inner portion 1141 of the source contact layer 114 is in contact with a segment of an inner sidewall of the vertical semiconductor channel 60. In one embodiment, the source-level material layers 110 comprise: a lower source-level semiconductor layer 112 that underlies the source contact layer 114; and an upper source-level semiconductor layer 116 layer that is interposed between the lower source-level semiconductor layer 112 and alternating stack (32, 46) and embedding the source contact layer 114.

In one embodiment, the outer portion 1140 of the source contact layer 114 comprises a stem portion that laterally extends along a first horizontal direction hd1 and multiple branch portions that laterally extend along a second horizontal direction hd2 that is different from the first horizontal direction hd1; and the semiconductor structure further comprises additional memory openings 49 and additional memory opening fill structures 58 that are located in the additional memory openings 49, wherein each of the additional memory opening fill structures 58 comprises a respective additional vertical semiconductor channel 60 that contacts a respective branch portion of the source contact layer 114.

The first and second embodiments of the present disclosure may be employed to provide a source contact layer 114 comprising, and/or consisting essentially of, at least one metallic material. Further, the various embodiments of the present disclosure may be employed to provide a source contact layer 114 that contacts, or is electrically connected to, an inner cylindrical sidewall of vertical semiconductor channels 60, thereby enhancing the electric contact between the source contact layer 114 and bottom ends of the vertical semiconductor channels 60. In addition, the various embodiments of the present disclosure may be employed to puncture lateral openings through each memory film 50 and through each vertical semiconductor channel 60 to provide a configuration in which inner portions 1141 of the source contact layer 114 are formed within volumes of memory openings 49. Further, some embodiments of the present disclosure provide a source contact layer 114 having the same material composition as electrically conductive layers 46. Yet further, some embodiments of the present disclosure provide a source-side blocking dielectric layer 144. Electrical contact between the source contact layer 114 and the vertical semiconductor channels 60 can be provided by charge carrier tunneling, which is enabled by employing a thin dielectric material suitable for quantum tunneling for the source-side blocking dielectric layer 144.

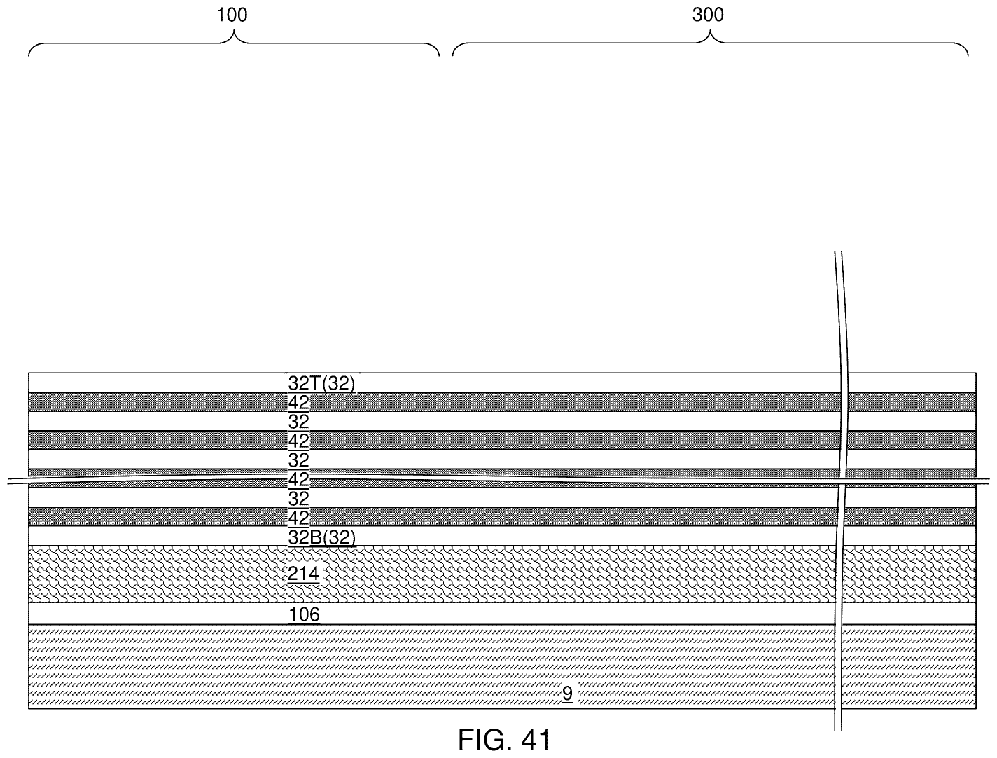

Referring to FIG. 41, a third exemplary structure according to a third embodiment of the present disclosure is illustrated. The third exemplary structure comprises the carrier substrate 9, which may be a semiconductor substrate or a conductive substrate. The stopper insulating layer 106 can be formed on a top surface of the carrier substrate 9.

A source semiconductor layer 214 can be formed over the stopper insulating layer 106. The source semiconductor layer 214 may include a doped semiconductor material such as doped polysilicon or doped amorphous silicon. The conductivity type of the source semiconductor layer 214 may be the opposite of the conductivity of vertical semiconductor channels to be subsequently formed. For example, if the vertical semiconductor channels to be subsequently formed have a doping of a first conductivity type, the source semiconductor layer 214 has a doping of a second conductivity type that is the opposite of the first conductivity type. The atomic concentration of dopants of the second conductivity type in the source semiconductor layer 214 may be in a range from 5×10¹⁸/cm³ to 2×10²¹/cm³, although lesser and greater atomic concentrations may also be employed. The thickness of each of the source semiconductor layer 214 may be in a range from 100 nm to 400 nm, such as from 150 nm to 300 nm, although lesser and greater thicknesses may also be used.

The alternating stack (32, 42) of insulating layers 32 and sacrificial material layers 42 can be formed over the source semiconductor layer 214. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

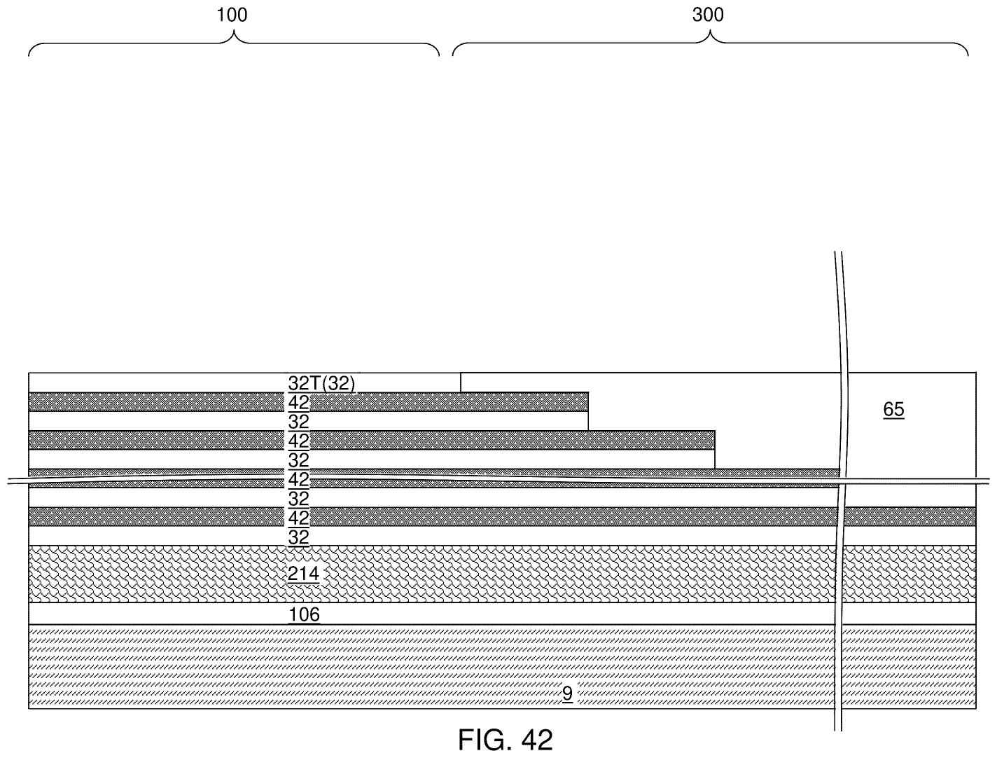

Referring to FIG. 42, the stepped surfaces are optionally formed in the contact region 300. The stepped cavity is formed within the volume from which portions of the alternating stack (32, 42) are removed through formation of the stepped surfaces. The stepped dielectric material portion 65 (i.e., an insulating fill material portion) can be formed in the stepped cavity. Optionally, drain-select-level isolation structures (not shown) can be formed through the topmost insulating layer 32T and a subset of the sacrificial material layers 42 located at drain-select-levels.

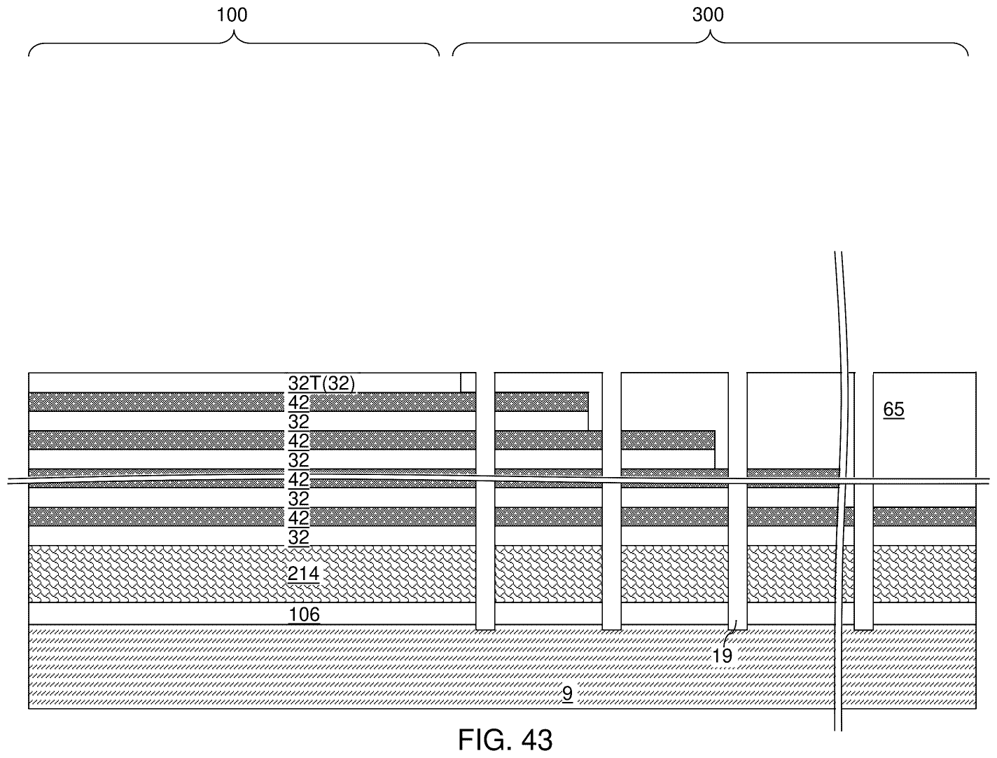

Referring to FIG. 43, the optional support openings 19 can be formed through the stepped dielectric material portion 65 and the alternating stack (32, 42) in the contact region 300. Each of the support openings 19 can vertically extend through the source semiconductor layer 214 and into the stopper insulating layer 106.

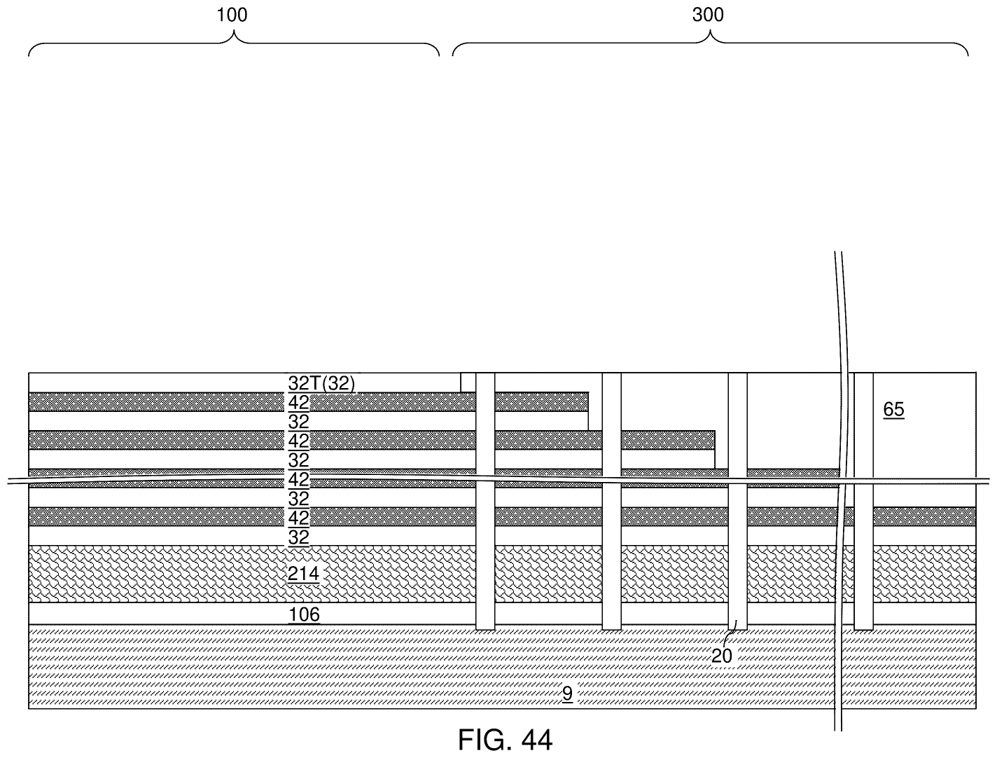

Referring to FIG. 44, the support pillar structures 20 are formed in the support openings 19.

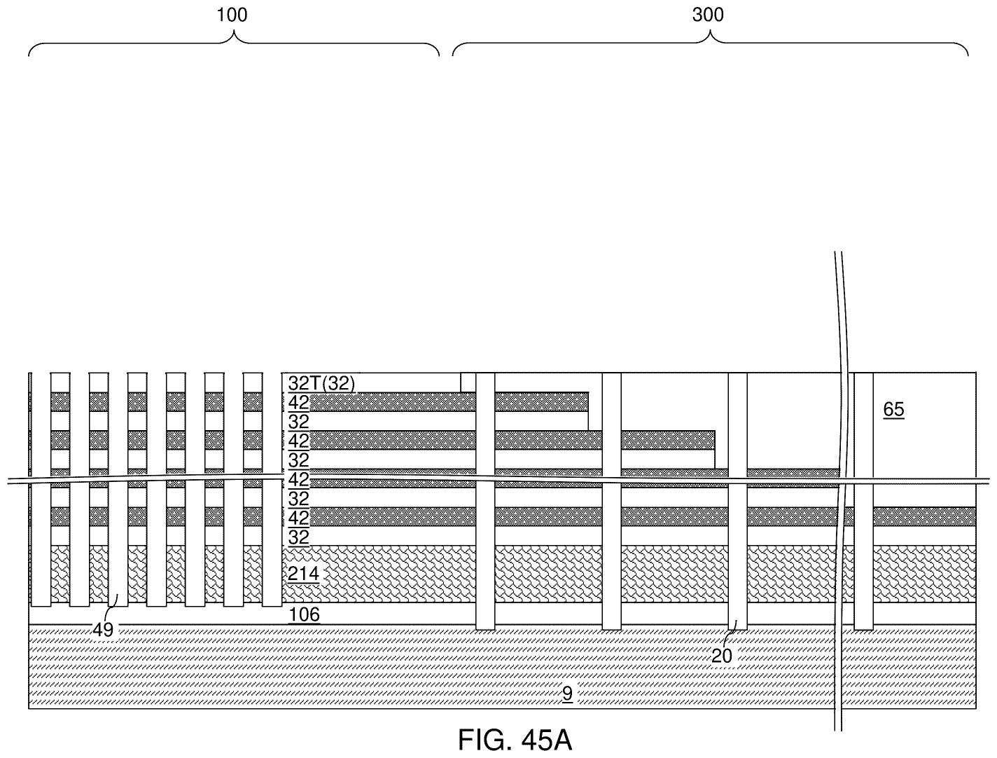

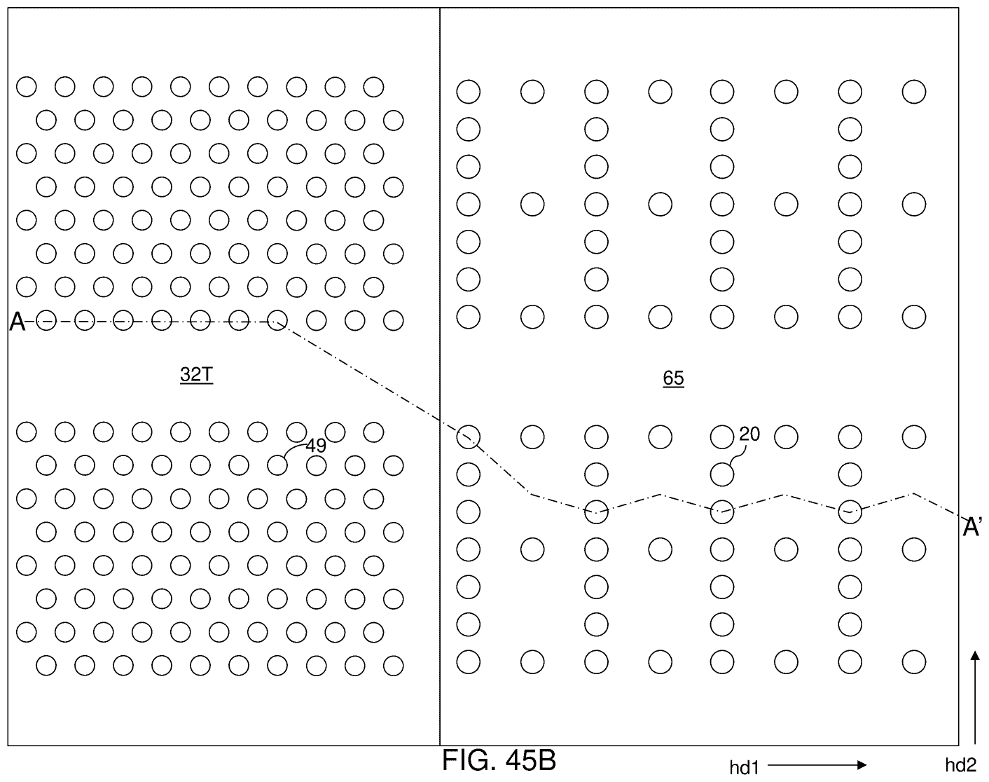

Referring to FIGS. 45A and 45B, the memory openings 49 are be formed through the alternating stack (32, 42) in the memory array region 100. Each of the memory openings 49 can vertically extend through the source semiconductor layer 214 and into the stopper insulating layer 106.

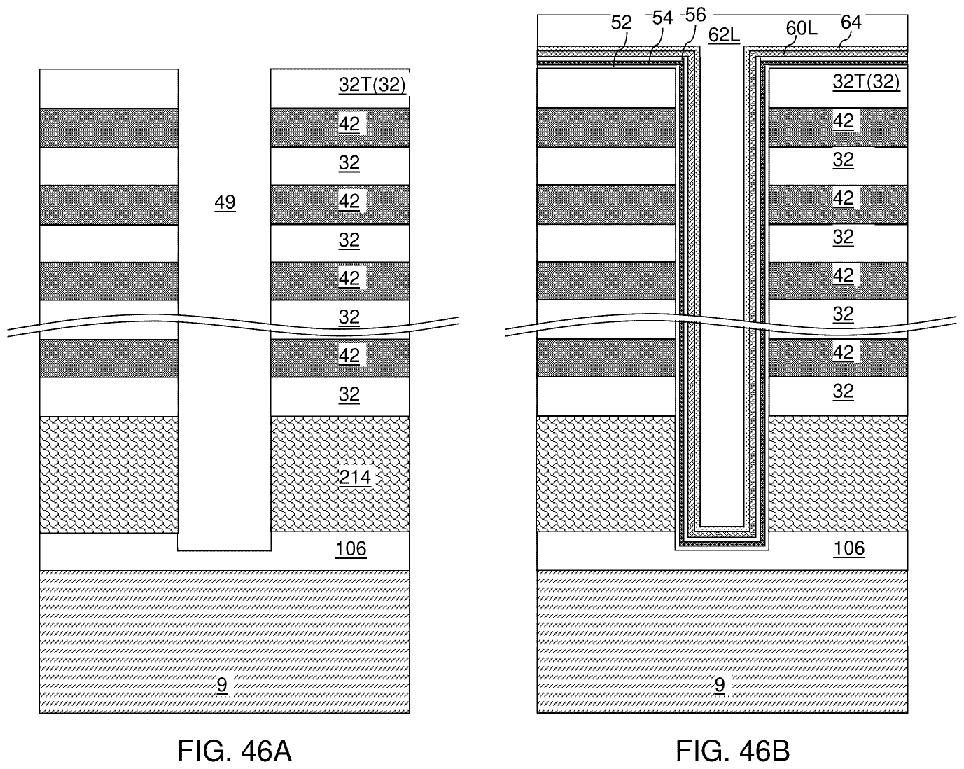

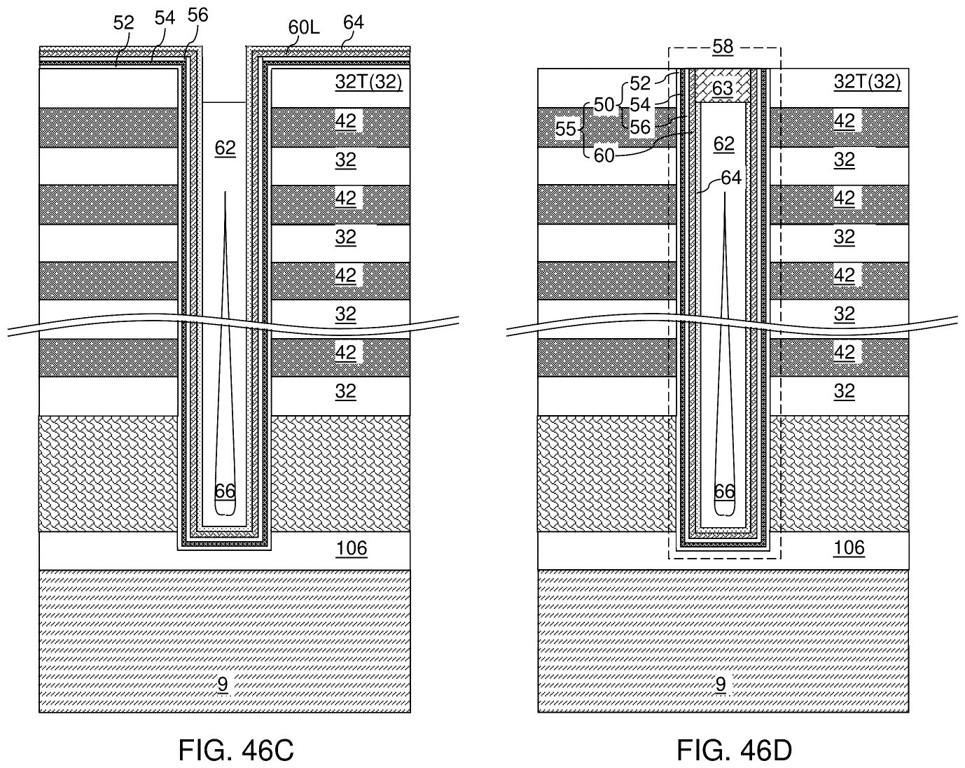

FIGS. 46A-46D are sequential vertical cross-sectional views of a memory opening 49 during formation of a memory opening fill structure 58 according to the third embodiment of the present disclosure.

Referring to FIG. 46A, a memory opening 49 is illustrated after the processing steps of FIG. 45.

Referring to FIG. 46B, the layer stack including the memory material layer 54 can be conformally deposited. In an illustrative example, the layer stack may comprise the optional blocking dielectric layer 52, the memory material layer 54, and the optional dielectric liner 56.

According to an aspect of the present disclosure, the etch stop dielectric layer 64 can be conformally deposited over the layer stack (52, 54, 56). The etch stop dielectric layer 64 comprises a dielectric material that is different from the material of the dielectric liner 56. The dielectric material of the etch stop dielectric layer 64 can also be different from the material of the memory material layer 54. In one embodiment, the dielectric liner 56 comprises an ONO stack which is a layer stack including a first silicon oxide layer, a silicon nitride layer, and a second silicon oxide layer. In this case, the etch stop dielectric layer 64 comprises and/or consists essentially of a dielectric metal oxide material such as aluminum oxide, tantalum oxide, hafnium oxide, zirconium oxide, yttrium oxide, lanthanum oxide, etc. Generally, the etch stop dielectric layer 64 comprises a material exhibiting high etch resistance to a wet etch process employing dilute hydrofluoric acid. The etch stop dielectric layer 64 can be deposited by a conformal deposition process, such as an atomic layer deposition process or a chemical vapor deposition process. The thickness of the etch stop dielectric layer 64 may be in a range from 3 nm to 20 nm, such as from 6 nm to 10 nm, although lesser and greater thicknesses may also be employed.

The semiconductor channel material layer 60L can be deposited over the etch stop dielectric layer 64 by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed.

The dielectric core layer 62L comprising a dielectric fill material can be deposited in remaining volumes of the memory openings 49 and over the alternating stack (32, 42). While the dielectric core layer 62L can be deposited employing a conformal deposition process such as a chemical vapor deposition process, the conformity of the conformal deposition process may not be perfect. Thus, the thickness of a bottom portion of the dielectric core layer 62L at the bottom of each memory opening 49 may be less than the thickness of an upper portion of the dielectric core layer 62L at the top of each memory opening 49. A scam or airgap can be formed in a bottom portion of each memory opening 49 that is not filled with the dielectric fill material of the dielectric core layer 62L. The seams or airgaps are herein referred to as core voids 66. The core voids 66 may vertically extend through a subset of layers of the alternating stack (32, 42) located at a bottom portion of the alternating stack (32, 42), and may have a variable lateral extent that generally decreases with a vertical distance from the horizontal plane including the top surface of the carrier substrate 9.

Referring to FIG. 46C, the dielectric core layer 62L can be vertically recessed such that each remaining portion of the dielectric core layer 62L has a top surface at or about the horizontal plane including the bottom surface of the topmost insulating layers 32T. Each remaining portion of the dielectric core layer 62L constitutes a dielectric core 62. A core void 66 may be embedded within at least one of the dielectric cores 62.

Referring to FIG. 46D, an etch process can be performed to remove physically exposed portions of the etch stop dielectric layer 64. The etch process may comprise a selective etch process that etches the material of the etch stop dielectric layer 64 selective to the semiconductor material of the semiconductor channel layer 60L. In an illustrative example, if the etch stop dielectric layer 64 comprises aluminum oxide, the etch process may comprise a wet etch process employing a mixture of phosphoric acid, acetic acid, and deionized water. If the etch stop dielectric layer 64 comprises hafnium oxide, the isotropic etch process may comprise a wet etch process employing a mixture of ammonium fluoride, hydrogen peroxide, and deionized water. If the etch stop dielectric layer 64 comprises tantalum oxide, the isotropic etch process may comprise a wet etch process employing a mixture of ammonium fluoride, hydrofluoric acid, and deionized water.

A doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Portions of the etch stop dielectric layer 64 that overlie the horizontal plane including the top surface of the topmost insulating layer 32T can be removed during the planarization process. Each portion of the layer stack (52, 54, 56) including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, a drain region 63 and an etch stop dielectric layer 64 within a memory opening 49 constitutes a memory opening fill structure 58.

Each drain region 63 is vertically spaced from the carrier substrate 9 and the stopper insulating layer 106 by a respective dielectric core 62, and contacts an end portion of a respective vertical semiconductor channel 60. Each etch stop dielectric layer 64 is in contact with the drain region 63.

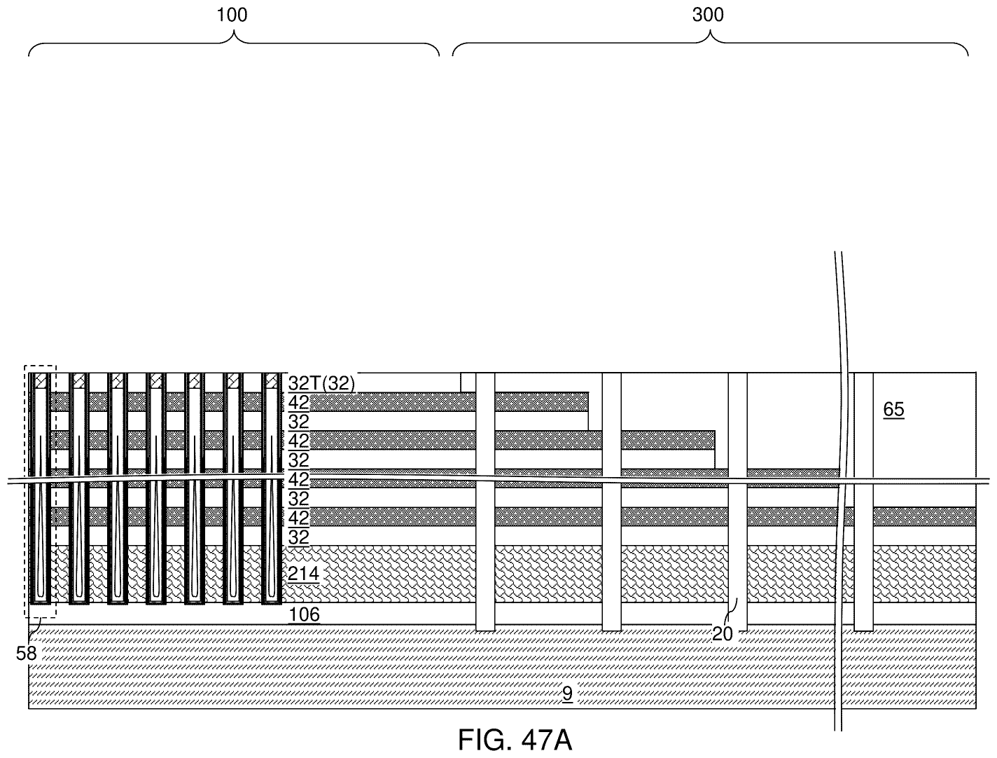

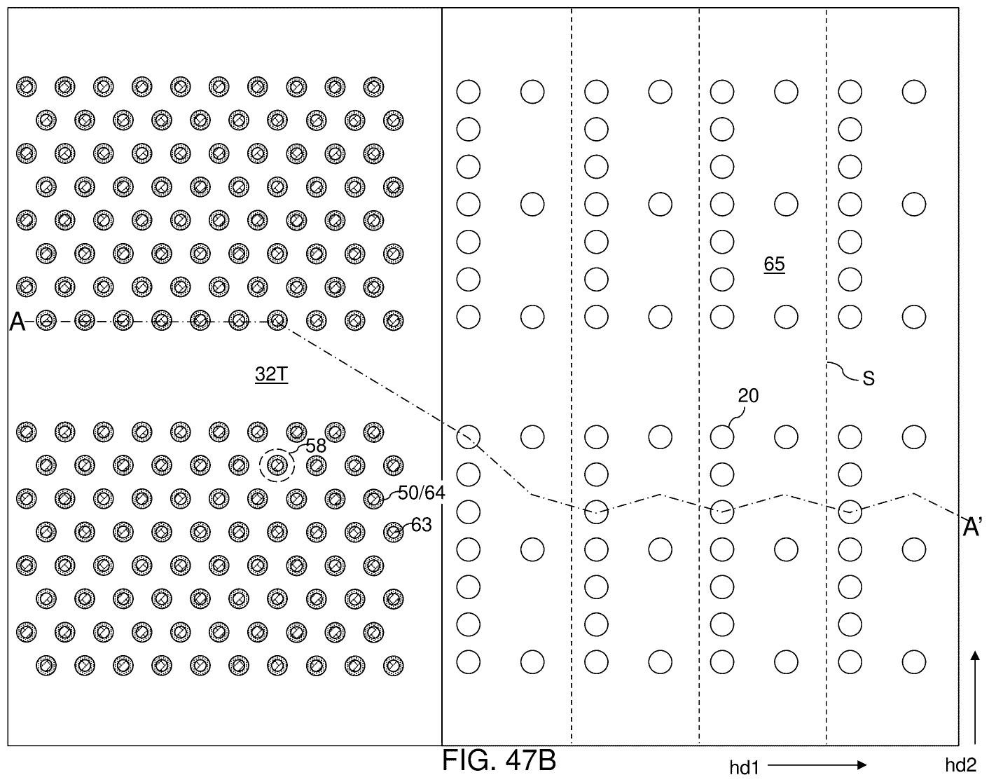

Referring to FIGS. 47A and 47B, the third exemplary structure is illustrated after formation of memory opening fill structures 58 within the memory openings 49.

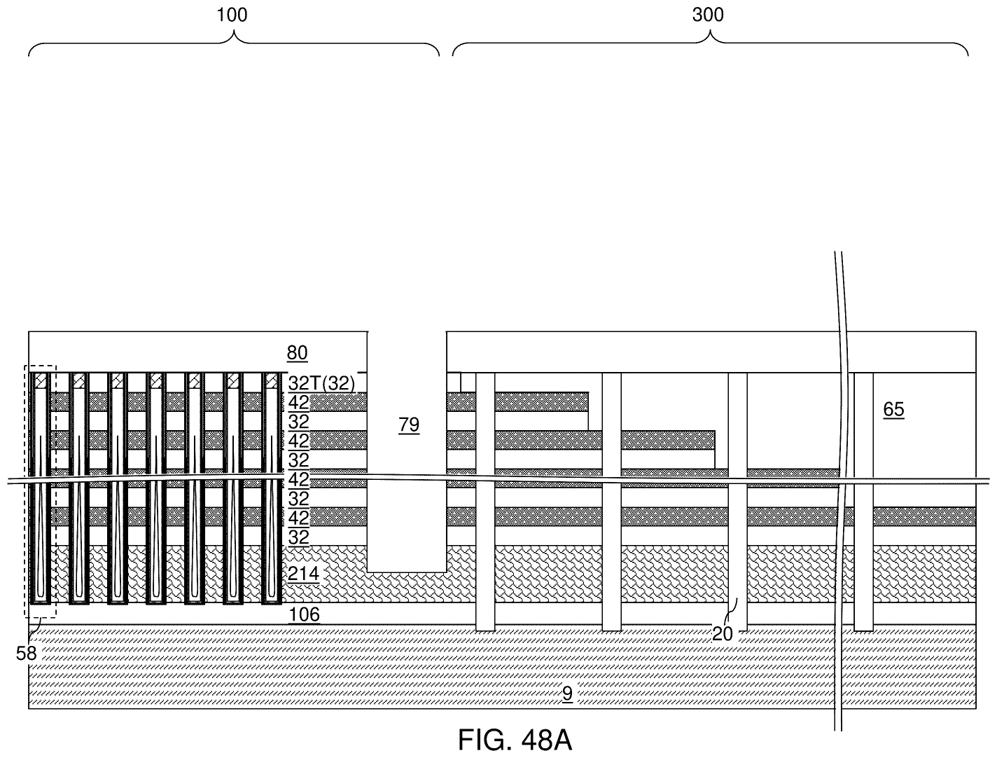

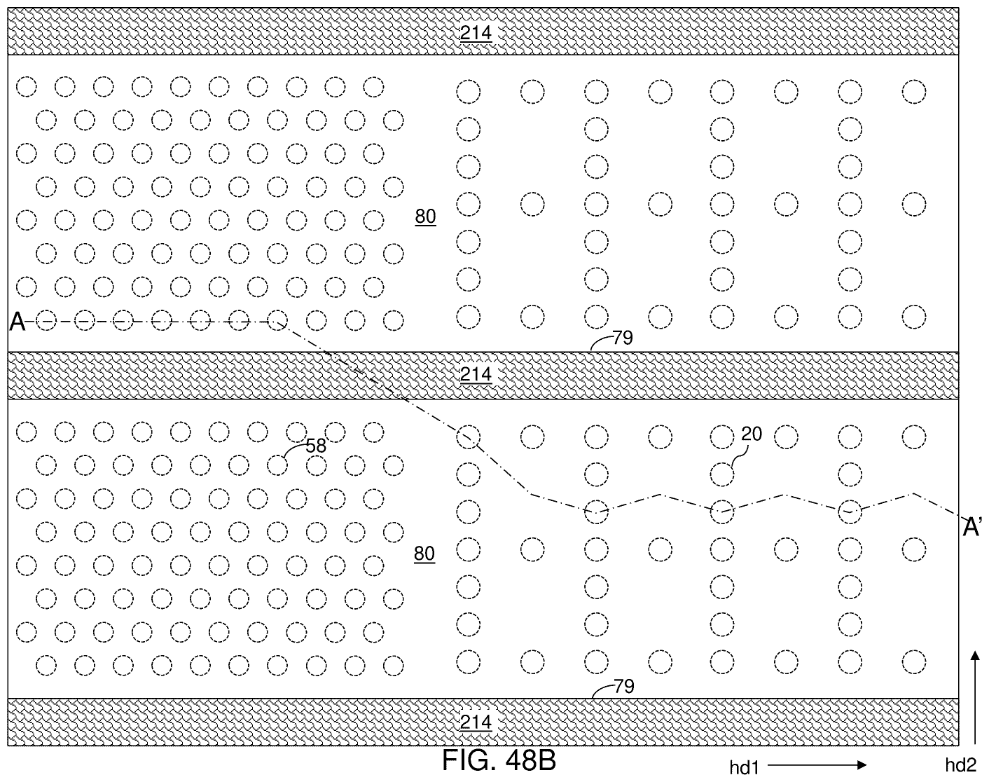

Referring to FIGS. 48A and 48B, a dielectric material, such as undoped silicate glass or a doped silicate glass, can be deposited over the alternating stack (32, 42) to form the contact-level dielectric layer 80.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portion 65, and into an upper portion of the source semiconductor layer 214. Lateral isolation trenches 79 laterally extending along the first horizontal direction hd1 can be formed through the alternating stack (32, 42), the stepped dielectric material portion 65, and the contact-level dielectric layer 80. Each of the lateral isolation trenches 79 may comprise a respective pair of lengthwise sidewalls that are parallel to the first horizontal direction hd1 and vertically extend from the stopper insulating layer 106 to the top surface of the contact-level dielectric layer 80. A surface of the source semiconductor layer 214 can be physically exposed underneath each lateral isolation trench 79. The photoresist layer can be subsequently removed, for example, by ashing.

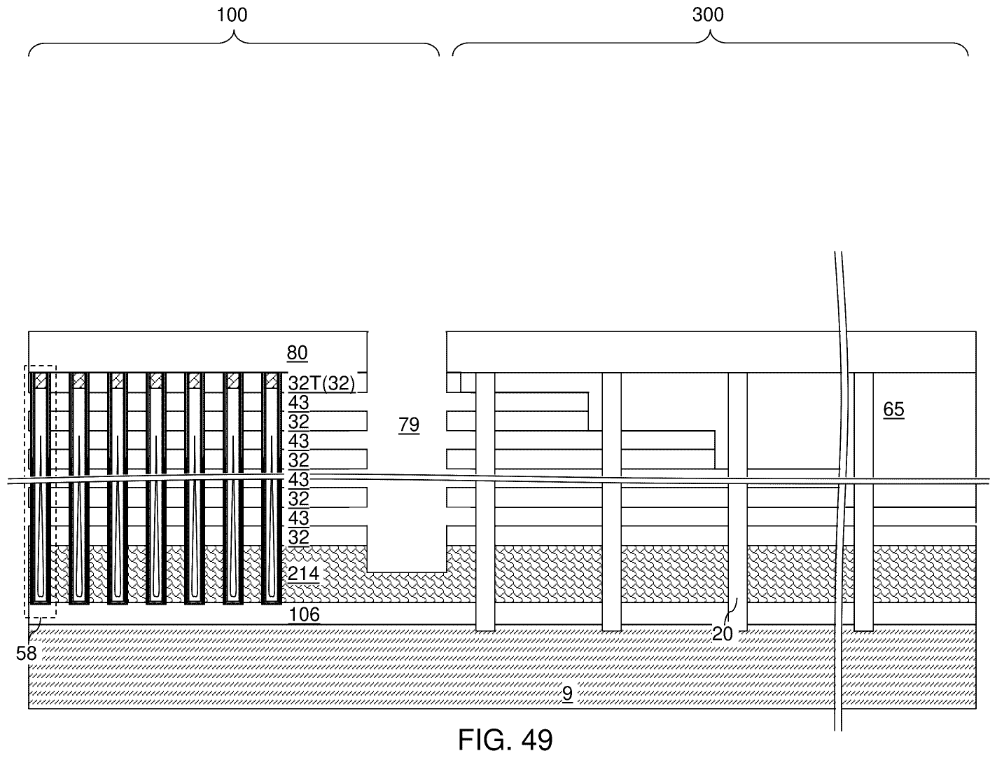

Referring to FIG. 49, an isotropic etch process can be performed to remove the sacrificial material layers 42 selective to the insulating layers 32, the stopper insulating layer 106, the memory opening fill structures 58, the sacrificial etch stop liners 71, and the source semiconductor layer 214. Laterally-extending cavities 43 can be formed in volumes from which the sacrificial material layers 42 are removed.

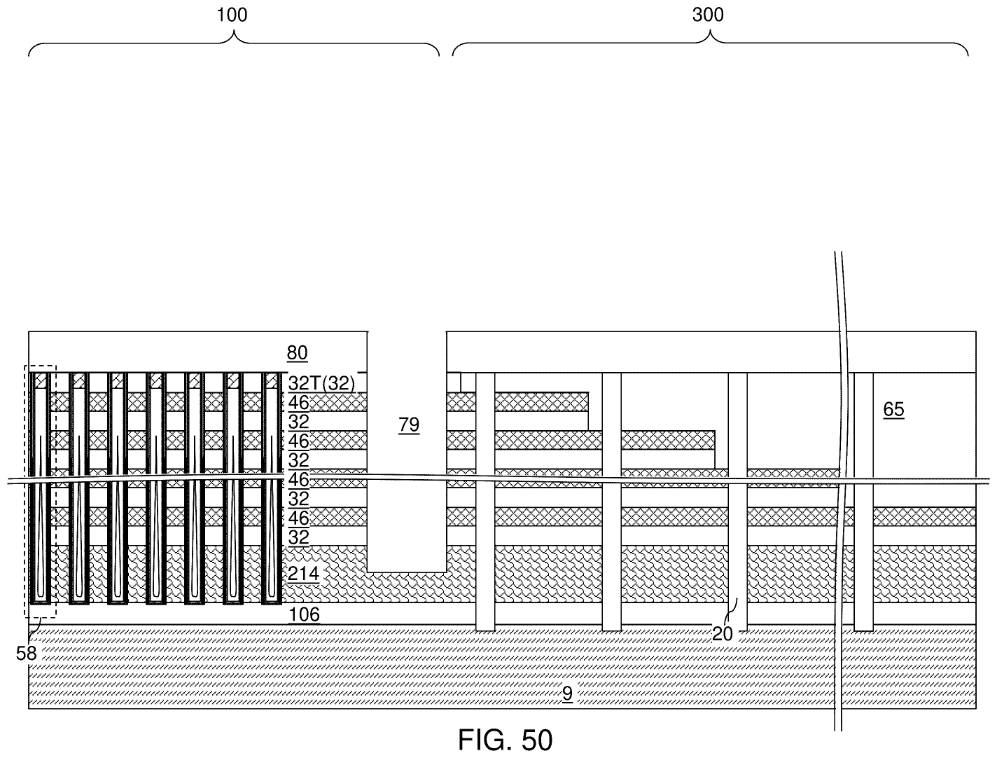

Referring to FIG. 50, the backside blocking dielectric layer (not shown) can be optionally formed in the laterally-extending cavities 43 by a conformal deposition process. At least one conductive material, such as at least one metallic material, can be conformally deposited in the laterally-extending cavities 43. Excess portions of the at least one conductive material that are deposited in the lateral isolation trenches 79 or above the contact-level dielectric layer 80 can be removed by performing an etch-back process, which may comprise an isotropic etch process and/or an anisotropic etch process. Each remaining portion of the at least one conductive material filling a respective one of the laterally-extending cavities 43 constitutes the electrically conductive layer 46.

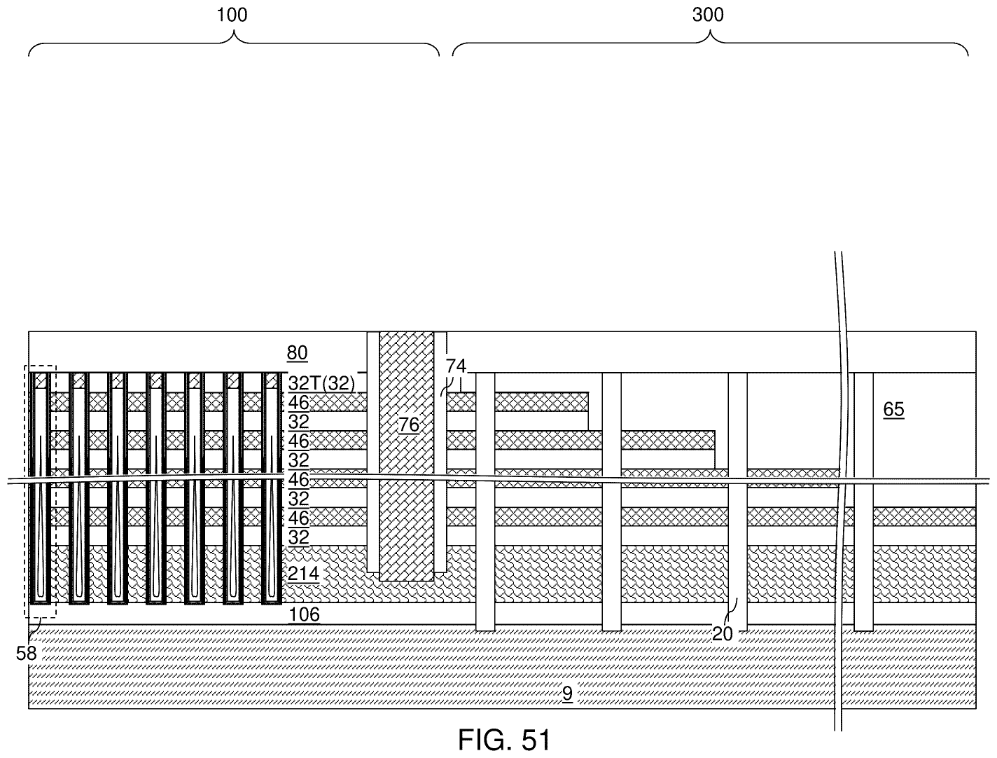

Referring to FIG. 51, an insulating material may be conformally deposited and anisotropically etched to form an insulating spacer 74 at the periphery of each of the lateral isolation trenches 79. At least one conductive fill material may be deposited in remaining volumes of the lateral isolation trenches 79 to form a conductive wall structure 76. Each contiguous combination of a conductive wall structure 76 and an insulating spacer 74 constitutes an isolation trench fill structure (74, 76) that fills a respective lateral isolation trench 79. In an alternative embodiment, each isolation trench fill structure may consist of a respective dielectric fill material portion.

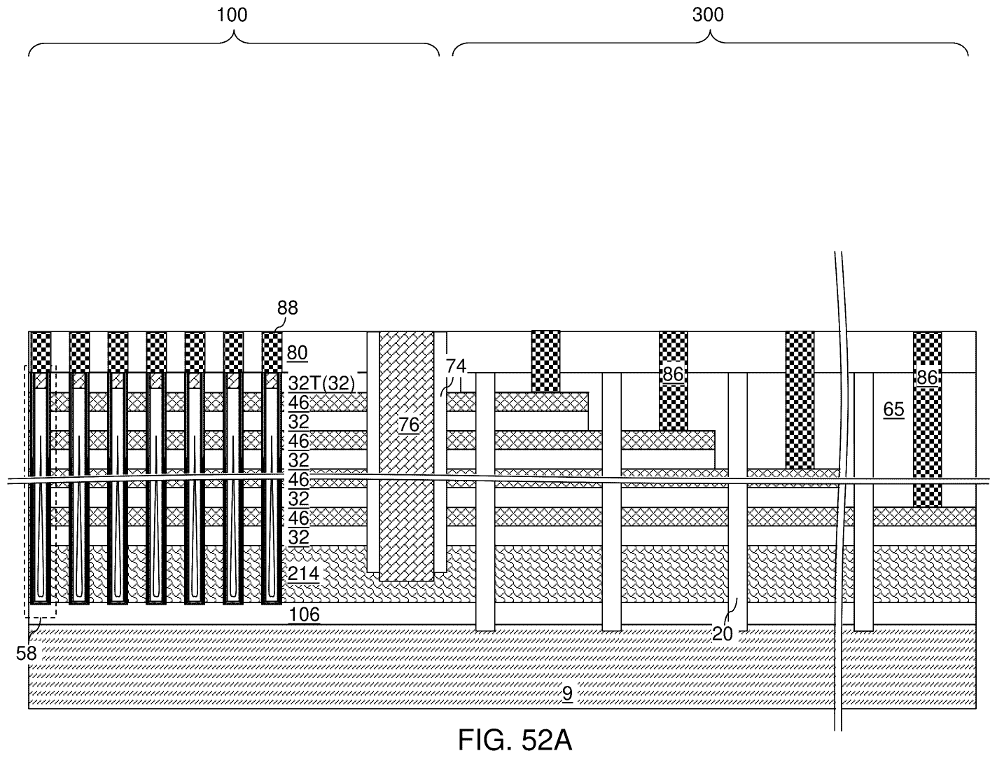

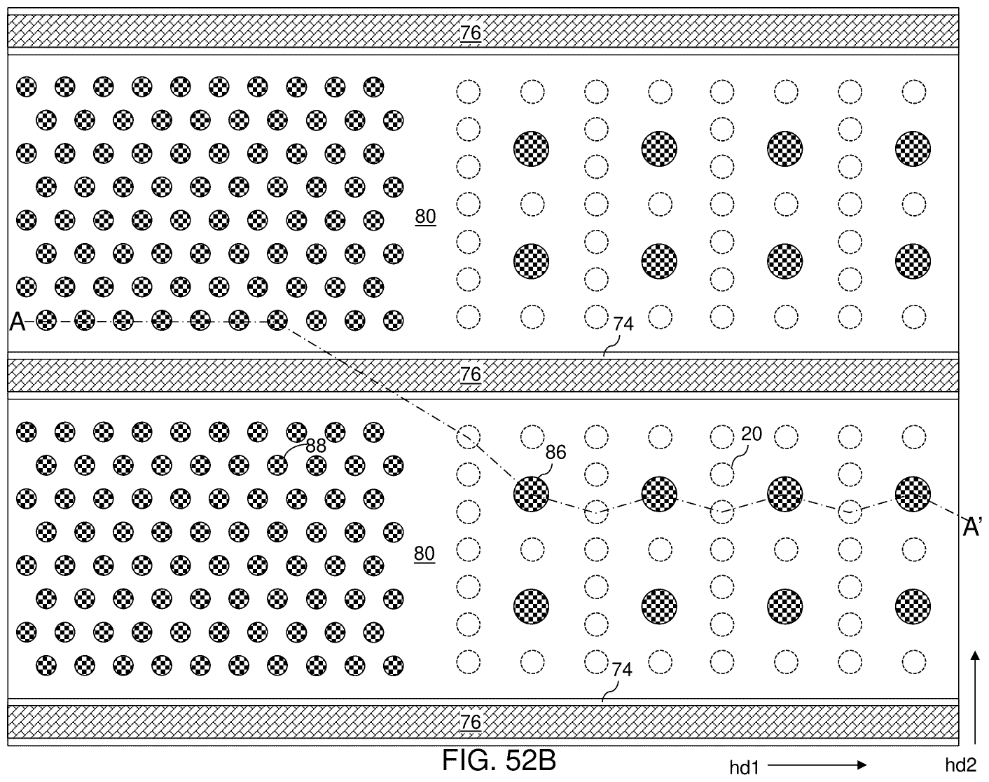

Referring to FIGS. 52A and 52B, a photoresist layer (not shown) can be applied over the contact-level dielectric layer 80, and can be lithographically patterned to form openings over each of the memory opening fill structures 58 over the horizontally-extending surfaces of the stepped surfaces in the contact region 300. An anisotropic etch process can be performed to transfer the pattern of the openings in the photoresist layer through the contact-level dielectric layer 80 and the stepped dielectric material portion 65. Drain contact via cavities can be formed through the contact-level dielectric layer 80 over the memory opening fill structures 58. Layer contact via cavities can be formed through the contact-level dielectric layer 80 and the stepped dielectric material portion 65 on a top surface of a respective one of the electrically conductive layers 46. The photoresist layer can be subsequently removed, for example, by ashing.

At least one conductive material, such as a combination of a metallic barrier material and a metallic fill material, can be deposited in the drain contact via cavities and the layer contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63. Remaining portions of the at least one conductive material that fill the layer contact via cavities constitute layer contact via structures 86 contacting a top surface of a respective one of the electrically conductive layers 46.

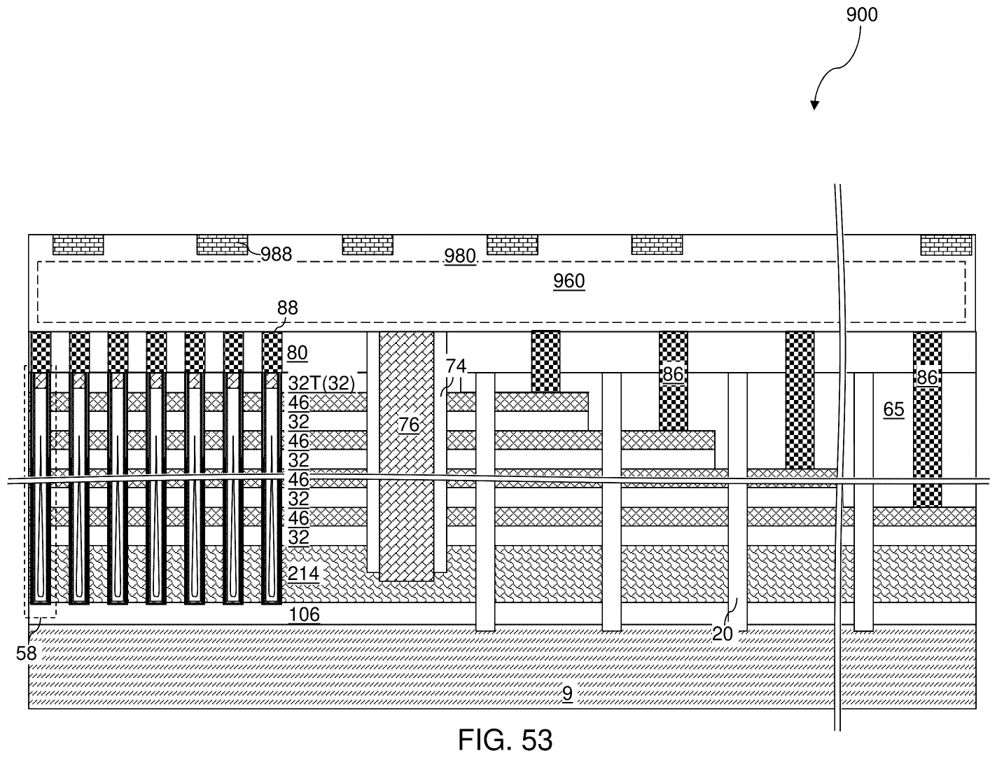

Referring to FIG. 53, the memory-side dielectric material layers 960, the memory-side dielectric material layers 980 and the upper bonding pads 988 are formed in the memory die 900 as described above with respect to the first embodiment. The memory-side dielectric material layers 960 comprise a bit-line-level dielectric material layer embedding bit lines, which are a subset of the memory-side metal interconnect structures 980.

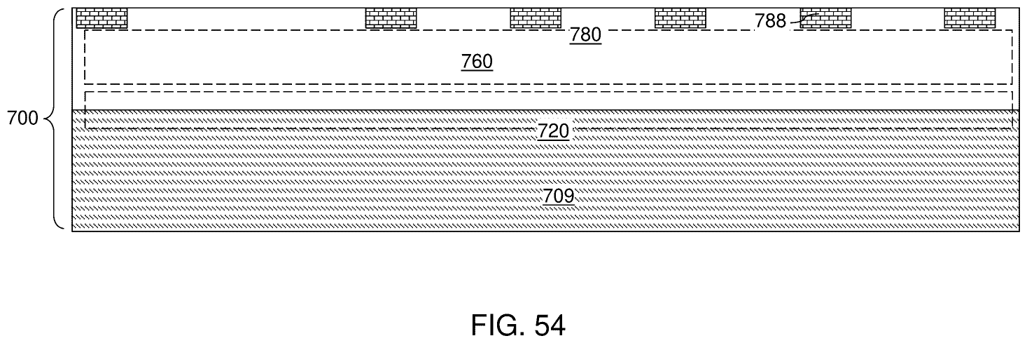

Referring to FIG. 54, the logic die 700 can be provided as described above with respect to the first embodiment.

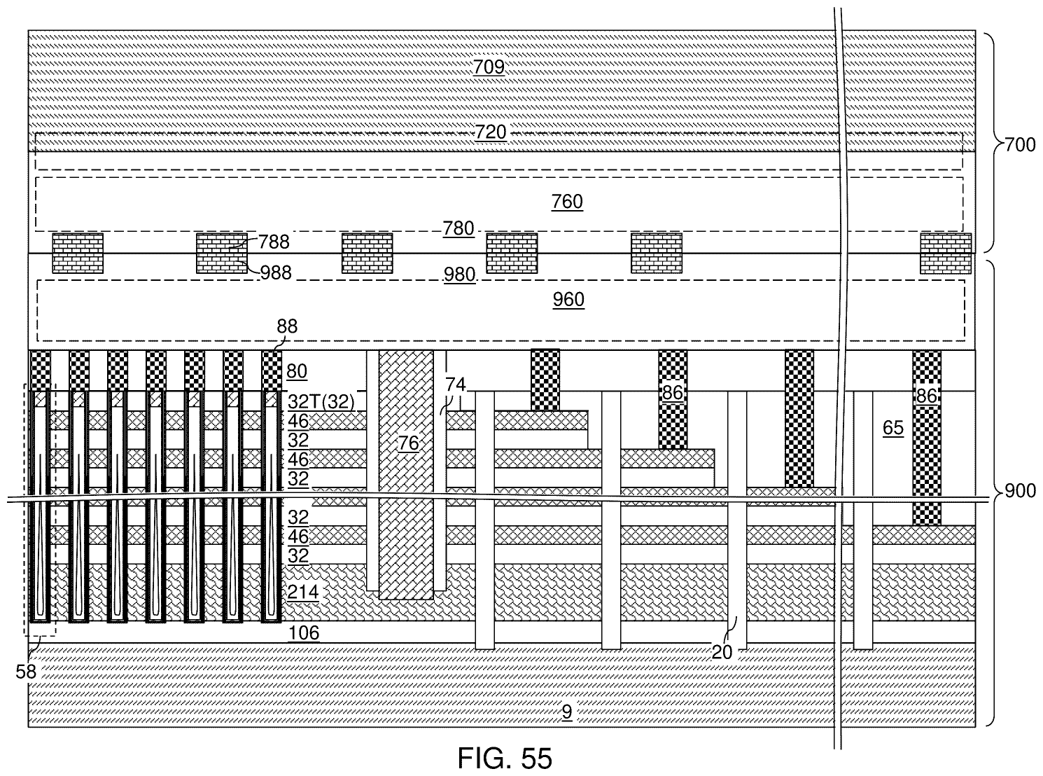

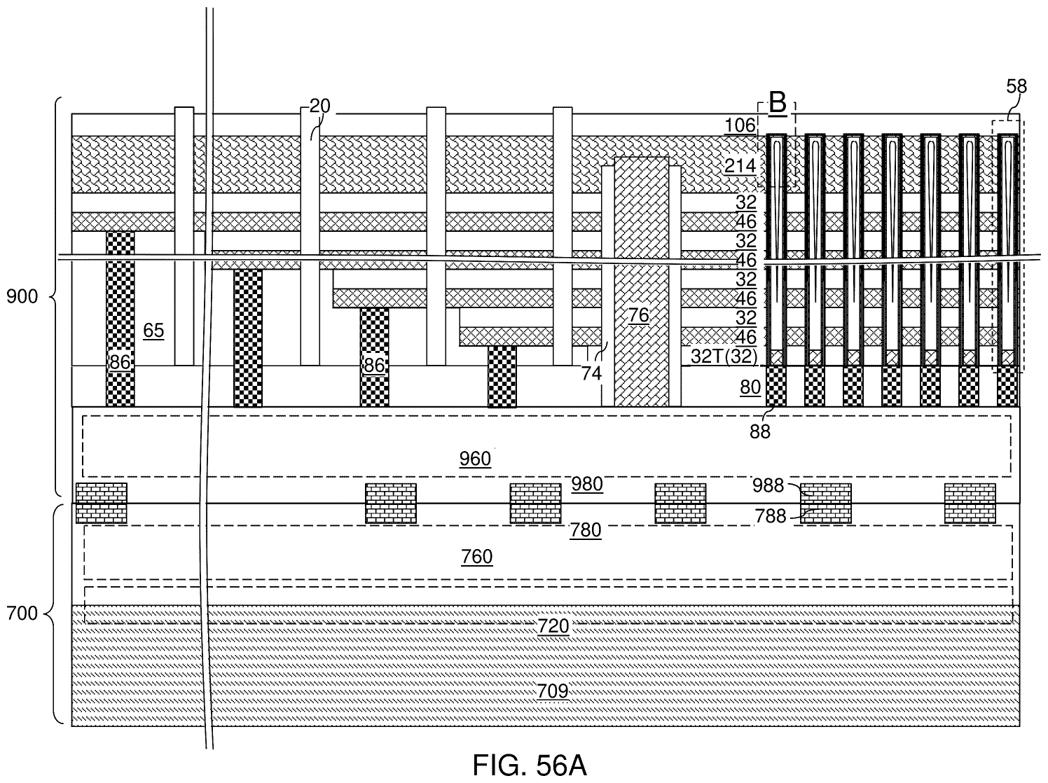

Referring to FIG. 55, the logic die 700 can be attached to the memory die 900, for example, by bonding the logic-side bonding pads 788 to the memory-side bonding pads 988, as described above.

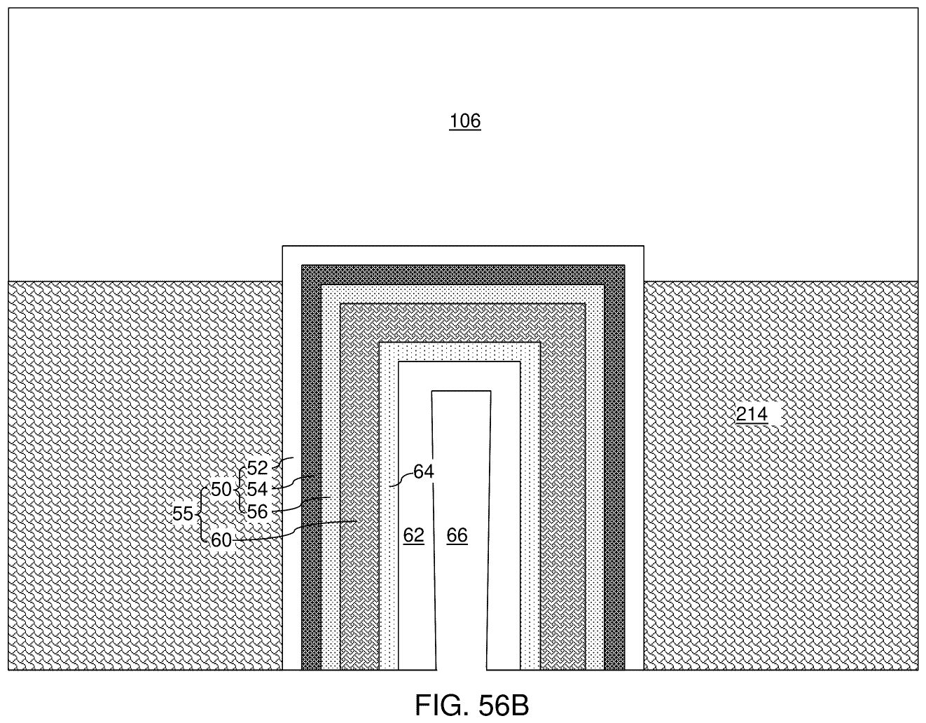

Referring to FIGS. 56A and 56B, the carrier substrate 9 can be removed, for example, by grinding, polishing, cleaving, an isotropic etch process, and/or an anisotropic etch process, as described above with respect to the first embodiment.

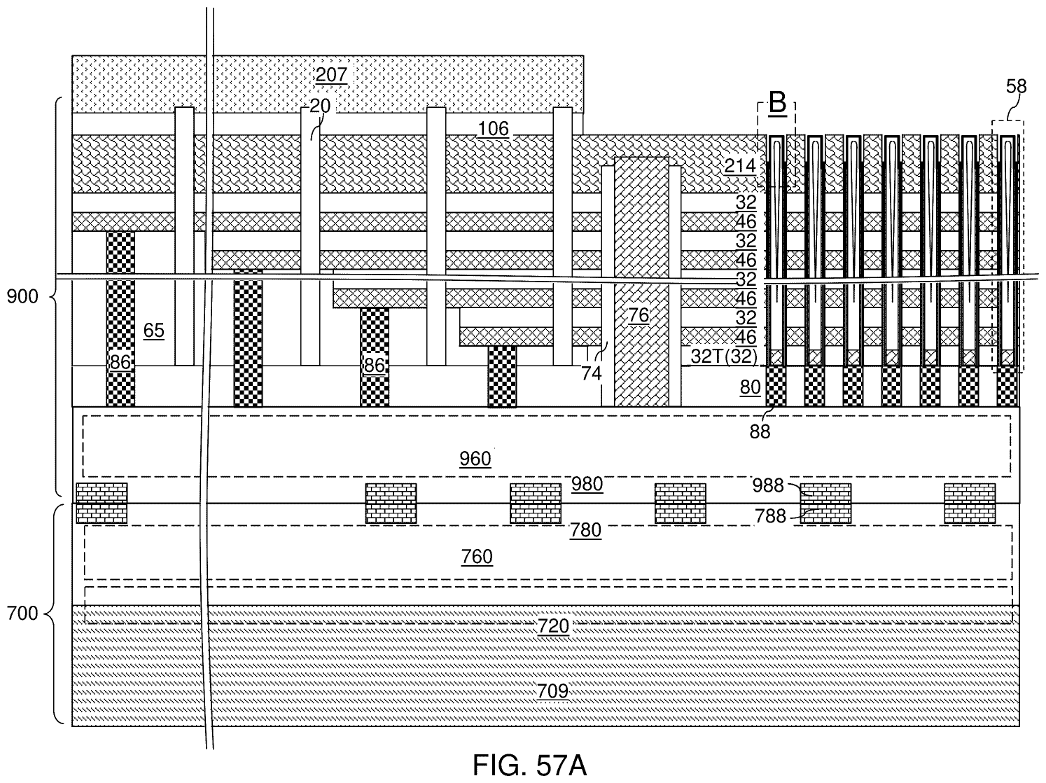

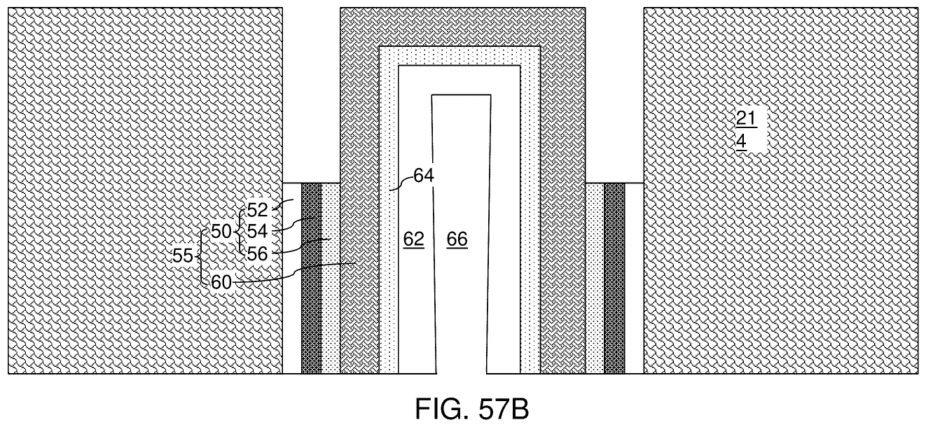

Referring to FIGS. 57A and 57B, a photoresist layer 207 can be applied over the backside surface of the stopper insulating layer 106, and can be lithographically patterned to cover the contact region 300 (i.e., the region in which layer contact via structures 86 are present) without covering the memory array region 100 (i.e., the region in which the memory opening fill structures 58 are present). A selective etch process can be performed to etch the material of the stopper insulating layer 106 selective to the semiconductor materials of the source semiconductor layer 214 and the vertical semiconductor channels 60. In an illustrative example, the selective etch process may comprise a wet etch process employing dilute hydrofluoric acid that etches a silicon oxide material of the stopper insulating layer 106. In another example, the selective etch process may comprise a reactive ion etch process that employs CHF₃ and O₂. In this case, physical exposure of the backside surface of the source semiconductor layer 214 can be detected during the reactive ion etch process, and can be employed to determine the endpoint of the reactive ion etch process and the duration of the overetch step of the reactive ion etch process.

In some embodiments, the blocking dielectric layers 52 may comprise silicon oxide, and end portions of the blocking dielectric layers 52 may be collaterally removed during the selective etch process. In case end portion of the memory material layers 54 and the dielectric liners 56 are not collaterally removed during the selective etch process, the end portions of the memory material layers 54 and the dielectric liners 56 may be subsequently removed by performing at least one isotropic etch process (such as a wet etch process) having an etch chemistry that is selective to the semiconductor materials of the vertical semiconductor channels 60 and the source semiconductor layer 214. For example, if the memory material layers 54 comprise silicon nitride and if the dielectric liners 56 comprise silicon oxide, a first wet etch process employing a combination of hot phosphoric acid can be performed to remove the end portions of the memory material layers 54, and a second wet etch process employing dilute hydrofluoric acid can be performed to remove end portions of the dielectric liners 56.

Generally, at least a portion of the stopper insulating layer 106 can be removed after removal of the carrier substrate 9 such that an end portion of each memory opening fill structure 58 is exposed. Further, an end portion of each memory film 50 can be removed by performing a selective etch process that etches materials of the memory film 50 selective to the material of the vertical semiconductor channel 60 and selective to a material of the source semiconductor layer 214. Thus, an end surface (which may be a planar end surface) and a cylindrical sidewall surface segment of each vertical semiconductor channel 60 can be removed after the selective etch process. Further, a backside surface of the source semiconductor layer 214 and each end surface of the memory films 50 can be physically exposed after the selective etch process. Each memory film 50 may have a tubular configuration after the selective etch process.

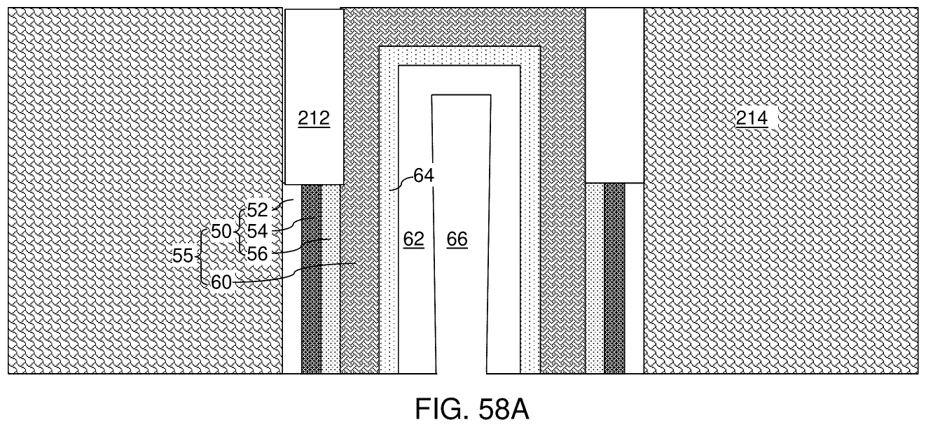

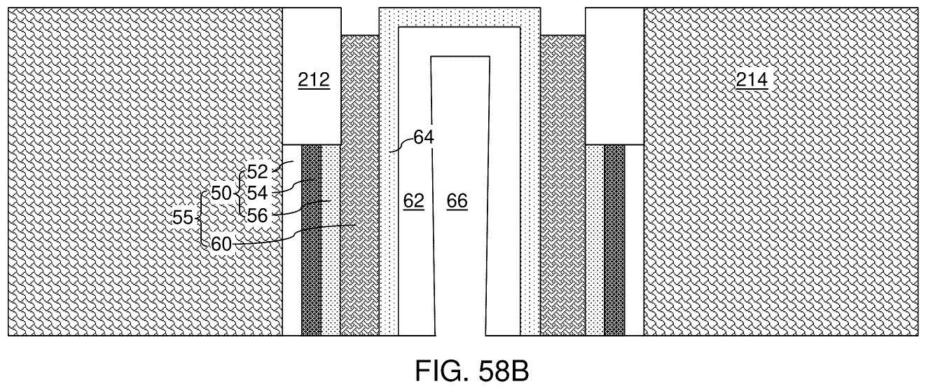

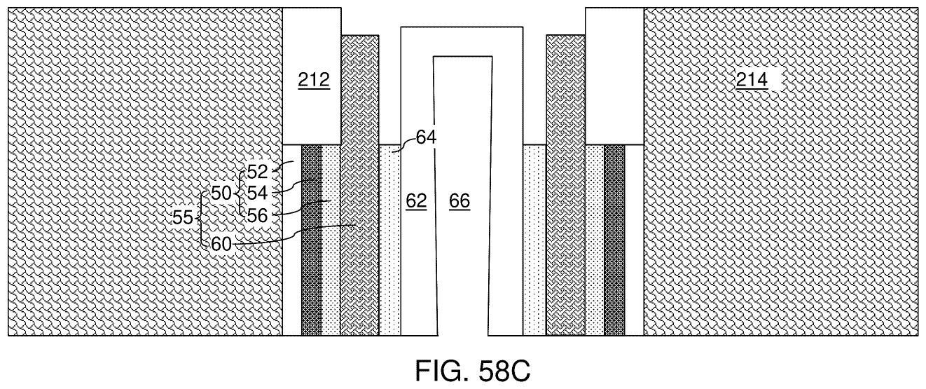

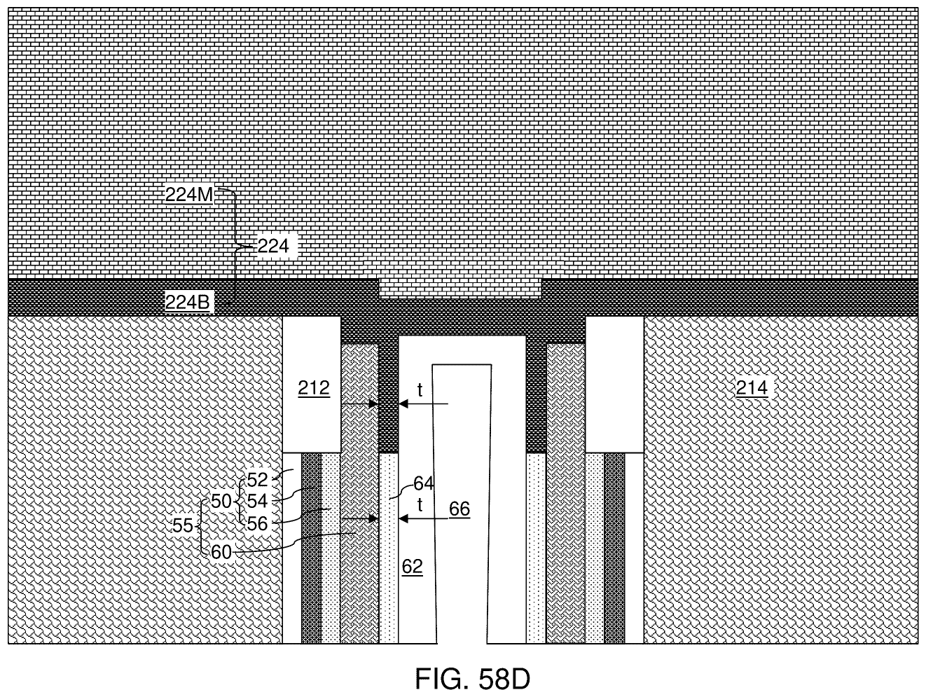

FIGS. 58A-58D are sequential vertical cross-sectional views of a region of a first configuration of the third exemplary structure during formation of backside source structure 224 according to an embodiment of the present disclosure.

Referring to FIG. 58A, a dielectric fill material such as silicon oxide can be conformally deposited in the cylindrical gaps around end portions of the vertical semiconductor channels 60. The dielectric fill material may be deposited by a conformal deposition process such as a chemical vapor deposition process or an atomic layer deposition process. Gaps around end portions of the vertical semiconductor channels 60 can be filled with the dielectric fill material. An isotropic recess etch process can be performed to remove a horizontally-extending portion of the deposited dielectric fill material from above the backside surface of the source semiconductor layer 214. Remaining cylindrical portions of the deposited dielectric fill material constitute tubular spacers, which are herein referred to as dielectric tubular spacers 212.

Referring to FIG. 58B, a first isotropic etch process that etches the semiconductor materials of the vertical semiconductor channels 60 and the source semiconductor layer 214 can be performed. For example, the first isotropic etch process may comprise a wet etch process employing tetramethyl aluminum hydroxide (TMAH) or TYM that etches silicon selective to silicon oxide and dielectric metal oxide materials. End portions of the vertical semiconductor channels 60 can be removed by the first isotropic etch process. Upon removal of the end portions of the vertical semiconductor channels 60, each vertical semiconductor channel 60 can have a respective tubular configuration after the first isotropic etch process. Thus, each vertical semiconductor channel 60 may have a physically exposed annular end surface after the isotropic etch process. According to an aspect of the present disclosure, the etch stop dielectric layer 64 prevents collateral etching of the material dielectric material of the dielectric cores 62. Thus, the core voids 66 remain encapsulated within a respective one of the dielectric cores 62 and are not expanded in the vertical direction.

Referring to FIG. 58C, end portions of the etch stop dielectric layers 64 can be removed by performing a second isotropic etch process that isotropically etches the dielectric metal oxide material of the etch stop dielectric layers 64 selective to materials of the dielectric cores 62, the vertical semiconductor channels 60, the dielectric tubular spacers 212, and the source semiconductor layer 214. In an illustrative example, if the etch stop dielectric layer 64 comprises aluminum oxide, the second isotropic etch process may comprise a wet etch process employing a mixture of phosphoric acid, acetic acid, and deionized water. If the etch stop dielectric layer 64 comprises hafnium oxide, the second isotropic etch process may comprise a wet etch process employing a mixture of ammonium fluoride, hydrogen peroxide, and deionized water. If the etch stop dielectric layer 64 comprises tantalum oxide, the second isotropic etch process may comprise a wet etch process employing a mixture of ammonium fluoride, hydrofluoric acid, and deionized water.

The removal of the end portion of each etch stop dielectric layer 64 can be selective to the material of the dielectric cores 62. Thus, the core voids 66 are not exposed after the isotropic etch process. A cylindrical segment of an inner sidewall of each vertical semiconductor channel 60 can be exposed. In one embodiment, etch stop dielectric layer 64 comprises an exposed annular end surface having an inner periphery and an outer periphery. In one embodiment, each dielectric core 62 comprises a cylindrical surface segment that is exposed. Further, each dielectric core 62 may comprise a respective end surface that is free of any opening therein and has a periphery that is adjoined to an edge of the cylindrical surface segment of the respective dielectric core 62. In one embodiment, each memory opening fill structure 58 comprises a dielectric liner 56 (which may be a tunneling dielectric layer in some embodiments) that is interposed between a vertical stack of memory elements (which may comprise portions of a memory material layer 54 located at levels of the electrically conductive layers 46) and the vertical semiconductor channel 60. Each dielectric liner 56 can contact a respective dielectric tubular spacer 212, and can contact a respective cylindrical surface segment of the source semiconductor layer 214.

Referring to FIG. 58D, a metallic barrier material can be conformally deposited in the cylindrical cavities laterally surrounding end portions of the dielectric cores 62. The metallic barrier material may comprise a metallic nitride material such as titanium nitride, tantalum nitride, tungsten nitride, or molybdenum nitride, and/or may comprise a metallic carbide material such as titanium carbide, tantalum carbide, or tungsten carbide. The metallic barrier material can be deposited by a conformal deposition process such as a chemical vapor deposition process. The thickness of the deposited metallic barrier material can be greater than the thickness t of the etch stop dielectric layer 64. A metallic barrier liner 224B can be formed in the cylindrical cavities around the dielectric cores 62 and over the end portions of the dielectric cores 62, the vertical semiconductor channels 60, the dielectric tubular spacers 212, and the source semiconductor layer 214.

A metal layer 224M can be formed over the metallic barrier liner 224B. The metal layer 224M may comprise tungsten, tantalum, titanium, molybdenum, cobalt, ruthenium, copper, etc. Subsequently, the metal layer 224M and the metallic barrier liner 224B can be patterned, for example, by applying and patterning a photoresist layer over the metal layer 224M, and by removing portions of the metal layer 224M and the metallic barrier liner 224B that are not masked by patterned portions of the photoresist layer. A metallic source structure 224 can be formed, which is a backside source structure that functions as a source electrode which contacts the source semiconductor layer 214. The photoresist layer can be subsequently removed, for example, by ashing.

The metallic source structure 224 can be formed on a segment of a backside surface of the source semiconductor layer 214 and on the vertical semiconductor channels 60. The metallic source structure 224 can be formed directly on the cylindrical segment of an inner sidewall of each vertical semiconductor channel 60 and directly on a cylindrical segment of a sidewall of each dielectric core 62. In one embodiment, the metallic source structure 224 contacts the source semiconductor layer 214, the etch stop dielectric layers 64, and the vertical semiconductor channels 60.

In one embodiment, each vertical semiconductor channel 60 comprises an annular end surface that is in contact with the metallic source structure 224 and has an inner periphery and an outer periphery. A cylindrical segment of an inner sidewall of each vertical semiconductor channel 60 may be in contact with the metallic source structure 224. Generally, the metallic source structure 224 may comprise a planar portion that extends horizontally underneath the source semiconductor layer 214, and tubular portions that extends vertically from the planar portion into a respective gap between a respective pair of a vertical semiconductor channel 60 and a dielectric core 62. In one embodiment, the dielectric core 62 comprises a cylindrical surface segment in contact with the metallic source structure 224. Each core void 66 can be spaced from the metallic source structure 224 by a respective dielectric core 62.

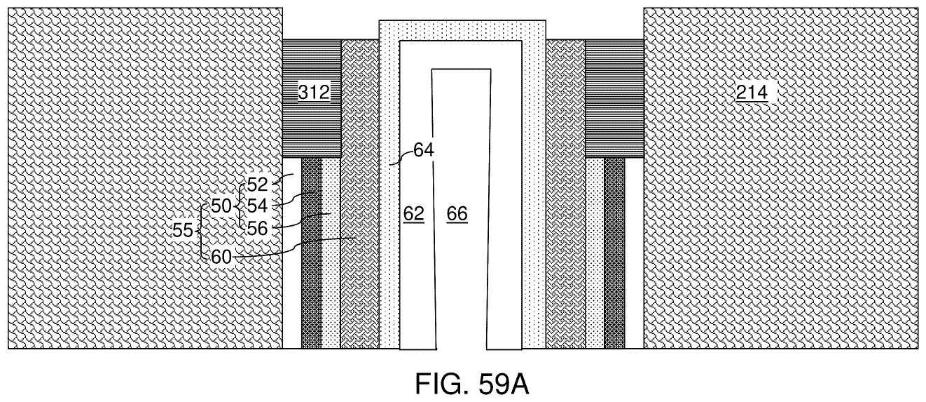

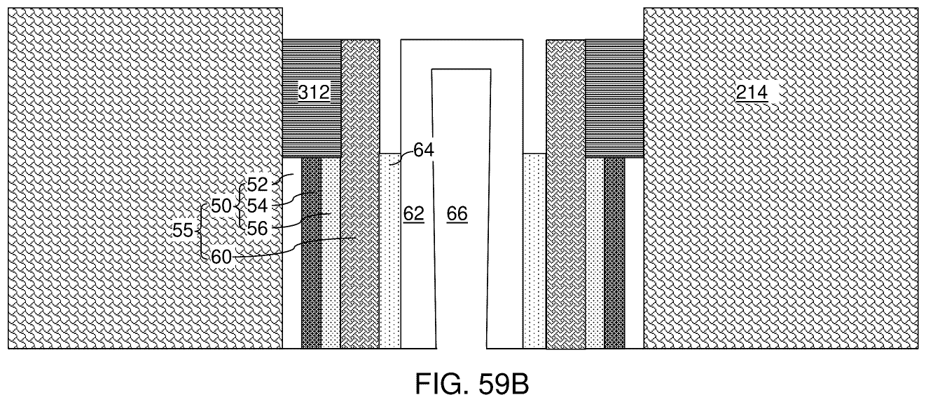

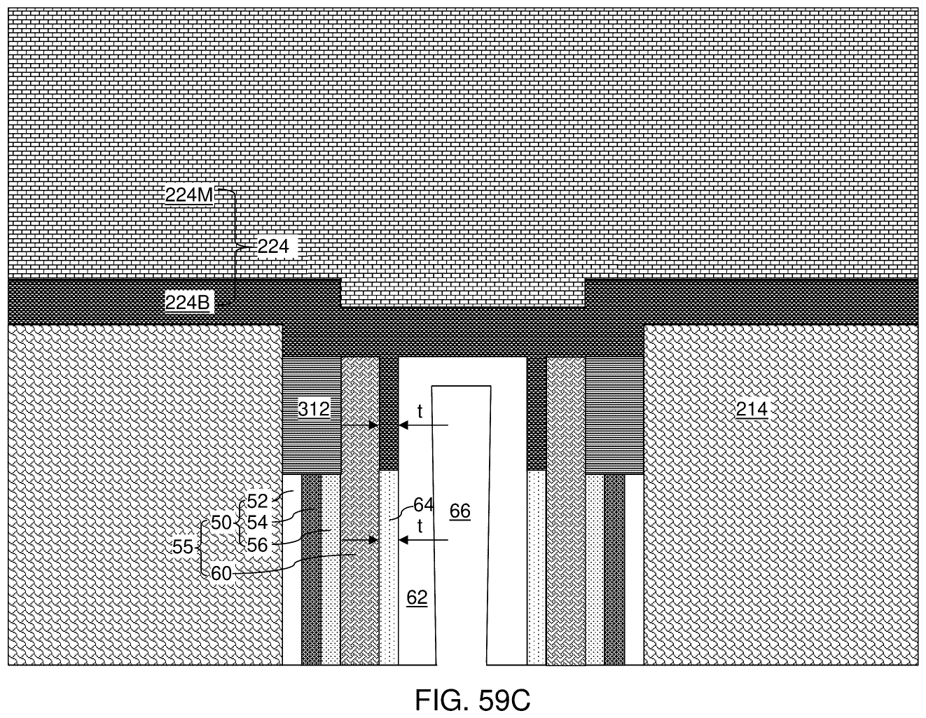

FIGS. 59A-59C are sequential vertical cross-sectional views of a region of a second configuration of the third exemplary structure during formation of a backside source structure 224 according to the third embodiment of the present disclosure.

Referring to FIG. 59A, the second configuration of the third exemplary structure can be derived from the third exemplary structure illustrated in FIGS. 57A and 57B by forming a semiconductor tubular spacer 312 in each cylindrical gap between the source semiconductor layer 214 and a respective one of the vertical semiconductor channels 60. A semiconductor fill material, such as amorphous silicon or polysilicon can be conformally deposited in the cylindrical gaps around end portions of the vertical semiconductor channels 60. The semiconductor fill material may be undoped, or may be doped with dopants of the second conductivity type. The semiconductor fill material may be deposited by a conformal deposition process such as a chemical vapor deposition process or an atomic layer deposition process. Gaps around end portions of the vertical semiconductor channels 60 can be filled with the semiconductor fill material. An isotropic recess etch process can be performed to remove a horizontally-extending portion of the deposited semiconductor fill material from above the backside surface of the source semiconductor layer 214. Remaining cylindrical portions of the deposited semiconductor fill material constitute tubular spacers, which are herein referred to as semiconductor tubular spacers 312.

Referring to FIG. 59B, the processing steps described with reference to FIG. 58B can be performed to remove end portions of the vertical semiconductor channels 60 y the first isotropic etch process.

Subsequently, the processing steps described with reference to FIG. 58C can be performed to remove end portions of the etch stop dielectric layers 64 selective to materials of the dielectric cores 62, the vertical semiconductor channels 60, the semiconductor tubular spacers 214, and the source semiconductor layer 214. The removal of the end portion of each etch stop dielectric layer 64 can be selective to the material of the dielectric cores 62, and thus, the core voids 66 are not exposed to the ambient after the isotropic etch process. Each dielectric liner 56 can contact a respective semiconductor tubular spacer 312, and can contact a respective cylindrical surface segment of the source semiconductor layer 214.

Referring to FIG. 59C, the processing steps described with reference to FIG. 58D can be performed. Specifically, a metallic barrier material and a metallic fill material can be deposited and patterned to form a metallic source structure 224 including a metallic barrier liner 224B and a metal layer 224M.

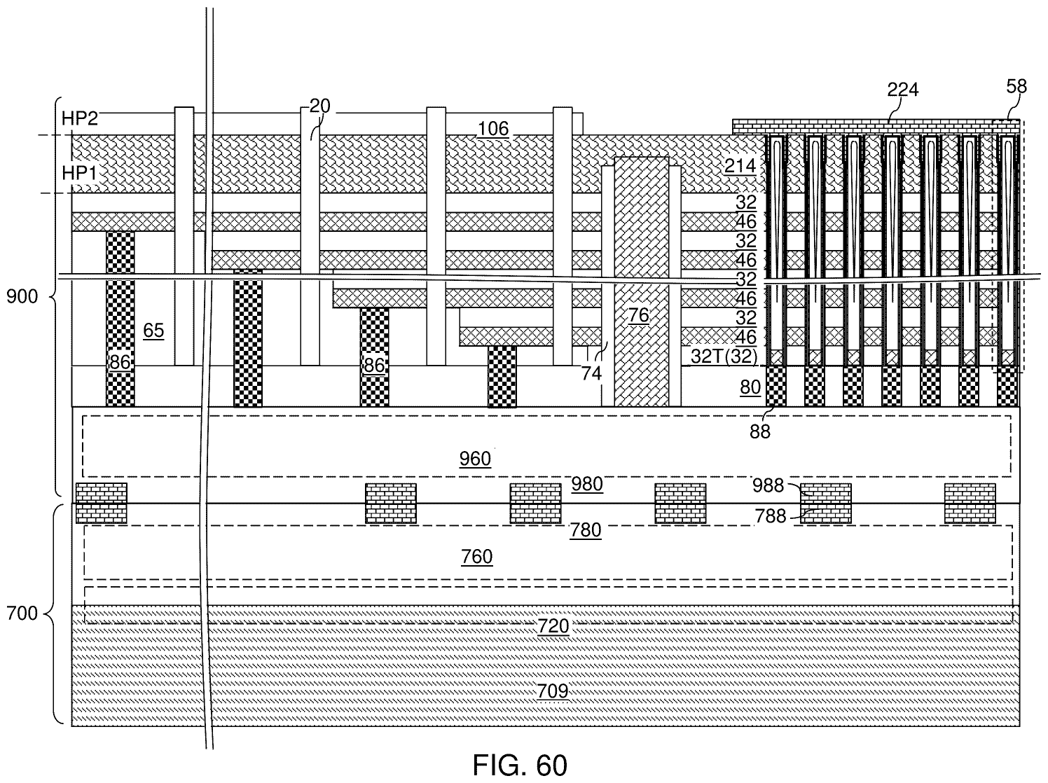

Referring to FIG. 60, the third exemplary structure is illustrated after performing the processing steps described with reference to FIG. 58D or FIG. 59C. The entirety of the contact area between the vertical semiconductor channels 60 and the metallic source structure 224 can be located between a first horizontal plane HP1 including a top surface of the source semiconductor layer 214 and a second horizontal plane HP2 including a top surface of the source semiconductor layer 214. Further, the entirety of each tubular spacer (212 or 312) can be located between the first horizontal plane HP1 and the second horizontal plane HP2.

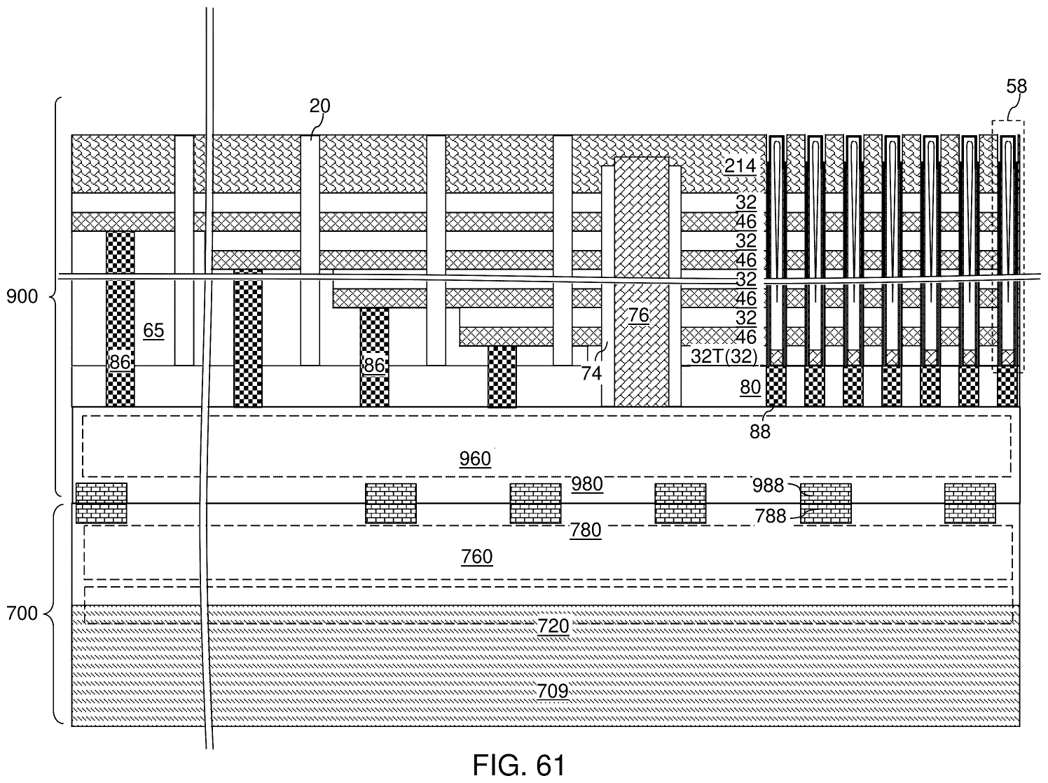

Referring to FIG. 61, a third configuration of the third exemplary structure can be derived from the second third exemplary structure illustrated in FIGS. 57A and 57B by removing the stopper insulating layer 106 without employing any masking process, e.g., without employing any patterned photoresist layer. In this case, the entirety of the stopper insulating layer 106 can be removed.

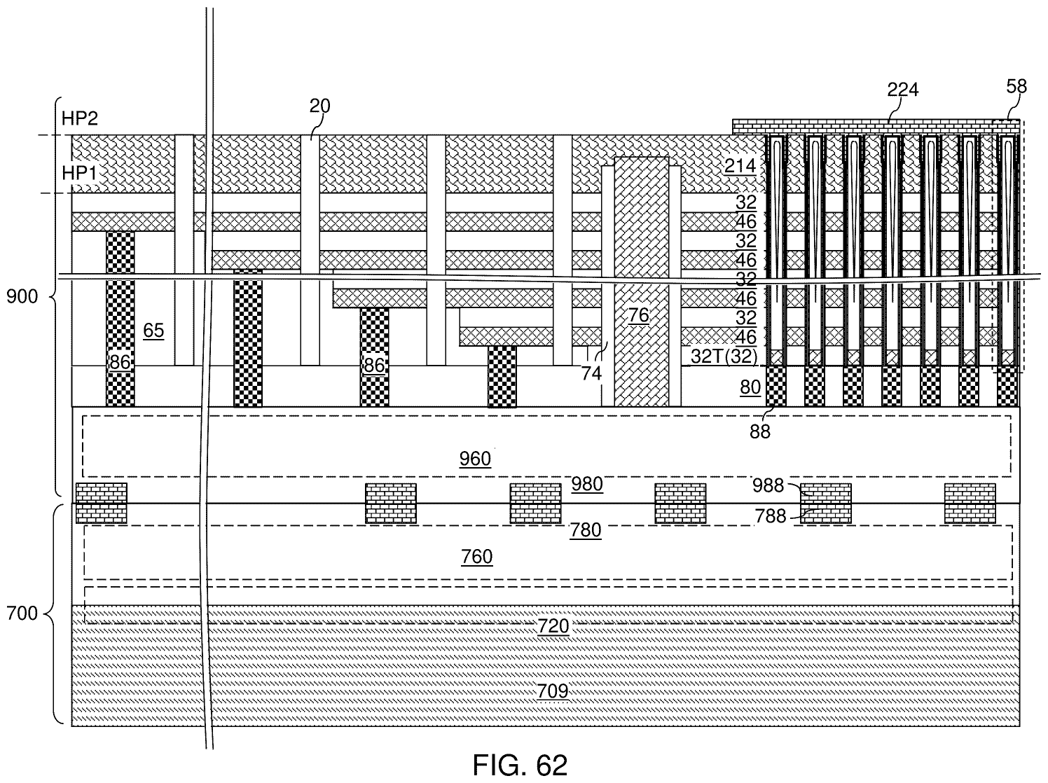

Referring to FIG. 62, the processing steps described with reference to FIGS. 58A-58D or the processing steps described with reference to FIGS. 59A-59C can be performed to remove end portions of the vertical semiconductor channels 60 and the etch stop dielectric layers 64.

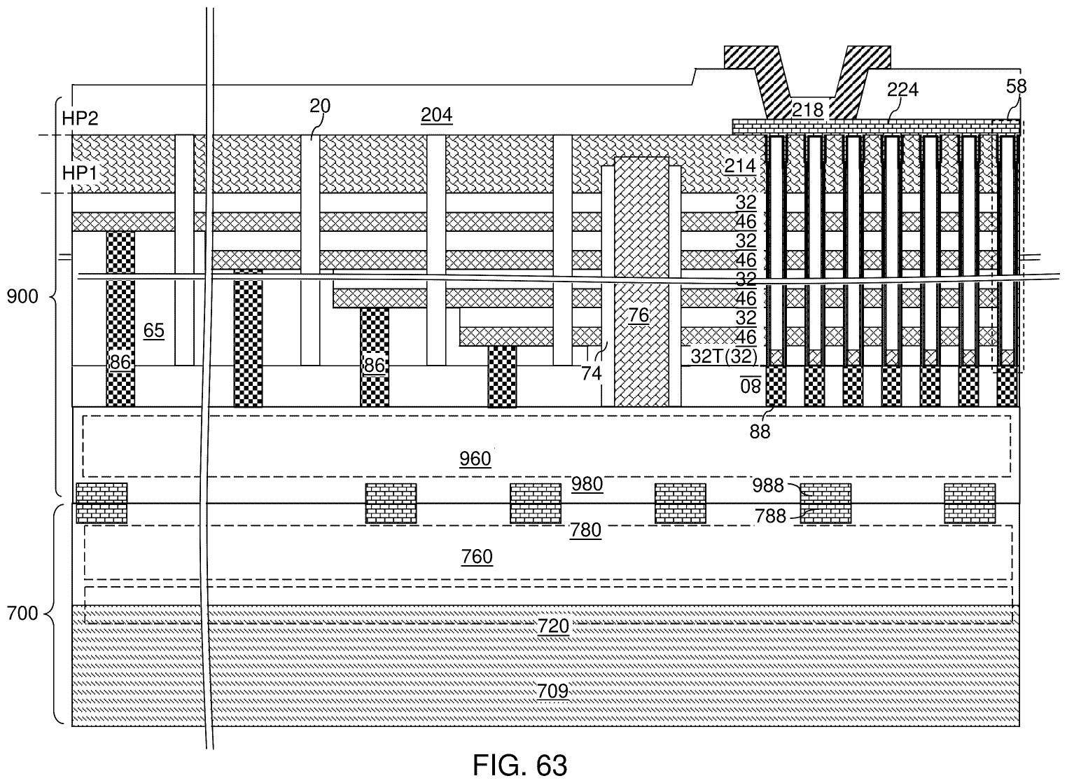

Referring to FIG. 63, a backside insulating layer 204 can be formed over the source semiconductor layer 214 and the metallic source structure 224. A backside contact pad 218 can be formed through the backside insulating layer 204 directly on a backside surface of the metallic source structure 224.

Referring to the third embodiment of the present disclosure, a semiconductor structure is provided, which comprises: an alternating stack (32, 46) of insulating layers 32 and electrically conductive layers 46 located over a source semiconductor layer 214; a memory opening 49 vertically extending through the alternating stack (32, 46) and the source semiconductor layer 214; a memory opening fill structure 58 located in the memory opening 49 and comprising, from outside to inside, a vertical stack of memory elements, a vertical semiconductor channel 60 having a first tubular configuration, an etch stop dielectric layer 64 having a second tubular configuration, and a dielectric core 62; and a metallic source structure 224 contacting the source semiconductor layer 214, the etch stop dielectric layer 64, and the vertical semiconductor channel 60.

In one embodiment, the vertical semiconductor channel 60 comprises an annular end surface in contact with the metallic source structure 224. In one embodiment, a cylindrical segment of an inner sidewall of the vertical semiconductor channel 60 is in contact with the metallic source structure 224. In one embodiment, the etch stop dielectric layer 64 comprises an annular end surface in contact with the metallic source structure 224.

In one embodiment, the dielectric core 62 comprises a cylindrical surface segment of an outer sidewall in contact with the metallic source structure 224. In one embodiment, the dielectric core 62 comprises an end surface that is free of any opening therein and a core void 66 is encapsulated by the dielectric core 62.

In one embodiment, the memory opening fill structure 58 comprises a dielectric liner 56 that is interposed between the vertical stack of memory elements and the vertical semiconductor channel 60. In one embodiment, the dielectric liner 56 is vertically spaced from the metallic source structure 224 by a tubular spacer (212 or 312) that laterally surrounds an end portion of the vertical semiconductor channel 60 and contacts a cylindrical surface segment of the source semiconductor layer 214. In one embodiment, the tubular spacer 212 comprises a dielectric material. In one embodiment, the tubular spacer 312 comprises a doped semiconductor material.

In one embodiment, the etch stop dielectric layer 64 comprises a dielectric metal oxide material. In one embodiment, the memory opening fill structure 58 comprises a drain region 63 that is vertically spaced from the metallic source structure 224 by the dielectric core 62 and contacts an end portion of the vertical semiconductor channel 60; the etch stop dielectric layer 64 is in contact with the drain region 63; the memory opening fill structure 58 is located in a memory die 900; and a logic die 700 is bonded to the memory die 900 over the drain region 63.

In one embodiment, an entirety of an interface between the metallic source structure 224 and the vertical semiconductor channel 60 is located between a first horizontal plane including a top surface of the source semiconductor layer 214 and a second horizontal plane including a bottom surface of the source semiconductor layer 214. In one embodiment, the metallic source structure 224 comprises: a planar portion that extends horizontally underneath the source semiconductor layer 214; and a tubular portion that extends vertically from the planar portion into a gap between the vertical semiconductor channel 60 and the dielectric core 62.

The third embodiment of the present disclosure provides a metallic source structure 224 that contacts end portions of vertical semiconductor channels 60 while avoiding or minimizing collateral removal of end portions of dielectric cores 62. Thus, core voids 66 are not exposed during formation of the metallic source structure 224. Adverse effects, such as collateral etching of inside of the core voids 66 and/or deposition of metallic source structure 22 into the core voids 66 can be avoided. Further, vertically-extending portions of the metallic source structure 224 contact cylindrical surface segments of inner sidewalls of the vertical semiconductor channels 60, thereby providing a more reliable electrical contact between the vertical semiconductor channels 60 and the metallic source structure 224.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
an alternating stack of insulating layers and electrically conductive layers located over source-level material layers;
a memory opening vertically extending through the alternating stack and into an upper portion of the source-level material layers; and
a memory opening fill structure located in the memory opening and comprising a vertical stack of memory elements and a vertical semiconductor channel,
wherein the source-level material layers comprise a source contact layer that includes an outer portion located outside a volume of the memory opening and an inner portion located within the volume of the memory opening and is more proximal to a vertical axis passing through a geometrical center of the volume of the memory opening than an inner sidewall of the vertical semiconductor channel is to the vertical axis.

2. The semiconductor structure of claim 1, wherein the outer portion of the source contact layer and the inner portion of the source contact layer are interconnected to each other by an interconnection portion of the source contact layer that is located within a lateral opening through the vertical semiconductor channel.

3. The semiconductor structure of claim 2, wherein:
the memory opening fill structure further comprises a dielectric liner that is interposed between the vertical semiconductor channel and the vertical stack of memory elements; and
the interconnection portion of the source contact layer extends through a lateral opening in the dielectric liner.

4. The semiconductor structure of claim 2, wherein:
the memory opening fill structure further comprises a blocking dielectric layer that is interposed between the vertical stack of memory elements and the alternating stack; and
the interconnection portion of the source contact layer extends through a lateral opening in the blocking dielectric layer.

5. The semiconductor structure of claim 1, wherein the inner portion of the source contact layer comprises a lower cylindrical segment and an upper tapered segment having a tapered convex surface.

6. The semiconductor structure of claim 1, wherein the memory opening fill structure further comprises a dielectric core that extends vertically through the electrically conductive layers within the alternating stack and has a lopsided bottom portion so that the dielectric core has a lesser vertical extent on a side that is proximal to the outer portion of the source contact layer than on a side that is distal from the outer portion of the source contact layer.

7. The semiconductor structure of claim 6, wherein the lopsided bottom portion of the dielectric core has a concave tapered bottom surface that overlies a convex tapered top surface of the inner portion of the source contact layer.

8. The semiconductor structure of claim 7, wherein the concave tapered bottom surface of the lopsided bottom portion of the dielectric core is in contact with the convex tapered top surface of the inner portion of the source contact layer.

9. The semiconductor structure of claim 7, wherein:
the concave tapered bottom surface of the lopsided bottom portion of the dielectric core is spaced from the convex tapered top surface of the inner portion of the source contact layer by a source-level blocking dielectric layer; and
each neighboring pair of an electrically conductive layer and an insulating within the alternating stack is vertically spaced from each other by a respective backside blocking dielectric layer having a same material composition as the source-level blocking dielectric layer.

10. The semiconductor structure of claim 6, wherein the memory opening fill structure further comprises an etch stop dielectric layer located between the dielectric core and the vertical semiconductor channel.

11. The semiconductor structure of claim 1, wherein the source contact layer comprises:
a source contact metallic barrier layer; and
a source contact fill material layer comprising a metal embedded within the source contact metallic barrier layer.

12. The semiconductor structure of claim 1, wherein:
the memory opening fill structure comprises a dielectric liner that is interposed between the vertical stack of memory elements and the vertical semiconductor channel; and
the source contact layer comprises a vertically-extending fin that contacts a surface segment of an outer sidewall of the vertical semiconductor channel and contacts a surface segment of the dielectric liner.

13. The semiconductor structure of claim 1, wherein the inner portion of the source contact layer is in contact with a segment of an inner sidewall of the vertical semiconductor channel.

14. The semiconductor structure of claim 1, wherein the source-level material layers further comprise:
a lower source-level semiconductor layer that underlies the source contact layer; and
an upper source-level semiconductor layer that is interposed between the lower source-level semiconductor layer and alternating stack and embedding the source contact layer.

15. The semiconductor structure of claim 1, wherein:
the outer portion of the source contact layer comprises a stem portion that laterally extends along a first horizontal direction and multiple branch portions that laterally extend along a second horizontal direction that is different from the first horizontal direction; and
the semiconductor structure further comprises additional memory openings and additional memory opening fill structures that are located in the additional memory openings, wherein each of the additional memory opening fill structures comprises a respective additional vertical semiconductor channel that contacts a respective branch portion of the source contact layer.

16. A method of forming a semiconductor structure, comprising:
forming in-process source-level material layers that comprise a source-level sacrificial layer over a substrate;
forming an alternating stack of insulating layers and spacer material layers over the in-process source-level material layers, wherein the spacer material layers are formed as or are subsequently replaced with electrically conductive layers;
forming a memory opening through the alternating stack and through a segment of the source-level sacrificial layer;
forming a memory opening fill structure comprising a vertical stack of memory elements, a vertical semiconductor channel, and a dielectric core that is laterally surrounded by the vertical semiconductor channel in the memory opening;
forming a source cavity by removing the source-level sacrificial layer;
expanding the source cavity into the memory opening fill structure to physically expose a segment of an inner sidewall of the vertical semiconductor channel; and
forming a source contact layer in the source cavity over the segment of the inner sidewall of the vertical semiconductor channel.

17. The method of claim 16, wherein:
the in-process source-level material layers comprise a lower source-level undoped semiconductor layer that underlies the source-level sacrificial layer and an upper source-level undoped semiconductor layer that overlies the source-level sacrificial layer; and
the method further comprises performing a first isotropic etch process that removes the source-level sacrificial layer selective to materials of the lower and the upper source-level undoped semiconductor layers.

18. The method of claim 17, further comprising:
performing another isotropic etch process that forms a lateral opening through vertical semiconductor channel; and
performing yet another isotropic etch process that etches a portion of the dielectric core to physically expose the segment of the inner sidewall of the vertical semiconductor channel.

19. The method of claim 17, wherein:
the source-level sacrificial layer comprises multiple source-level sacrificial material rails that are laterally spaced from each other along a first horizontal direction and laterally extending along a second horizontal direction that is different from the first horizontal direction; and
the memory opening cuts through an edge region of one of the multiple source-level sacrificial material rails so that a horizontally-concave and vertically-straight surface segment of the one of the multiple source-level sacrificial material rails is physically exposed to the memory opening.

20. The method of claim 16, wherein the source contact layer is formed directly on the segment of the inner sidewall of the vertical semiconductor channel.
